(19) United States
(12) Patent Application Publication
(10) Pub. No.: US 2023/0417969 A1
(43) Pub. Date: Dec. 28, 2023

(54) LIGHT ABSORPTION ANISOTROPIC FILM, LAMINATE, AND IMAGE DISPLAY DEVICE

(71) Applicant: FUJIFILM Corporation, Tokyo (JP)

(72) Inventors: Yasukazu KUWAYAMA, Kanagawa (JP); Hiroshi MATSUYAMA, Kanagawa (JP); Naoya NISHIMURA, Kanagawa (JP); Hiroyuki OKUSA, Kanagawa (JP); Yoshinori MAEDA, Kanagawa (JP)

(73) Assignee: FUJIFILM Corporation, Tokyo (JP)

(21) Appl. No.: 18/462,136

(22) Filed: Sep. 6, 2023

Related U.S. Application Data
(63) Continuation of application No. PCT/JP2022/011507, filed on Mar. 15, 2022.

(30) Foreign Application Priority Data
Mar. 23, 2021 (JP) 2021-048138
Sep. 10, 2021 (JP) 2021-148062
Sep. 29, 2021 (JP) 2021-159549
Dec. 20, 2021 (JP) 2021-206160

(51) Int. Cl. G02B 5/30; G02B 27/28; C09K 19/60; C09K 19/56; C09K 19/38

(52) U.S. Cl. CPC G02B 5/3016; G02B 27/281; C09K 19/601; C09K 19/56; C09K 19/3852; G02F 1/133528

(57) ABSTRACT

Provided is a light absorption anisotropic film capable of suppressing reflection occurring between the light absorption anisotropic film and a layer disposed adjacent thereto, a laminate, and an image display device. The light absorption anisotropic film includes a dichroic substance, in which a polarization degree A measured by allowing polarized light to be incident from one surface of the light absorption anisotropic film is different from a polarization degree B measured by allowing polarized light to be incident from the other surface of the light absorption anisotropic film.

### CROSS-REFERENCE TO RELATED APPLICATIONS

This application is a Continuation of PCT International Application No. PCT/JP2022/011507 filed on Mar. 15, 2022, which claims priority under 35 U.S.C. § 119(a) to Japanese Patent Application No. 2021-048138 filed on Mar. 23, 2021, Japanese Patent Application No. 2021-148062 filed on Sep. 10, 2021, Japanese Patent Application No. 2021-159549 filed on Sep. 29, 2021, and Japanese Patent Application No. 2021-206160 filed on Dec. 20, 2021. The above applications are hereby expressly incorporated by reference, in their entirety, into the present application.

### BACKGROUND OF THE INVENTION

### 1. Field of the Invention

The present invention relates to a light absorption anisotropic film, a laminate, and an image display device.

### 2. Description of the Related Art

In the related art, in a case where an attenuation function, a polarization function, a scattering function, a light-shielding function, or the like of irradiation light including laser light or natural light is required, a device that is operated according to principles different for each function is used. Therefore, products corresponding to the above-described functions are also produced by production processes different for each function.

For example, a linear polarizer or a circular polarizer is used in an image display device (for example, a liquid crystal display device) to control optical rotation or birefringence in display. Further, a circular polarizer is used in an organic light emitting diode (OLED) to prevent reflection of external light.

In the related art, iodine has been widely used as a dichroic substance in these polarizers, but a polarizer that uses an organic coloring agent in place of iodine as a dichroic substance has also been examined.

For example, JP2019-164390A discloses a patterned polarizing film obtained by laminating a base material and a patterned liquid crystal cured film, in which the liquid crystal cured film contains a polymerized substance of a polymerizable liquid crystal compound and a plurality of dichroic coloring agents and has a region (A) with a thickness of 0.5 to 10 μm, a polarization degree of 10% or less, and a single body transmittance of 80% or greater and a region (B) with a polarization degree of 90% or greater and a single body transmittance of 40% or greater (claim 1).

### SUMMARY OF THE INVENTION

As an antireflection film for external light in an organic light emitting diode or the like, a laminate that includes a light absorption anisotropic film containing a dichroic substance may be used. As a result of examination on a laminate including a light absorption anisotropic film containing a dichroic substance as described in JP2019-164390A, the present inventors found that since reflection occurs between the light absorption anisotropic film and a layer (particularly a protective layer disposed on a viewing side of the light absorption anisotropic film) disposed adjacent to the light absorption anisotropic film, reflection may be insufficiently suppressed in a case where the laminate is applied to an image display device, and therefore, there is room for improvement.

Therefore, an object of the present invention is to provide a light absorption anisotropic film capable of suppressing reflection occurring between the light absorption anisotropic film and a layer disposed adjacent thereto, a laminate, and an image display device.

As a result of intensive examination conducted to achieve the above-described object, the present inventors found that in a case where a light absorption anisotropic film containing a dichroic substance has a front surface and a rear surface with different polarization degrees, reflection occurring between the light absorption anisotropic film and a layer disposed adjacent thereto can be suppressed, thereby completing the present invention.

That is, the present inventors found that the above-described object can be achieved by employing the following configurations.

[1]

A light absorption anisotropic film comprising: a dichroic substance, in which a polarization degree A measured by allowing polarized light to be incident from one surface of the light absorption anisotropic film is different from a polarization degree B measured by allowing polarized light to be incident from the other surface of the light absorption anisotropic film.

[2]

The light absorption anisotropic film according to [1], in which an absolute value of a difference between the polarization degree A and the polarization degree B is 0.10% or greater.

[3]

The light absorption anisotropic film according to [1] or [2], in which in a surface of the light absorption anisotropic film on a side where the measured polarization degree is smaller between the polarization degree A and the polarization degree B, the dichroic substance has an out-of-plane alignment degree f_{zx} of −0.2 or greater.

[4]

The light absorption anisotropic film according to any one of [1] to [3], in which the light absorption anisotropic film has an in-plane absorption axis.

[5]

The light absorption anisotropic film according to any one of [1] to [4], in which the light absorption anisotropic film has a visible light average transmittance of 35% to 70%.

[6]

The light absorption anisotropic film according to any one of [1] to [5], in which a content of the dichroic substance is 40% by mass or less with respect to a total mass of the light absorption anisotropic film.

[7]

The light absorption anisotropic film according to any one of [1] to [5], further comprising: a polymer liquid crystal compound.

[8]

The light absorption anisotropic film according to any one of [1] to [7], further comprising: a surfactant having a fluorine atom and a log P value of 5.2 or less.

[9]

The light absorption anisotropic film according to [8], in which a content of the fluorine atom in the surfactant is 10% by mass or greater.

[10]

The light absorption anisotropic film according to [8] or [9], in which the surfactant does not contain a hydrogen bonding group.

[11]

The light absorption anisotropic film according to any one of [8] to [10], in which a content of the surfactant is in a range of 0.05% to 5% by mass with respect to a total mass of the light absorption anisotropic film.

[12]

The light absorption anisotropic film according to any one of [8] to [11], in which in a case where the light absorption anisotropic film contains a polymer liquid crystal compound, a distance between a Hansen solubility parameter of the surfactant and a Hansen solubility parameter of the polymer liquid crystal compound is 3.5 MPa^{1/2} or greater.

[13]

A laminate comprising: a protective layer; the light absorption anisotropic film according to any one of [1] to [12]; and an alignment film in this order in a thickness direction, in which the alignment film is disposed on a surface side of the light absorption anisotropic film where a measured polarization degree is greater between a polarization degree A and a polarization degree B measured using the light absorption anisotropic film.

[14]

The laminate according to [13], in which a refractive index of the light absorption anisotropic film at a wavelength of 550 nm is greater than a refractive index of the protective layer at a wavelength of 550 nm.

[15]

The laminate according to or [14], further comprising: a λ/4 plate on a surface side of the alignment film opposite to the light absorption anisotropic film.

[16]

An image display device comprising: the light absorption anisotropic film according to any one of [1] to [12]; or the laminate according to any one of to [15].

According to the present invention, it is possible to provide a light absorption anisotropic film capable of suppressing reflection occurring between the light absorption anisotropic film and a layer disposed adjacent thereto, a laminate, and an image display device.

### BRIEF DESCRIPTION OF THE DRAWINGS

FIG. 1 is a schematic view illustrating a waveguide spectroscopic analyzer used for measuring an absorbance spectrum of an object to be measured.

FIG. 2 is a schematic view for describing a procedure of measuring the absorbance spectrum of an object to be measured.

FIG. 3 is a schematic view for describing a procedure of measuring the absorbance spectrum of an object to be measured.

FIG. 4 is a schematic view describing a relationship between a traveling direction of light and orientation of an object to be measured in the measurement of the absorbance spectrum of the object to be measured.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In addition, in the present specification, a numerical range shown using “to” indicates a range including numerical values described before and after “to” as a lower limit value and an upper limit value.

Further, in the present specification, materials corresponding to respective components may be used alone or in combination of two or more kinds thereof. Here, in a case where two or more kinds of materials corresponding to respective components are used in combination, the content of the components indicates the total content of the materials used in combination unless otherwise specified.

Further, in the present specification, “(meth)acrylate” denotes “acrylate” or “methacrylate”, “(meth)acryl” denotes “acryl” or “methacryl”, “(meth)acryloyl” denotes “acryloyl” or “methacryloyl”, and “(meth)acrylic acid” denotes “acrylic acid” or “methacrylic acid”.

[Light Absorption Anisotropic Film]

A light absorption anisotropic film according to the embodiment of the present invention is a light absorption anisotropic film containing a dichroic substance, in which a polarization degree A measured by allowing polarized light to be incident from one surface of the light absorption anisotropic film is different from a polarization degree B measured by allowing polarized light to be incident from the other surface of the light absorption anisotropic film.

According to the light absorption anisotropic film according to the embodiment of the present invention, reflection occurring between the light absorption anisotropic film and a layer disposed adjacent thereto (hereinafter, also referred to as “adjacent layer”) can be suppressed. The details of the reason for this are not clear, but it is assumed as follows.

In a case where the dichroic substance contained in the light absorption anisotropic film is disposed to have an absorption axis in an in-plane direction of the light absorption anisotropic film (that is, the dichroic substance is horizontally aligned), the refractive index of the light absorption anisotropic film is increased in a case where the light absorption anisotropic film is irradiated with light at an angle close to a normal line with respect to the surface of the light absorption anisotropic film. In a case where such a light absorption anisotropic film is applied to the laminate, reflection is considered to occur at the interface between the light absorption anisotropic film and the adjacent layer due to an increase in a difference between the refractive index of the light absorption anisotropic film and the refractive index of the adjacent layer.

Here, the light absorption anisotropic film according to the embodiment of the present invention has a front surface and a rear surface with different polarization degrees. In the vicinity of one surface of the light absorption anisotropic film in which the entire dichroic substance is horizontally aligned, the light absorption anisotropic film having a front surface and a rear surface with different polarization degrees can be obtained in a case where the dichroic substance is in an alignment state close to vertical alignment. Specifically, the polarization degree is low and the refractive index decreases in the surface where the dichroic substance is in the alignment state close to vertical alignment. Further, the polarization degree is high and the refractive index increases in the surface where the dichroic substance is horizontally aligned. Therefore, it is assumed that in a case where the surface with a lower polarization degree (a surface with a lower refractive index) is disposed on the adjacent layer side (a layer on the viewing side, for example, a protective layer described below), the difference in refractive index between the light absorption anisotropic film and the adjacent layer is decreased, and thus the internal reflection can be suppressed. The display performance of the image display device is considered to be improved as a result of suppressing the internal reflection.

[Dichroic Substance]

The light absorption anisotropic film according to the embodiment of the present invention contains a dichroic substance. In the present invention, the dichroic substance indicates a coloring agent having different absorbances depending on the direction. The dichroic substance may be polymerized in the light absorption anisotropic film.

The dichroic substance contained in the light absorption anisotropic film is not particularly limited, and examples thereof include a visible light absorbing substance (dichroic coloring agent), a luminescent substance (such as a fluorescent substance or a phosphorescent substance), an ultraviolet absorbing substance, an infrared absorbing substance, a nonlinear optical substance, a carbon nanotube, and an inorganic substance (for example, a quantum rod). Further, known dichroic substances (dichroic coloring agents) of the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, and paragraphs [0014] to [0034] of WO2018/164252A.

In the present invention, two or more kinds of dichroic substances may be used in combination. For example, from the viewpoint of making the color of the light absorption anisotropic film to be obtained closer to black, it is preferable that at least one dichroic substance having a maximal absorption wavelength in a wavelength range of 370 nm or greater and less than 500 nm and at least one dichroic substance having a maximal absorption wavelength in a wavelength range of 500 nm or greater and less than 700 nm are used in combination.

The dichroic substance may contain a crosslinkable group.

Specific examples of the crosslinkable group include a (meth)acryloyl group, an epoxy group, an oxetanyl group, and a styryl group. Among these, a (meth)acryloyl group is preferable.

As the dichroic substance, a dichroic azo coloring agent compound is preferable.

In the present invention, from the viewpoint of adjusting the tint, the light absorption anisotropic film contains preferably at least one coloring agent compound having a maximal absorption wavelength in a wavelength range of 560 to 700 nm (hereinafter, also referred to as “first dichroic azo coloring agent compound”) and at least one coloring agent compound having a maximal absorption wavelength in a wavelength range of 455 nm or greater and less than 560 nm (hereinafter, also referred to as “second dichroic azo coloring agent compound”) and specifically more preferably at least a dichroic azo coloring agent compound represented by Formula (1A) and a dichroic azo coloring agent compound represented by Formula (2A).

In the present invention, three or more kinds of dichroic azo coloring agent compounds may be used in combination. For example, from the viewpoint of making the color of the light absorption anisotropic film close to black, it is preferable to use the first dichroic azo coloring agent compound, the second dichroic azo coloring agent compound, and at least one coloring agent compound having a maximal absorption wavelength in a wavelength range of 380 nm or greater and less than 455 nm (preferably in a wavelength range of 380 to 454 nm) (hereinafter, also referred to as “third dichroic azo coloring agent compound”) in combination.

In the present invention, from the viewpoint of further enhancing pressing resistance, it is preferable that the dichroic azo coloring agent compound contains a crosslinkable group.

Specific examples of the crosslinkable group include a (meth)acryloyl group, an epoxy group, an oxetanyl group, and a styryl group. Among these, a (meth)acryloyl group is preferable.

(First Dichroic Azo Coloring Agent Compound)

It is preferable that the first dichroic azo coloring agent compound is a compound having a chromophore which is a nucleus and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic ring group and an azo group is preferable, and a bisazo structure containing an aromatic heterocyclic group (preferably a thienothiazole group) and two azo groups is more preferable.

The side chain is not particularly limited, and examples thereof include a group represented by L3, R2, or L4 in Formula (1A).

From the viewpoint adjusting the tint of the light absorption anisotropic film, it is preferable that the first dichroic azo coloring agent compound is a dichroic azo coloring agent compound having a maximum absorption wavelength in a wavelength range of 560 nm or greater and 700 nm or less (more preferably in a range of 560 to 650 nm and particularly preferably in a range of 560 to 640 nm).

The maximum absorption wavelength (nm) of the dichroic azo coloring agent compound in the present specification is acquired from an ultraviolet visible spectrum in a wavelength range of 380 to 800 nm measured by a spectrophotometer using a solution prepared by dissolving the dichroic azo coloring agent compound in a good solvent.

In the present invention, from the viewpoint of further improving the alignment degree of the light absorption anisotropic film to be formed, it is preferable that the first dichroic azo coloring agent compound is a compound represented by Formula (1A).

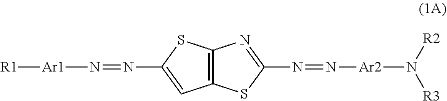

In Formula (1A), Ar1 and Ar2 each independently represent a phenylene group which may have a substituent or a naphthylene group which may have a substituent. Among these, a phenylene group is preferable.

In Formula (1A), R1 represents a hydrogen atom, a linear or branched alkyl group having 1 to 20 carbon atoms which may have a substituent, an alkoxy group, an alkylthio group, an alkylsulfonyl group, an alkylcarbonyl group, an alkyloxycarbonyl group, an acyloxy group, an alkylcarbonate group, an alkylamino group, an acylamino group, an alkylcarbonylamino group, an alkoxycarbonylamino group, an alkylsulfonylamino group, an alkylsulfamoyl group, an alkylcarbamoyl group, an alkylsulfinyl group, an alkylureido group, an alkylphosphoric acid amide group, an alkylimino group, or an alkylsilyl group.

Further, —CH₂— constituting the alkyl group may be substituted with —O—, —CO—, —C(O)—O—C(O)—, —Si(CH₃)₂—O—Si(CH₃)₂—, —N(R1′)—, —N(R1′)—CO—, —CO—N(R1′)—, —N(R1′)—C(O)—O—, —O—C(O)—N(R1′)—, —N(R1′)—C(O)—N(R1′)—, —CH═CH—, —CδC—, —N═N—, —C(R1′)═CH—C(O)—, or —O—C(O)—O—.

In a case where R1 represents a group other than a hydrogen atom, the hydrogen atom in each group may be substituted with a halogen atom, a nitro group, a cyano group, —N(R1′)₂, an amino group, —C(R1′)═C(R1′)—NO₂, —C(R1′)═C(R1′)—CN, or —C(R1′)═C(CN)₂.

R1′ represents a hydrogen atom or a linear or branched alkyl group having 1 to 6 carbon atoms. In a case where a plurality of (R1′)'s are present in each group, these may be the same as or different from one another.

In Formula (1A), R2 and R3 each independently represent a hydrogen atom, a linear or branched alkyl group having 1 to 20 carbon atoms which may have a substituent, an alkoxy group, an acyl group, an alkyloxycarbonyl group, an alkylamide group, an alkylsulfonyl group, an aryl group, an arylcarbonyl group, an arylsulfonyl group, an aryloxycarbonyl group, or an arylamide group.

Further, —CH₂— constituting the alkyl group may be substituted with —O—, —S—, —C(O)—, —C(O)—O—, —O—C(O)—, —C(O)—S—, —S—C(O)—, —Si(CH₃)₂—O—Si(CH₃)₂—, —NR2′—, —NR2′—CO—, —CO—NR2′—, —NR2′—C(O)—O—, —O—C(O)—NR2′—, —NR2′—C(O)—NR2′—, —CH═CH—, —N═N—, —C(R2′)═CH—C(O)—, or —O—C(O)—O—.

In a case where R2 and R3 represent a group other than a hydrogen atom, the hydrogen atom of each group may be substituted with a halogen atom, a nitro group, a cyano group, a —OH group, —N(R2′)₂, an amino group, —C(R2′)═C(R2′)—NO₂, —C(R2′)═C(R2′)—CN, or —C(R2′)═C(CN)₂.

R2′ represents a hydrogen atom or a linear or branched alkyl group having 1 to 6 carbon atoms. In a case where a plurality of (R2′)'s are present in each group, these may be the same as or different from one another.

R2 and R3 may be bonded to each other to form a ring, or R2 or R3 may be bonded to Ar2 to form a ring.

From the viewpoint of the light fastness, it is preferable that R1 represents an electron-withdrawing group and R2 and R3 represent a group having a low electron-donating property.

Specific examples of such a group as R1 include an alkylsulfonyl group, an alkylcarbonyl group, an alkyloxycarbonyl group, an acyloxy group, an alkylsulfonylamino group, an alkylsulfamoyl group, an alkylsulfinyl group, and an alkylureido group, and examples of groups as R2 and R3 include groups having the following structures. Further, the groups having the following structures are shown in the form having a nitrogen atom to which R2 and R3 are bonded in Formula (1A).

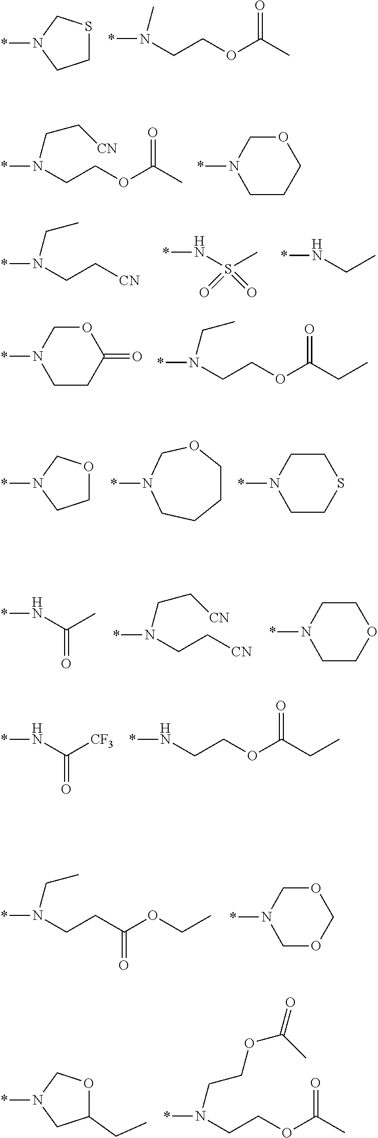

Specific examples of the first dichroic azo coloring agent compound are shown below, but the present invention is not limited thereto.

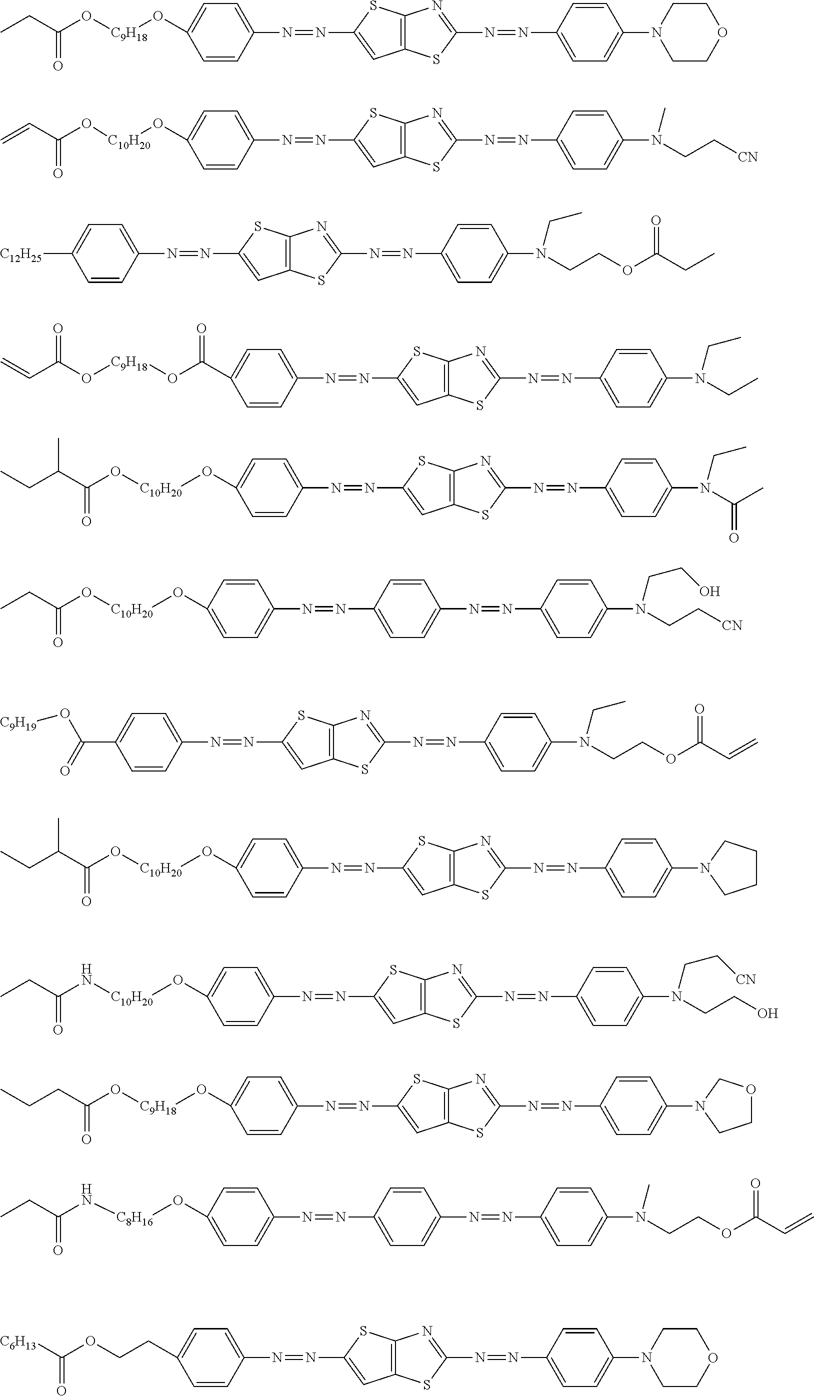

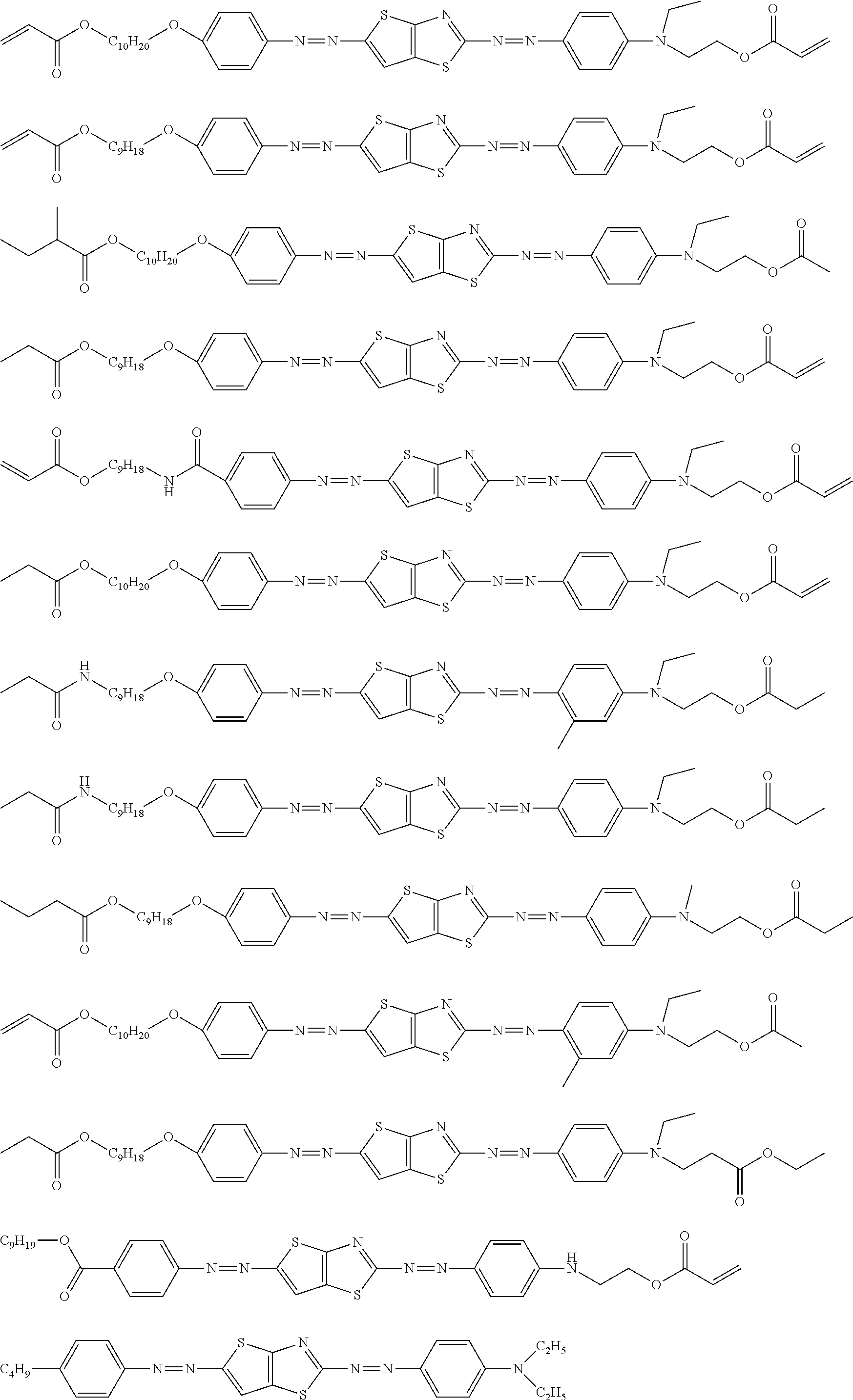

(Second Dichroic Azo Coloring Agent Compound)

The second dichroic azo coloring agent compound is a compound different from the first dichroic azo coloring agent compound, and specifically, the chemical structure thereof is different from that of the first dichroic azo coloring agent compound.

It is preferable that the second dichroic azo coloring agent compound is a compound having a chromophore which is a nucleus of a dichroic azo coloring agent compound and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic hydrocarbon group and an azo group is preferable, and a bisazo or trisazo structure containing an aromatic hydrocarbon group and two or three azo groups is more preferable.

The side chain is not particularly limited, and examples thereof include a group represented by R4, R5, or R6 in Formula (2A).

The second dichroic azo coloring agent compound is a dichroic azo coloring agent compound having a maximum absorption wavelength in a wavelength range of 455 nm or greater and less than 560 nm, and from the viewpoint of adjusting the tint of the light absorption anisotropic film, preferably a dichroic azo coloring agent compound having a maximum absorption wavelength in a wavelength range of 455 to 555 nm and more preferably a dichroic azo coloring agent compound having a maximum absorption wavelength in a wavelength range of 455 to 550 nm.

In particular, the tint of the light absorption anisotropic film is easily adjusted by using a first dichroic azo coloring agent compound having a maximum absorption wavelength of 560 to 700 nm and a second dichroic azo coloring agent compound having a maximum absorption wavelength of 455 nm or greater and less than 560 nm.

From the viewpoint of further improving the alignment degree of the light absorption anisotropic film, it is preferable that the second dichroic azo coloring agent compound is a compound represented by Formula (2A).

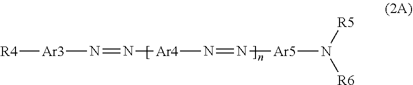

In Formula (2A), n represents 1 or 2.

In Formula (2A), Ar3, Ar4, and Ar5 each independently represent a phenylene group which may have a substituent, a naphthylene group which may have a substituent, or a heterocyclic group which may have a substituent.

The heterocyclic group may be aromatic or non-aromatic.

The atoms other than carbon constituting the aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

In Formula (2A), R4 has the same definition as that for R1 in Formula (1A).

In Formula (2A), R5 and R6 each have the same definition as that for R2 and R3 in Formula (1A).

From the viewpoint of the light resistance, it is preferable that R4 represents an electron-withdrawing group and R5 and R6 represent a group having a low electron-donating property.

Among such groups, specific examples of a case where R4 represents an electron-withdrawing group are the same as the specific examples of a case where R1 represents an electron-withdrawing group, and specific examples of a case where R5 and R6 represent a group having a low electron-donating property are the same as the specific examples of a case where R2 and R3 represent a group having a low electron-donating property.

Specific examples of the second dichroic azo coloring agent compound are shown below, but the present invention is not limited thereto.

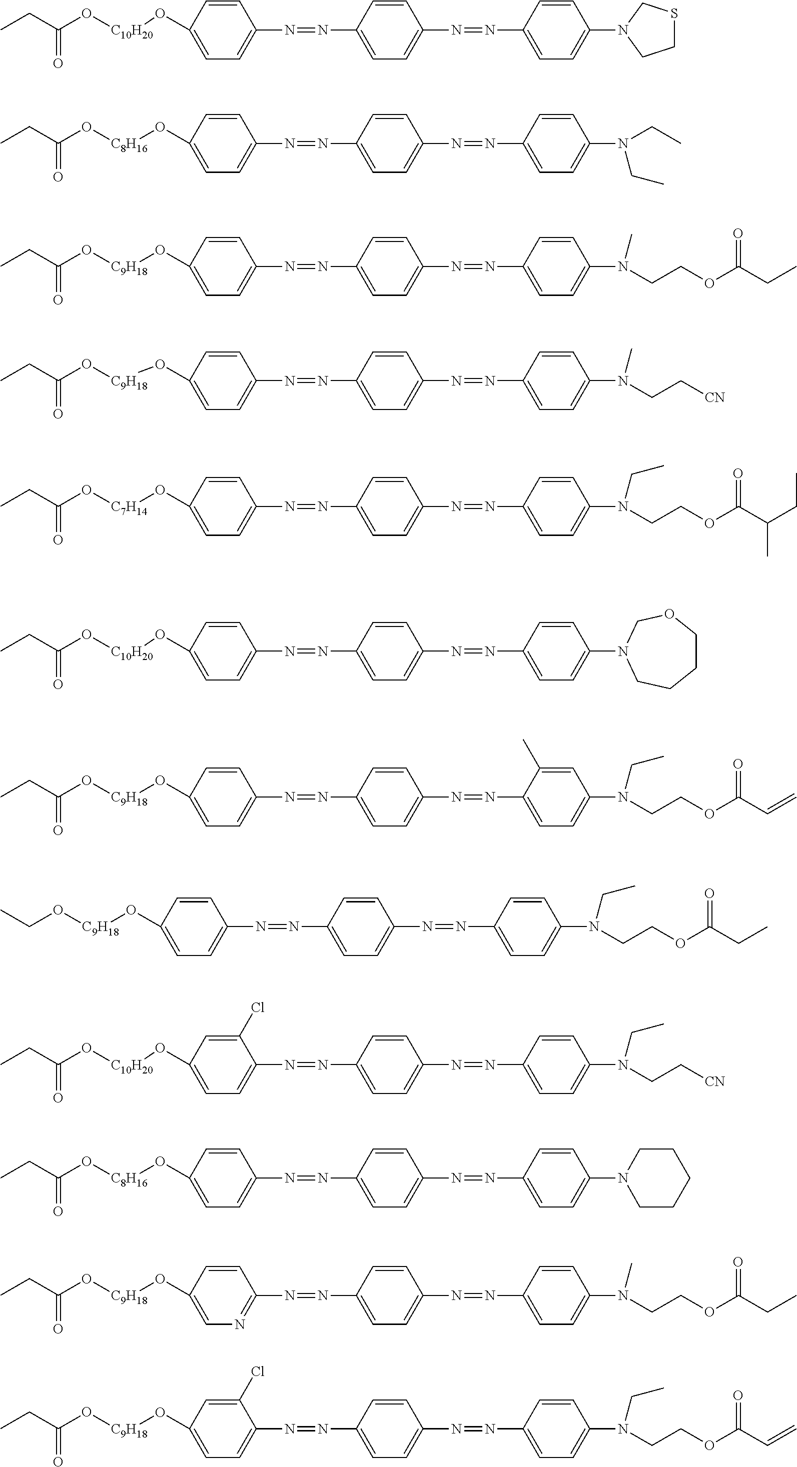

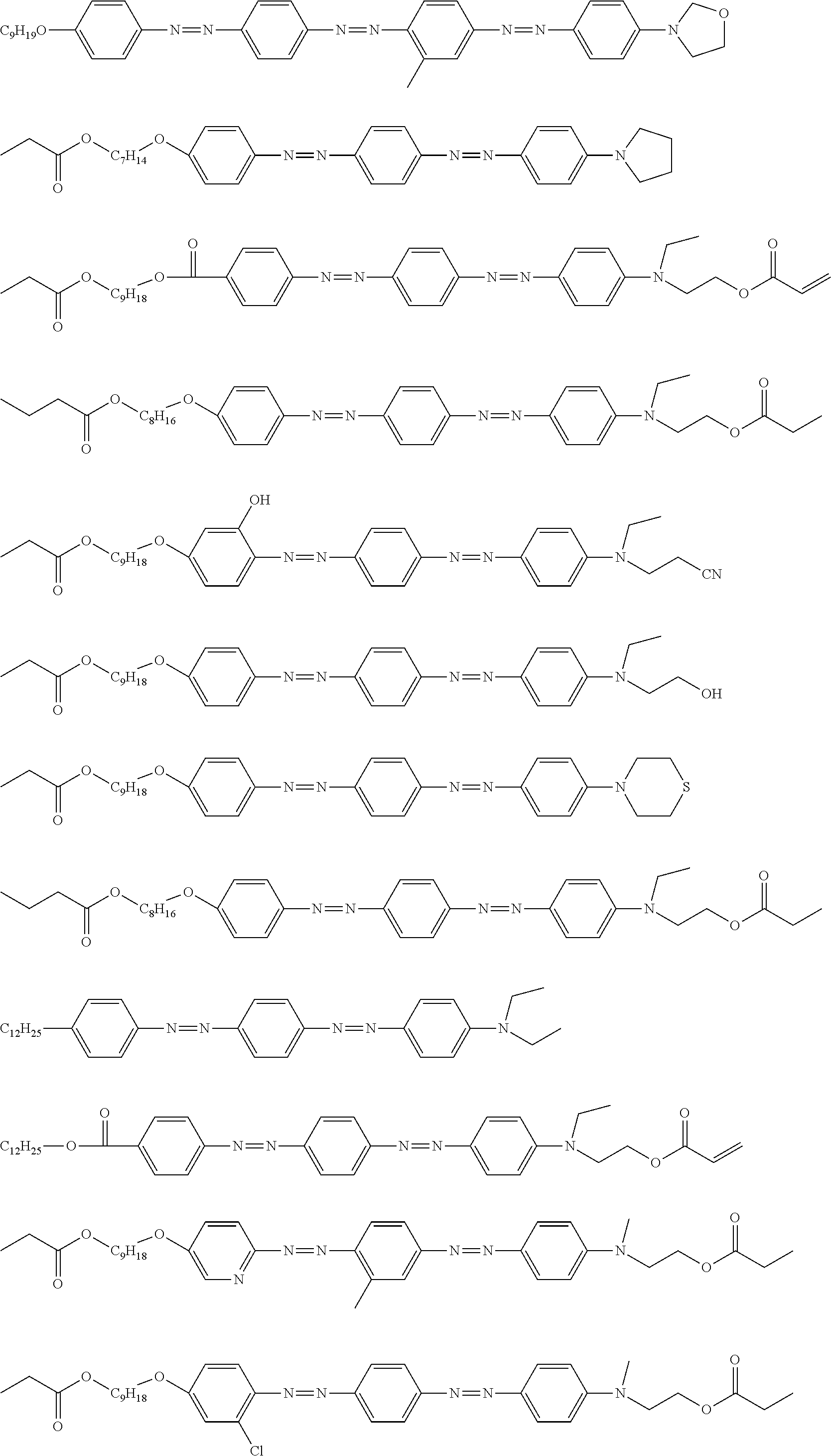

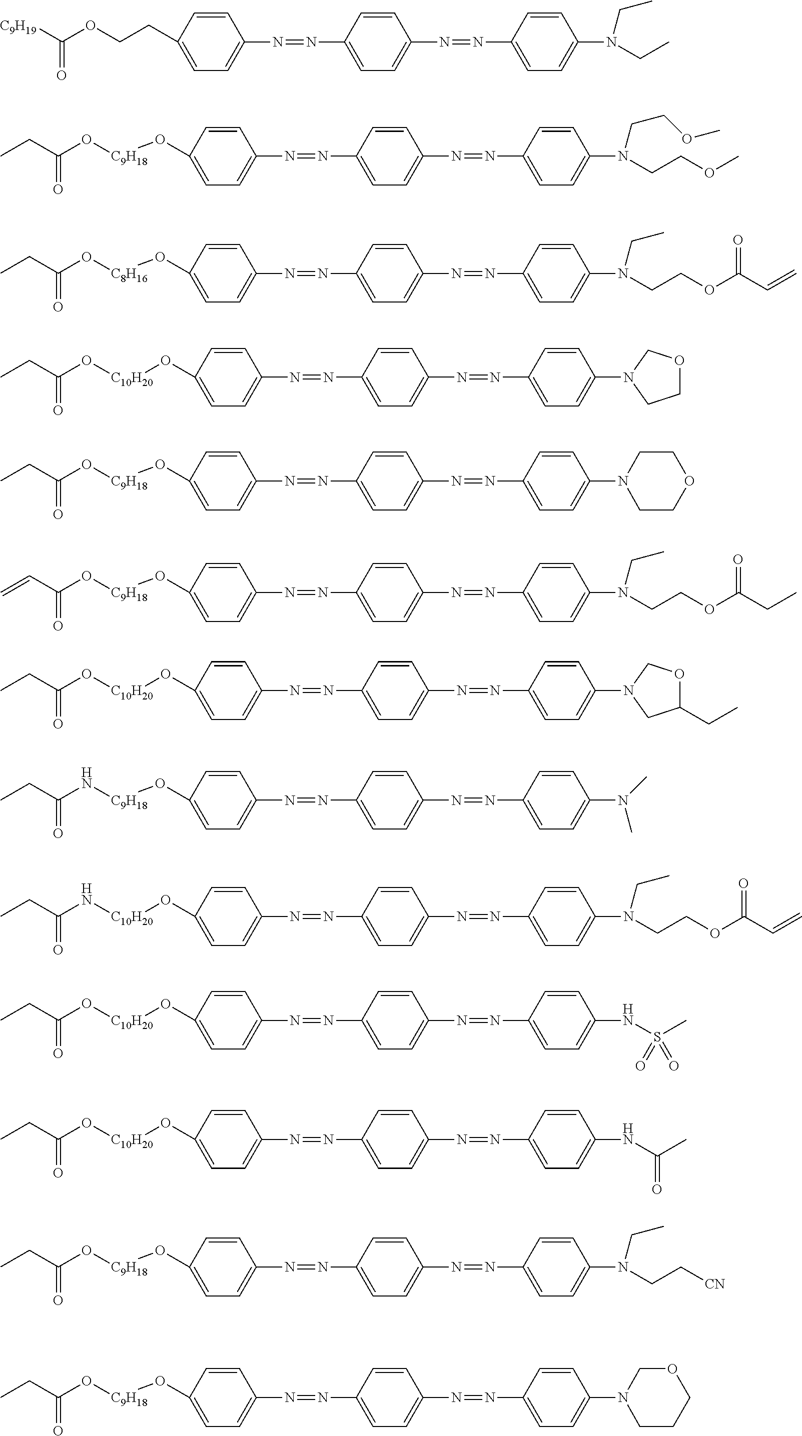

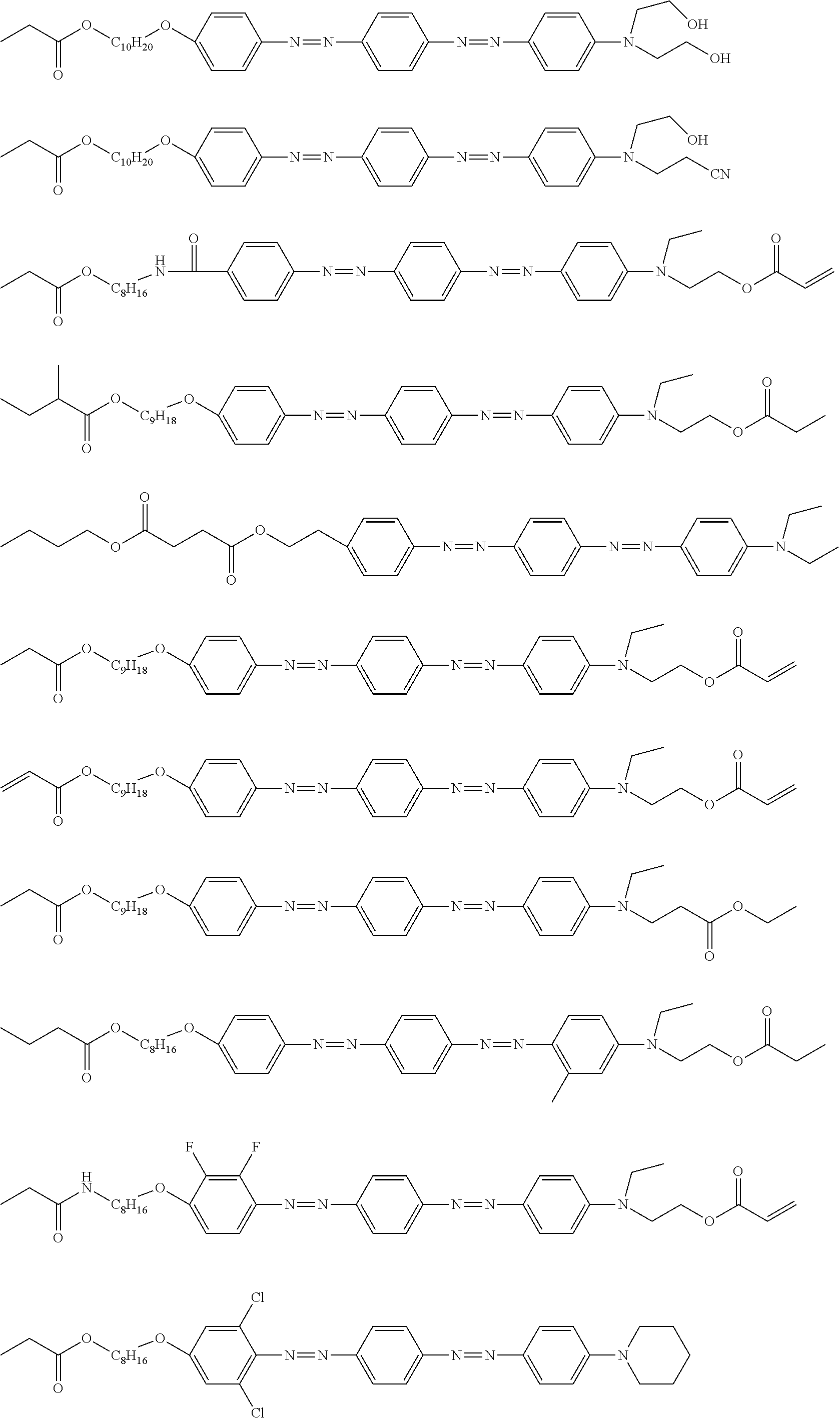

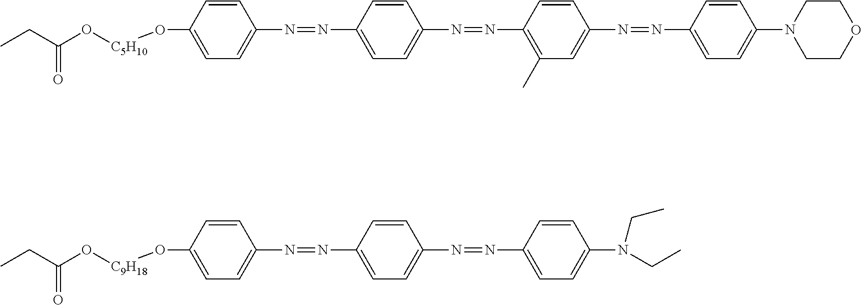

(Difference in Log P Value)

The log P value is an index expressing the hydrophilicity and the hydrophobicity of a chemical structure. An absolute value of a difference (hereinafter, also referred to as “difference in log P value”) between the log P value of a side chain of the first dichroic azo coloring agent compound and the log P value of a side chain of the second dichroic azo coloring agent compound is preferably 2.30 or less, more preferably 2.0 or less, still more preferably 1.5 or less, and particularly preferably 1.0 or less. In a case where the difference in log P value is 2.30 or less, since the affinity between the first dichroic azo coloring agent compound and the second dichroic azo coloring agent compound is enhanced and an arrangement structure is more easily formed, the alignment degree of the light absorption anisotropic film is further improved.

Further, in a case where the first dichroic azo coloring agent compound or the second dichroic azo coloring agent compound has a plurality of side chains, it is preferable that at least one difference in log P value is in the above-described ranges.

Here, the side chain of the first dichroic azo coloring agent compound and the side chain of the second dichroic azo coloring agent compound denote a group bonded to the terminal of the above-described chromophore. For example, R1, R2, and R3 in Formula (1A) represent a side chain in a case where the first dichroic azo coloring agent compound is a compound represented by Formula (1A), and R4, R5, and R6 in Formula (2A) represent a side chain in a case where the second dichroic azo coloring agent compound is a compound represented by Formula (2A). In particularly, in a case where the first dichroic azo coloring agent compound is a compound represented by Formula (1A) and the second dichroic azo coloring agent compound is a compound represented by Formula (2A), it is preferable that at least one difference in log P value among the difference in log P value between R1 and R4, the difference in log P value between R1 and R5, the difference in log P value between R2 and R4, and the difference in log P value between R2 and R5 is in the above-described ranges.

Here, the log P value is an index for expressing the properties of the hydrophilicity and hydrophobicity of a chemical structure and is also referred to as a hydrophilic-hydrophobic parameter. The log P value can be calculated using software such as ChemBioDraw Ultra or HSPiP (Ver. 4.1.07). Further, the log P value can be acquired experimentally by the method of the OECD Guidelines for the Testing of Chemicals, Sections 1, Test No. 117 or the like. In the present invention, a value calculated by inputting the structural formula of a compound to HSPiP (Ver. 4.1.07) is employed as the log P value unless otherwise specified.

(Third Dichroic Azo Coloring Agent Compound)

The third dichroic azo coloring agent compound is a dichroic azo coloring agent compound other than the first dichroic azo coloring agent compound and the second dichroic azo coloring agent compound, and specifically, the chemical structure thereof is different from those of the first dichroic azo coloring agent compound and the second dichroic azo coloring agent compound. In a case where the light absorption anisotropic film contains the third dichroic azo coloring agent compound, there is an advantage that the tint of the light absorption anisotropic film is easily adjusted.

The maximum absorption wavelength of the third dichroic azo coloring agent compound is 380 nm or greater and less than 455 nm and preferably in a range of 385 to 454 nm.

Specific examples of the third dichroic azo coloring agent compound include compounds represented by Formula (1A) described in WO2017/195833A. Among the compounds, compounds other than the first dichroic azo coloring agent compound and the second dichroic azo coloring agent compound may be exemplified.

Specific examples of the third dichroic azo coloring agent compound are shown below, but the present invention is not limited thereto. In the following specific examples, n represents an integer of 1 to 10. Further, Me represents a methyl group.

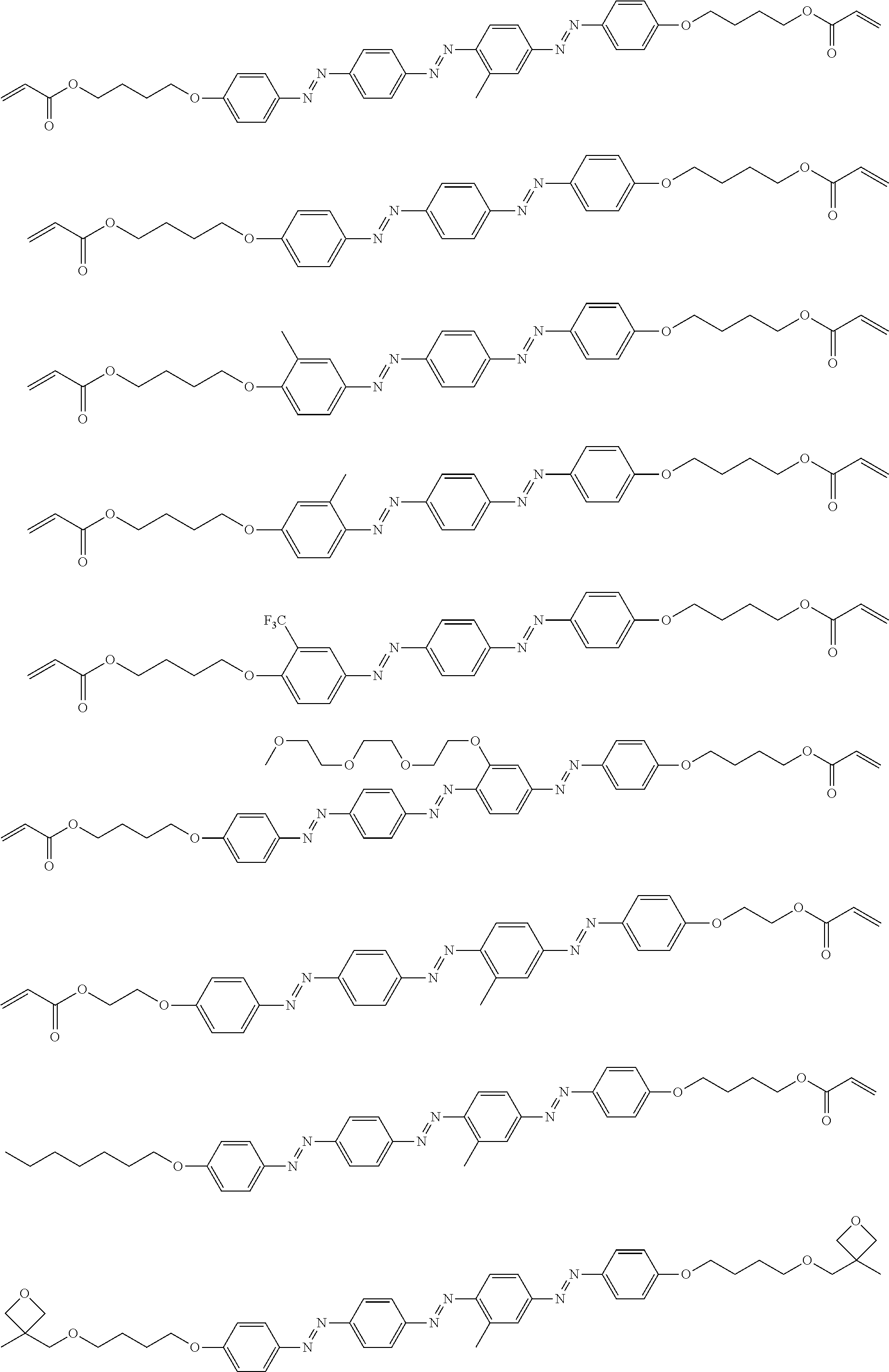

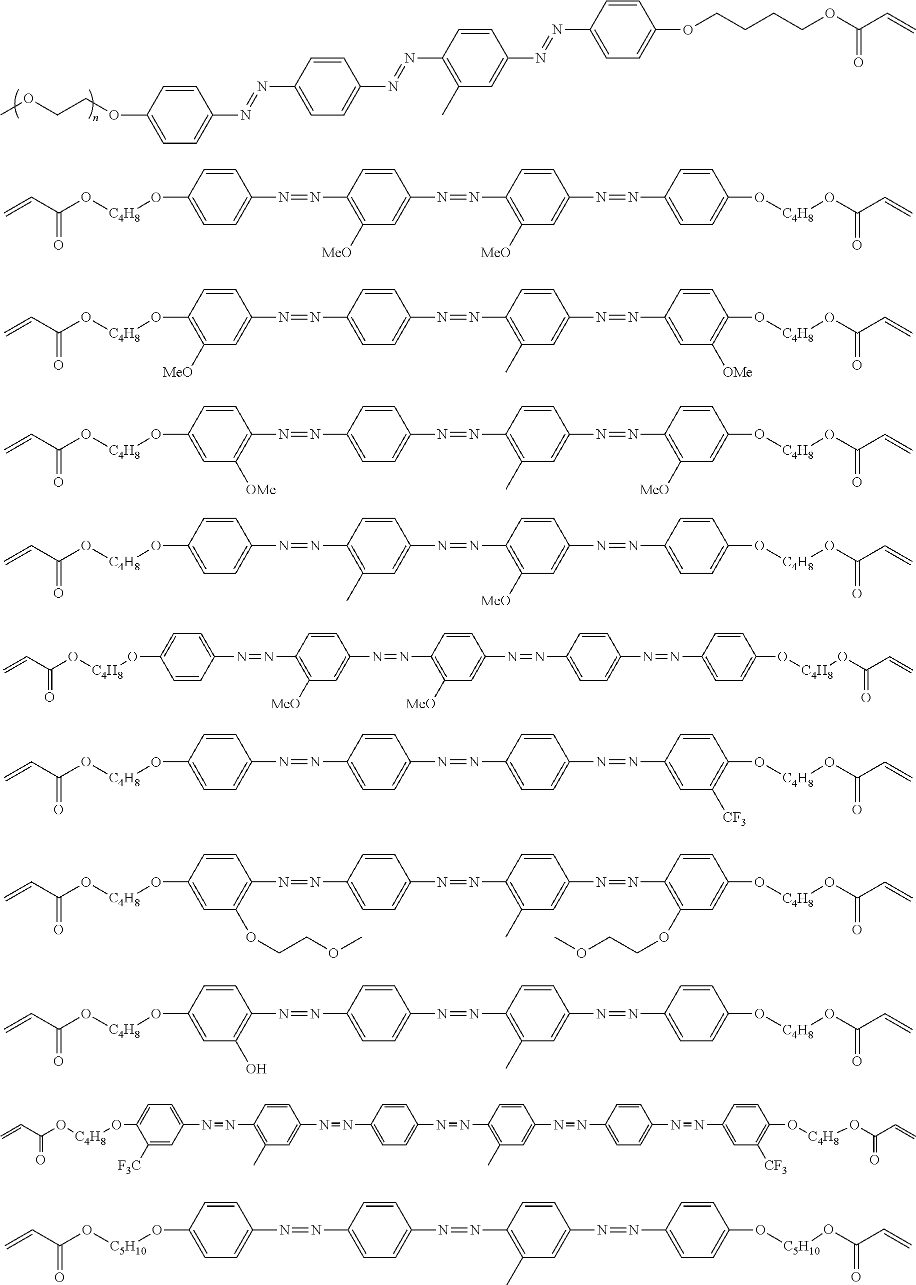

From the viewpoint that the effects of the present invention are more excellent, the content of the dichroic substance is preferably 40% by mass or less and more preferably 30% by mass or less with respect to the total mass of the light absorption anisotropic film.

From the viewpoint that the alignment degree is excellent, the content of the dichroic substance is preferably 5% by mass or greater, more preferably 10% by mass or greater, and still more preferably 15% by mass or greater with respect to the total mass of the light absorption anisotropic film.

The content of the first dichroic azo coloring agent compound is preferably in a range of to 90 parts by mass and more preferably in a range of 45 to 75 parts by mass with respect to 100 parts by mass of the total content of the dichroic substance in the composition for forming a light absorption anisotropic film.

The content of the second dichroic azo coloring agent compound is preferably in a range of 6 to 50 parts by mass and more preferably in a range of 8 to 35 parts by mass with respect to 100 parts by mass of the total content of the dichroic substance in the composition for forming a light absorption anisotropic film.

The content of the third dichroic azo coloring agent compound is preferably in a range of 3 to 35 parts by mass and more preferably in a range of 5 to 30 parts by mass with respect to 100 parts by mass of the total content of the dichroic substance in the composition for forming a light absorption anisotropic film.

The content ratio between the first dichroic azo coloring agent compound, the second dichroic azo coloring agent compound, and the third dichroic azo coloring agent compound used as necessary can be optionally set in order to adjust the tint of the light absorption anisotropic film. Here, the content ratio of the second dichroic azo coloring agent compound to the first dichroic azo coloring agent compound (second dichroic azo coloring agent compound/first dichroic azo coloring agent compound) is preferably in a range of 0.1 to 10, more preferably in a range of 0.2 to 5, and particularly preferably in a range of 0.3 to 0.8 in terms of moles. In a case where the content ratio of the second dichroic azo coloring agent compound to the first dichroic azo coloring agent compound is in the above-described ranges, the alignment degree is increased.

[Liquid Crystal Compound]

It is preferable that the light absorption anisotropic film according to the embodiment of the present invention further contains a liquid crystal compound. In this manner, the dichroic substance can be aligned with a high alignment degree while the precipitation of the dichroic substance is restrained.

Both a polymer liquid crystal compound and a low-molecular-weight liquid crystal compound can be used as the liquid crystal compound, and it is preferable that the liquid crystal compound contains a polymer liquid crystal compound from the viewpoint of increasing the alignment degree. Further, as the liquid crystal compound, a polymer liquid crystal compound and a low-molecular-weight liquid crystal compound may be used in combination.

Here, “polymer liquid crystal compound” denotes a liquid crystal compound having a repeating unit in the chemical structure.

Here, “low-molecular-weight liquid crystal compound” denotes a liquid crystal compound having no repeating units in the chemical structure.

Examples of the polymer liquid crystal compound include thermotropic liquid crystal polymers described in JP2011-237513A and polymer liquid crystal compounds described in paragraphs to of WO2018/199096A.

Examples of the low-molecular-weight liquid crystal compound include liquid crystal compounds described in paragraphs to of JP2013-228706A. Among these, a liquid crystal compound exhibiting smectic properties is preferable.

From the viewpoint of further improving the alignment degree of the light absorption anisotropic film to be obtained, it is preferable that the liquid crystal compound is a polymer liquid crystal compound having a repeating unit represented by Formula (1) (hereinafter, also referred to as “repeating unit (1)”).

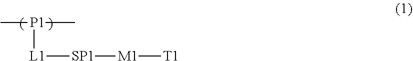

In Formula (1), P1 represents a main chain of the repeating unit, L1 represents a single bond or a divalent linking group, SP1 represents a spacer group, M1 represents a mesogen group, and T1 represents a terminal group.

Specific examples of the main chain of the repeating unit represented by P1 include groups represented by Formulae (P1-A) to (P1-D). Among these, from the viewpoints of diversity and handleability of a monomer serving as a raw material, a group represented by Formula (P1-A) is preferable.

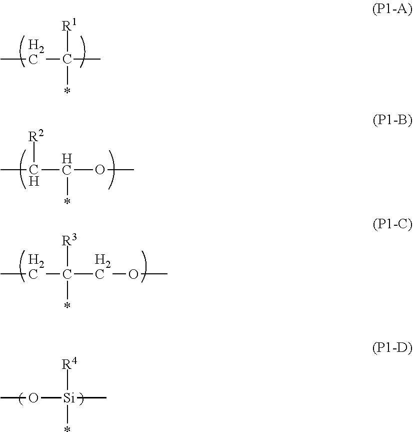

In Formulae (P1-A) to (P1-D), “*” represents a bonding position with respect to L1 in Formula (1).

In Formulae (P1-A) to (P1-D), R¹, R², R³, and R⁴ each independently represent a hydrogen atom, a halogen atom, a cyano group, an alkyl group having 1 to 10 carbon atoms, or an alkoxy group having 1 to 10 carbon atoms. The alkyl group may be a linear or branched alkyl group or an alkyl group having a cyclic structure (cycloalkyl group). Further, the number of carbon atoms of the alkyl group is preferably in a range of 1 to 5.

It is preferable that the group represented by Formula (P1-A) is a unit of a partial structure of poly(meth)acrylic acid ester obtained by polymerization of (meth)acrylic acid ester.

It is preferable that the group represented by Formula (P1-B) is an ethylene glycol unit formed by ring-opening polymerization of an epoxy group of a compound containing the epoxy group.

It is preferable that the group represented by Formula (P1-C) is a propylene glycol unit formed by ring-opening polymerization of an oxetane group of a compound containing the oxetane group.

It is preferable that the group represented by Formula (P1-D) is a siloxane unit of a polysiloxane obtained by polycondensation of a compound containing at least one of an alkoxysilyl group or a silanol group. Here, examples of the compound containing at least one of an alkoxysilyl group or a silanol group include a compound containing a group represented by Formula SiR¹⁴(OR¹⁵)₂—. In the formula, R¹⁴ has the same definition as that for R¹⁴ in Formula (P1-D), and a plurality of R¹⁵'s each independently represent a hydrogen atom or an alkyl group having 1 to 10 carbon atoms.

In Formula (1), L1 represents a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom or an alkyl group having 1 to 6 carbon atoms which may have a substituent.

In a case where P1 represents a group represented by Formula (P1-A), from the viewpoint of further increasing the alignment degree of the light absorption anisotropic film, it is preferable that L1 represents a group represented by —C(O)O—.

In a case where P1 represents a group represented by any of Formulae (P1-B) to (P1-D), from the viewpoint of further increasing the alignment degree of the light absorption anisotropic film, it is preferable that L1 represents a single bond.

In Formula (1), from the viewpoints of easily exhibiting liquid crystallinity and the availability of raw materials, it is preferable that the spacer group represented by SP1 has at least one structure selected from the group consisting of an oxyethylene structure, an oxypropylene structure, a polysiloxane structure, and an alkylene fluoride structure.

Here, as the oxyethylene structure represented by SP1, a group represented by *—(CH₂—CH₂O)ₙ₁—* is preferable. In the formula, n1 represents an integer of 1 to 20, and “*” represents a bonding position with respect to L1 or M1 in Formula (1). From the viewpoint of further increasing the alignment degree of the light absorption anisotropic film, n1 represents preferably an integer of 2 to 10, more preferably an integer of 2 to 4, and most preferably 3.

Further, from the viewpoint of further increasing the alignment degree of the light absorption anisotropic film, a group represented by *—(CH(CH₃)—CH₂O)ₙ₂—* is preferable as the oxypropylene structure represented by SP1. In the formula, n2 represents an integer of 1 to 3, and * represents a bonding position with respect to L1 or M1.

Further, from the viewpoint that the alignment degree of the light absorption anisotropic film is more excellent, a group represented by *—(Si(CH₃)₂—O)ₙ₃—* is preferable as the polysiloxane structure represented by SP1. In the formula, n3 represents an integer of 6 to 10, and * represents a bonding position with respect to L1 or M1.

Further, from the viewpoint of further increasing the alignment degree of the light absorption anisotropic film, a group represented by *—(CF₂—CF₂)ₙ₄—* is preferable as the alkylene fluoride structure represented by SP1. In the formula, n4 represents an integer of 6 to 10, and * represents a bonding position with respect to L1 or M1.

In Formula (1), the mesogen group represented by M1 is a group showing a main skeleton of a liquid crystal molecule that contributes to liquid crystal formation. A liquid crystal molecule exhibits liquid crystallinity which is in an intermediate state (mesophase) between a crystal state and an isotropic liquid state. The mesogen group is not particularly limited, and for example, particularly description on pages 7 to 16 of “Flussige Kristalle in Tabellen II” (VEB Deutsche Verlag fur Grundstoff Industrie, Leipzig, 1984) and particularly the description in Chapter 3 of “Liquid Crystal Handbook” (Maruzen, 2000) edited by Liquid Crystal Handbook Editing Committee can be referred to.

As the mesogen group, for example, a group having at least one cyclic structure selected from the group consisting of an aromatic hydrocarbon group, a heterocyclic group, and an alicyclic group is preferable.

From the viewpoint of further increasing the alignment degree of the light absorption anisotropic film, the mesogen group contains preferably an aromatic hydrocarbon group, more preferably two to four aromatic hydrocarbon groups, and still more preferably three aromatic hydrocarbon groups.

From the viewpoints of exhibiting the liquid crystallinity, adjusting the liquid crystal phase transition temperature, and the availability of raw materials and synthetic suitability and from the viewpoint of further increasing the alignment degree of the light absorption anisotropic film, a group represented by Formula (M1-A) or Formula (M1-B) is preferable, and a group represented by Formula (M1-B) is more preferable as the mesogen group.

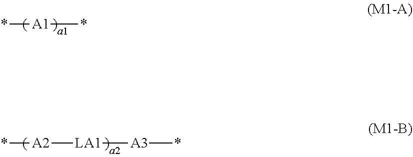

In Formula (M1-A), A1 represents a divalent group selected from the group consisting of an aromatic hydrocarbon group, a heterocyclic group, and an alicyclic group. These groups may be substituted with an alkyl group, a fluorinated alkyl group, an alkoxy group, or a substituent.

It is preferable that the divalent group represented by A1 is a 4- to 6-membered ring. Further, the divalent group represented by A1 may be a monocycle or a fused ring.

Further, “*” represents a bonding position with respect to SP1 or T1.

Examples of the divalent aromatic hydrocarbon group represented by A1 include a phenylene group, a naphthylene group, a fluorene-diyl group, an anthracene-diyl group, and a tetracene-diyl group. From the viewpoints of design diversity of a mesogenic skeleton and the availability of raw materials, a phenylene group or a naphthylene group is preferable, and a phenylene group is more preferable.

The divalent heterocyclic group represented by A1 may be any of aromatic or non-aromatic, but a divalent aromatic heterocyclic group is preferable as the divalent heterocyclic group from the viewpoint of further improving the alignment degree.

The atoms other than carbon constituting the divalent aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the divalent aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 represents 2 or greater, a plurality of A1's may be the same as or different from each other.

In Formula (M1-B), A2 and A3 each independently represent a divalent group selected from the group consisting of an aromatic hydrocarbon group, a heterocyclic group, and an alicyclic group. Specific examples and preferred embodiments of A2 and A3 are the same as those for A1 in Formula (M1-A), and thus description thereof will not be repeated.

In Formula (M1-B), a2 represents an integer of 1 to 10. In a case where a2 represents 2 or greater, a plurality of A2's may be the same as or different from each other, a plurality of A3's may be the same as or different from each other, and a plurality of LA1's may be the same as or different from each other. From the viewpoint of further increasing the alignment degree of the light absorption anisotropic film, a2 represents preferably an integer of 2 or greater and more preferably 2.

In Formula (M1-B), in a case where a2 represents 1, LA1 represents a divalent linking group. In a case where a2 represents 2 or greater, a plurality of LA1's each independently represent a single bond or a divalent linking group, and at least one of the plurality of LA1's is a divalent linking group. In a case where a2 represents 2, from the viewpoint of further increasing the alignment degree of the light absorption anisotropic film, it is preferable that one of the two LA1's represents a divalent linking group and the other represents a single bond.

In Formula (M1-B), examples of the divalent linking group represented by LA1 include —O—, —(CH₂)_{g}—, —(CF₂)_{g}—, —Si(CH₃)₂—, —(Si)(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, and —C(Z)═N—N═C(Z′)— (Z, Z′, and Z″ each independently represent a hydrogen atom, a C1-C4 alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among these, from the viewpoint of further increasing the alignment degree of the light absorption anisotropic film, —C(O)O— is preferable. LA1 may represent a group obtained by combining two or more of these groups.

Specific examples of M1 include the following structures. In the following specific examples, “Ac” represents an acetyl group.

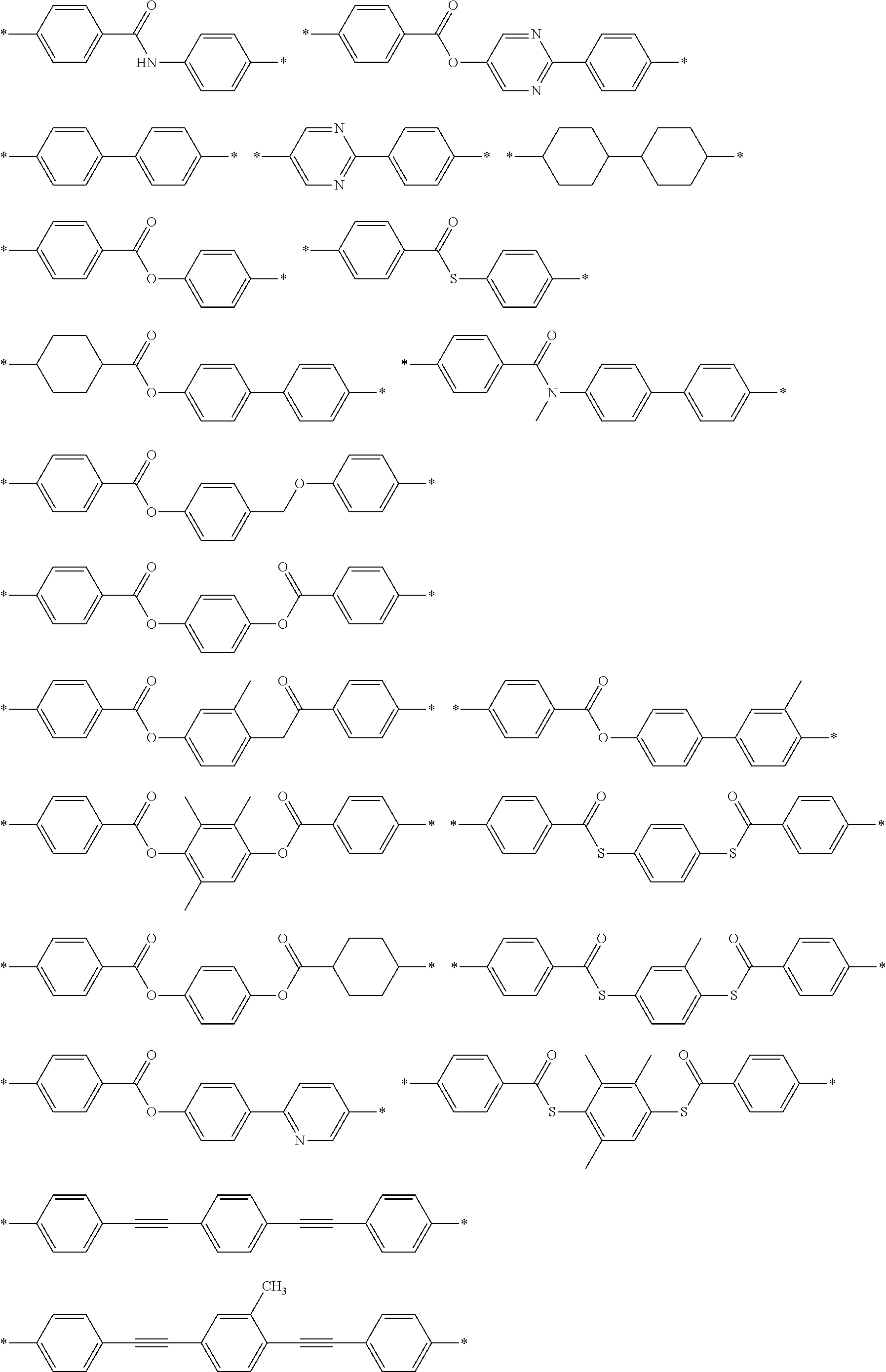

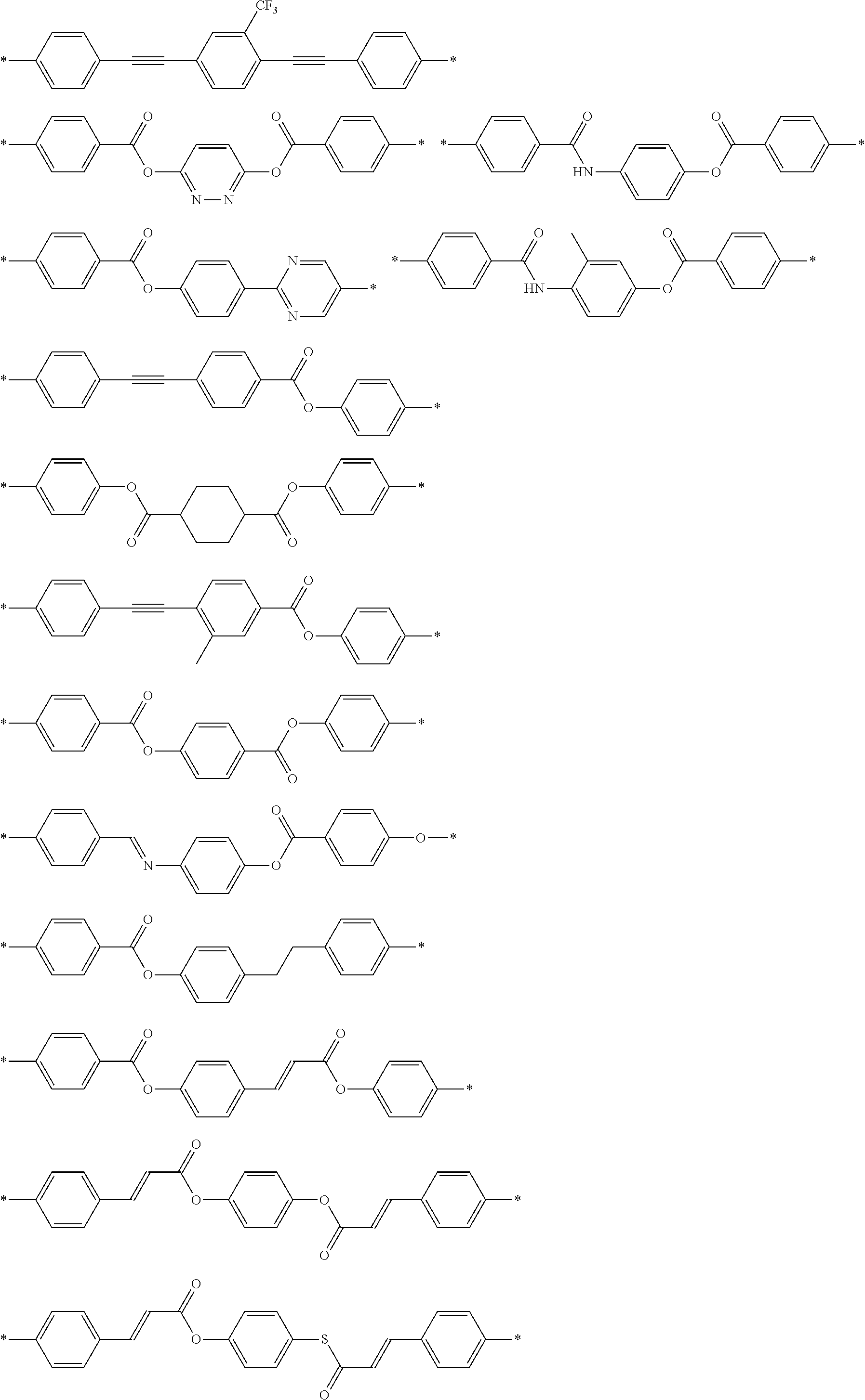

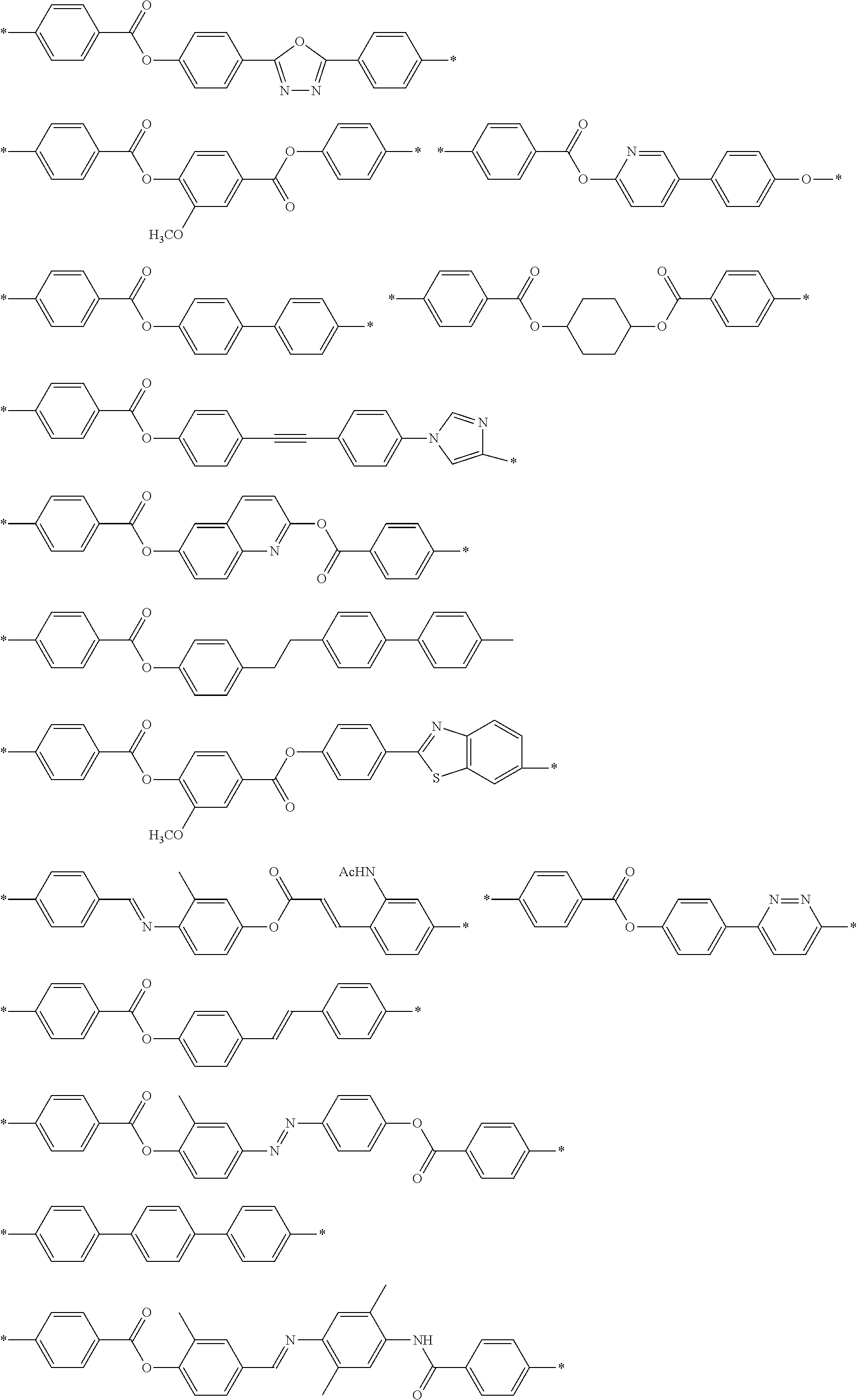

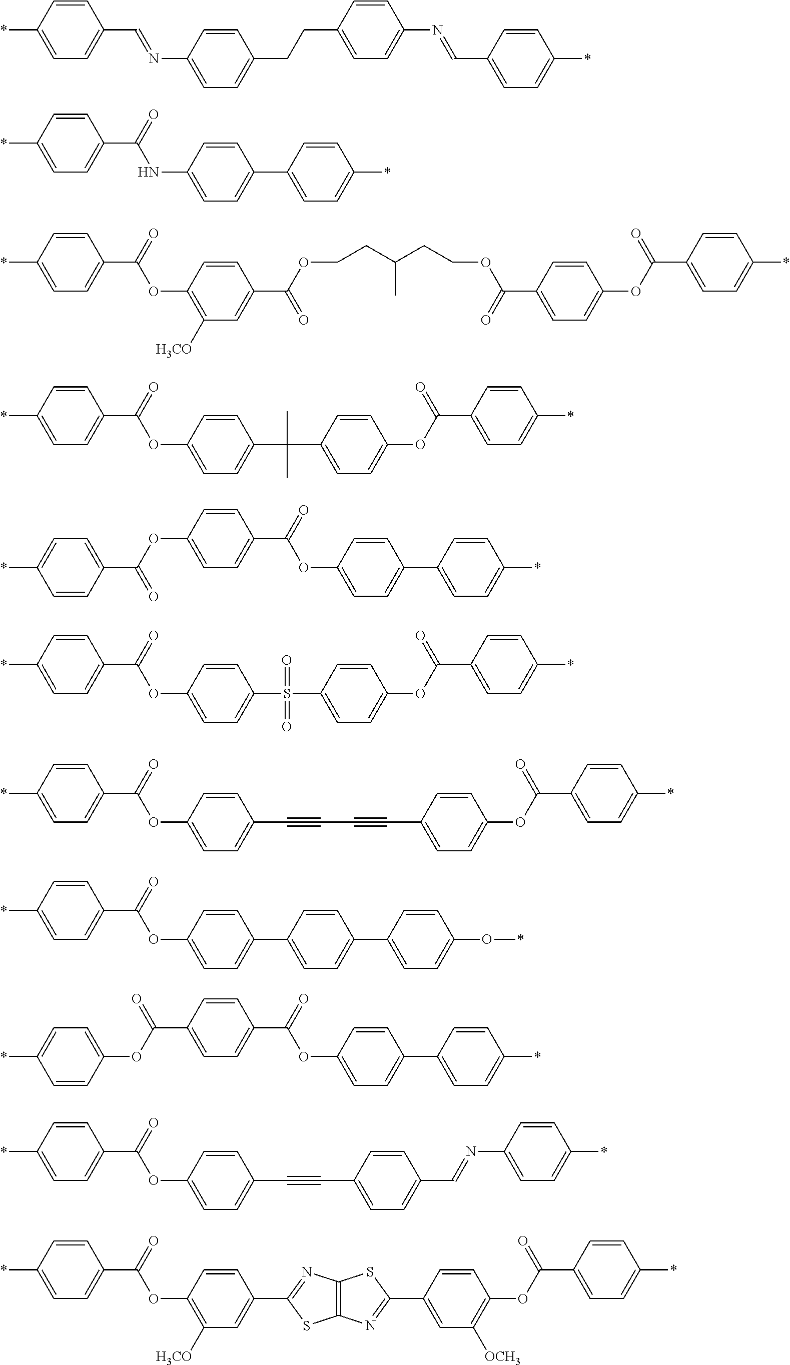

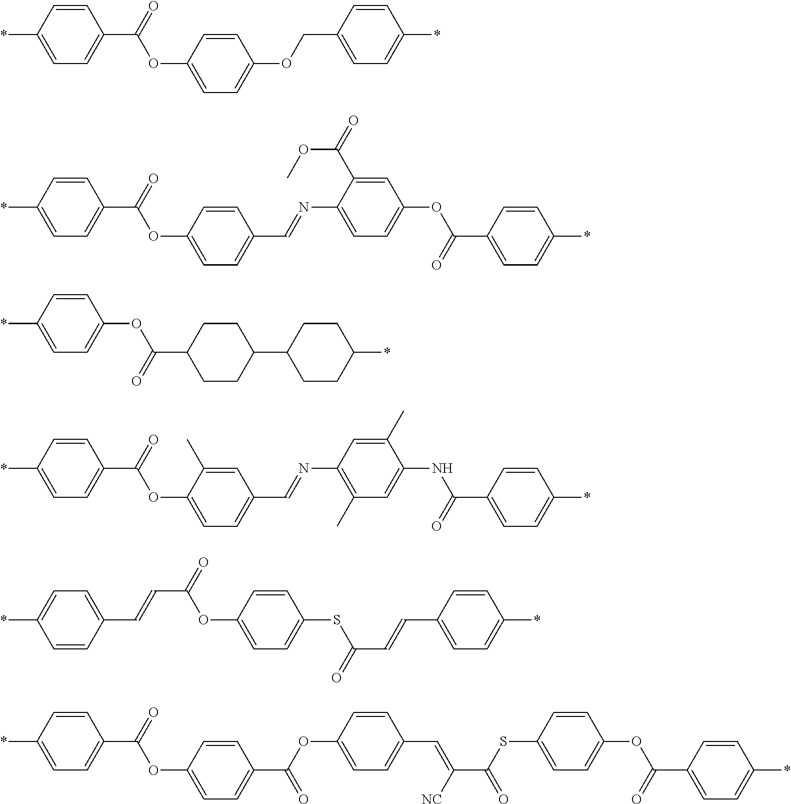

In Formula (1), examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group having 1 to 10 carbon atoms (ROC(O)—: R represents an alkyl group), an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureido group having 1 to 10 carbon atoms, and a (meth)acryloyloxy group-containing group. Examples of the (meth)acryloyloxy group-containing group include a group represented by -L-A (L represents a single bond or a linking group, specific examples of the linking group are the same as those for L1 and SP1 described above. A represents a (meth)acryloyloxy group).

From the viewpoint of further increasing the alignment degree of the light absorption anisotropic film, T1 represents preferably an alkoxy group having 1 to 10 carbon atoms, more preferably an alkoxy group having 1 to 5 carbon atoms, and still more preferably a methoxy group.

These terminal groups may be further substituted with these groups or the polymerizable groups described in JP2010-244038A.

From the viewpoint of further enhancing the adhesiveness of the film to the adjacent layer and improving the cohesive force of the film, it is preferable that T1 represents a polymerizable group.

Here, the polymerizable group is not particularly limited, but a polymerizable group capable of radical polymerization or cationic polymerization is preferable.

As the radically polymerizable group, a generally known radically polymerizable group can be used, and suitable examples thereof include an acryloyl group and a methacryloyl group. In this case, an acryloyl group is generally known to have a high polymerization rate and therefore the acryloyl group is preferable from the viewpoint of improving productivity, but a methacryloyl group can also be used as the polymerizable group.

As the cationically polymerizable group, a generally known cationically polymerizable group can be used, and specific examples thereof include an alicyclic ether group, a cyclic acetal group, a cyclic lactone group, a cyclic thioether group, a spiroorthoester group, and a vinyloxy group. Among those, an alicyclic ether group or a vinyloxy group is suitable, and an epoxy group, an oxetanyl group, or a vinyloxy group is preferable.

From the viewpoint of further increasing the alignment degree of the light absorption anisotropic film, the weight-average molecular weight (Mw) of the polymer liquid crystal compound having a repeating unit represented by Formula (1) is preferably in a range of 1,000 to 500,000 and more preferably in a range of 2,000 to 300,000. In a case where the Mw of the polymer liquid crystal compound is in the above-described range, the polymer liquid crystal compound is easily handled.

In particular, from the viewpoint of suppressing cracking during the coating, the weight-average molecular weight (Mw) of the polymer liquid crystal compound is preferably 10000 or greater and more preferably in a range of 10,000 to 300,000.

In addition, from the viewpoint of the temperature latitude of the alignment degree, the weight-average molecular weight (Mw) of the polymer liquid crystal compound is preferably less than 10,000 and more preferably 2,000 or greater and less than 10,000.

Here, the weight-average molecular weight and the number average molecular weight in the present invention are values measured by the gel permeation chromatography (GPC) method.
Solvent (eluent): N-methylpyrrolidone
Device name: TOSOH HLC-8220GPC
Column: Connect and use three of TOSOH TSKgel Super AWM-H (6 mm×15 cm)
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2,800,000 to 1,050 (Mw/Mn=1.03 to 1.06) are used.

In a case where the light absorption anisotropic film contains a liquid crystal compound, from the viewpoint of further increasing the alignment degree of the light absorption anisotropic film, the content of the liquid crystal compound is preferably in a range of 60% to 95% by mass, more preferably in a range of 70% to 90% by mass, and still more preferably in a range of 75% to 85% by mass with respect to the total mass of the light absorption anisotropic film.

In a case where the light absorption anisotropic film contains a polymer liquid crystal compound, from the viewpoint of further increasing the alignment degree of the light absorption anisotropic film, the content of the polymer liquid crystal compound is preferably in a range of 30% to 80% by mass, more preferably in a range of 40% to 70% by mass, and still more preferably in a range of 50% to 60% by mass with respect to the total mass of the light absorption anisotropic film.

In a case where the light absorption anisotropic film contains a low-molecular-weight liquid crystal compound, from the viewpoint of further increasing the alignment degree of the light absorption anisotropic film, the content of the low-molecular-weight liquid crystal compound is preferably in a range of 5% to 50% by mass, more preferably in a range of 10% to 40% by mass, and still more preferably in a range of 20% to 30% by mass with respect to the total mass of the light absorption anisotropic film.

[Surfactant Having Fluorine Atom and Log P Value of 5.2 or Less]

It is preferable that the light absorption anisotropic film according to the embodiment of the present invention contains a surfactant having a fluorine atom and a log P value of 5.2 or less (hereinafter, also referred to as “specific surfactant”).

In a case where the light absorption anisotropic film according to the embodiment of the present invention contains the specific surfactant, the light absorption anisotropic film having a front surface and a rear surface with different polarization degrees can be easily obtained. The reason for this is assumed as follows. The specific surfactant has a fluorine atom and is thus unevenly distributed on one surface side (air interface side during the production) of the light absorption anisotropic film. It is assumed that since the specific surfactant unevenly distributed on one surface side of the light absorption anisotropic film by the action of the fluorine atom has a log P value of 5.2 or less as a hydrophilic property, the specific surfactant is unlikely to be mixed with a dichroic substance, and as a result, the aligning properties of the dichroic substance on one surface side of the light absorption anisotropic film are disturbed.

The specific surfactant is not particularly limited as long as the surfactant has a fluorine atom and a log P value of 5.2 or less, but from the viewpoint that light absorption anisotropic film having a front surface and a rear surface with different polarization degrees is more easily obtained, a compound that has a repeating unit having a fluorine atom is preferable, and a surfactant having at least one of a repeating unit represented by Formula (F-1) (hereinafter, also referred to as “repeating unit F-1”) or a repeating unit represented by Formula (F-2) (hereinafter, also referred to as “repeating unit F-2”) is more preferable.

The content of the repeating unit having a fluorine atom is preferably in a range of 10% to 98% by mass, more preferably in a range of 15% to 97% by mass, still more preferably in a range of 20% to 90% by mass, and particularly preferably in a range of 25% to 80% by mass with respect to all repeating units (100% by mass) of the specific surfactant. In a case where the content of the repeating unit having a fluorine atom is in the above-described ranges, the effects of the present invention are more excellent.

The specific surfactant may have only one or two or more kinds of the repeating units having a fluorine atom. In a case where the specific surfactant has two or more kinds of repeating units having a fluorine atom, the content of the repeating units having a fluorine atom denotes the total content of the repeating units having a fluorine atom.

<Repeating Unit F-1>

The repeating unit F-1 is a repeating unit represented by Formula (F-1).

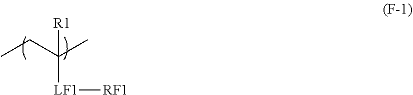

In Formula (F-1), LF1 represents a single bond or a divalent linking group, R1 represents a hydrogen atom, a fluorine atom, a chlorine atom, or an alkyl group having 1 to 20 carbon atoms, and RF1 represents a group containing at least one of groups (a) to (e), (a) a group represented by Formula (1), (2), or (3), (b) a perfluoropolyether group, (c) an alkyl group having 1 to 20 carbon atoms, which has a hydrogen bond between a proton-donating functional group and a proton-accepting functional group and in which at least one carbon atom has a fluorine atom as a substituent, (d) a group represented by Formula (1-d), and (e) a group represented by Formula (1-e).

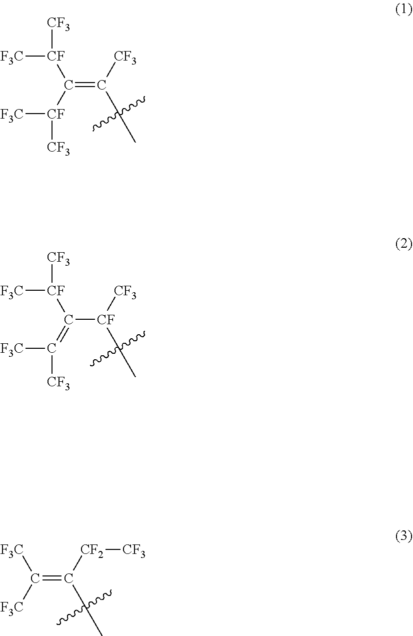

In Formula (F-1), R1 represents preferably a hydrogen atom, a fluorine atom, or an alkyl group having 1 to 4 carbon atoms and more preferably a hydrogen atom or a methyl group.

In Formula (F-1), LF1 represents a single bond or a divalent linking group, more specifically, a group represented by -LW-SPW—(LW represents a divalent linking group, and SPW represents a divalent spacer group), an aromatic hydrocarbon group having 4 to 20 carbon atoms, a cyclic alkylene group having 4 to 20 carbon atoms, or a heterocyclic group having 1 to carbon atoms, preferably a linear, branched, or cyclic alkylene group having 1 to 20 carbon atoms or an aromatic hydrocarbon group having 4 to 20 carbon atoms, more preferably a group having —O—, —C(O)—O—, —C(O)—NH—, or —O—C(O)—, and still more preferably —C(O)—O-alkylene group-. The alkylene group in the —C(O)—O-alkylene group— may be any of a linear structure or a branched structure, and the number of carbon atoms thereof is preferably in a range of 1 to more preferably in a range of 1 to 10, and still more preferably in a range of 1 to 5. The alkylene group may be further substituted with a substituent, and a halogen atom is preferable, and a fluorine atom is more preferable as the substituent.

Examples of the divalent linking group represented by LW include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ each independently represent a hydrogen atom, an alkyl group having 1 to 4 carbon atoms, a cycloalkyl group, an aryl group, a cyano group, or a halogen atom), —N═N—, —S—, —S(O)—, —S(O)(O)—, —(O)S(O)O—, —O(O)S(O)O—, —SC(O)—, and —C(O)S—. LW may represent a group in which two or more of these groups are combined (hereinafter, also referred to as “L-C”).

Examples of the divalent spacer group represented by SPW include a linear, branched, or cyclic alkylene group having 1 to 50 carbon atoms, and a heterocyclic group having 1 to 20 carbon atoms.

The carbon atoms of the alkylene group and the heterocyclic group may be substituted with —O—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ each independently represent a hydrogen atom, an alkyl group having 1 to 4 carbon atoms, a cycloalkyl group, an aryl group, a cyano group, or a halogen atom), —N═N—, —S—, —C(S)—, —S(O)—, —SO₂—, —(O)S(O)O—, —O(O)S(O)O—, —SC(O)—, —C(O)S—, or a group obtained by combining two or more of these groups (hereinafter, also referred to as “SP—C”).

Further, the hydrogen atom of the alkylene group and the hydrogen atom of the heterocyclic group may be substituted with a halogen atom, a cyano group, —Z^{H}, —OH—, —OZ^{H}, —COOH, —C(O)Z^{H}, —C(O)OZ^{H}, —OC(O)Z^{H}, —OC(O)OZ^{H}, —NZ^{H}Z^{H′}, —NZ^{H}C(O)Z^{H′}, —NZ^{H}C(O)OZ^{H′}, —C(O)NZ^{H}Z^{H′}, —OC(O)NZ^{H}Z^{H′}, —NZ^{H}C(O)NZ^{H′}OZ^{H″}, —SH, —SZ^{H}, —C(S)Z^{H}, —C(O)SZ^{H}, or —SC(O)Z^{H} (hereinafter, also referred to as “SP—H”). Here, Z^{H}, Z^{H′}, and Z^{H″} each independently represent an alkyl group having 1 to 10 carbon atoms, a halogenated alkyl group, or -L-CL (L represents a single bond or a divalent linking group, and specific examples of the divalent linking group are the same as those of LW and SPW described above, CL represents a crosslinkable group and preferably a crosslinkable group represented by any of Formulae (P-1) to (P-30)).

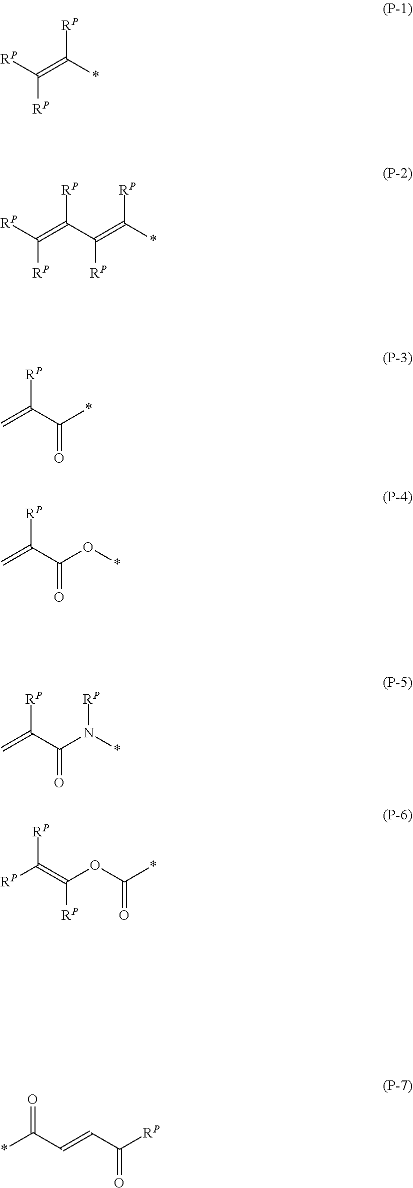

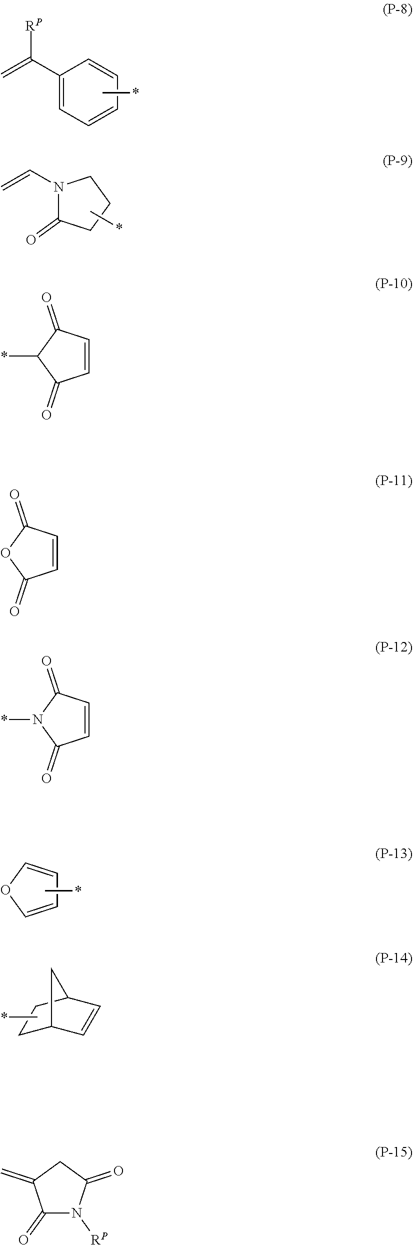

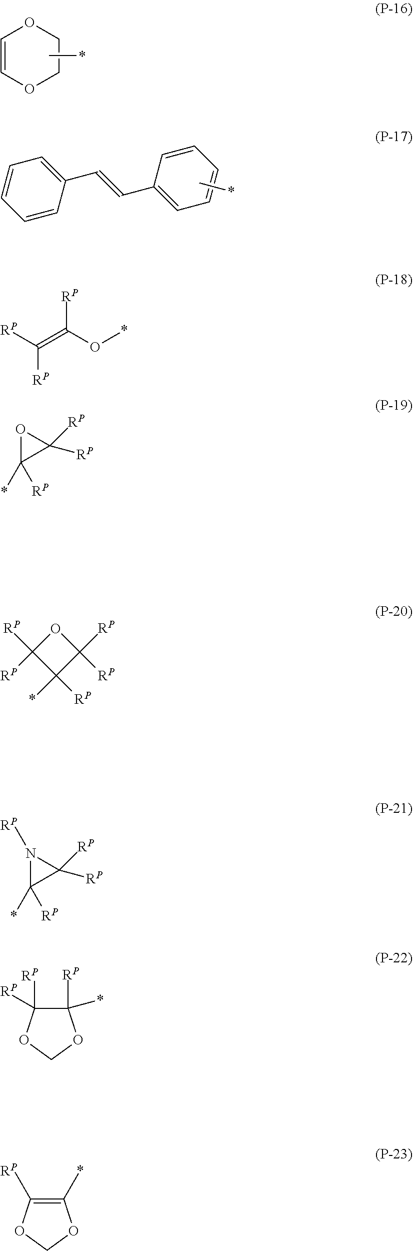

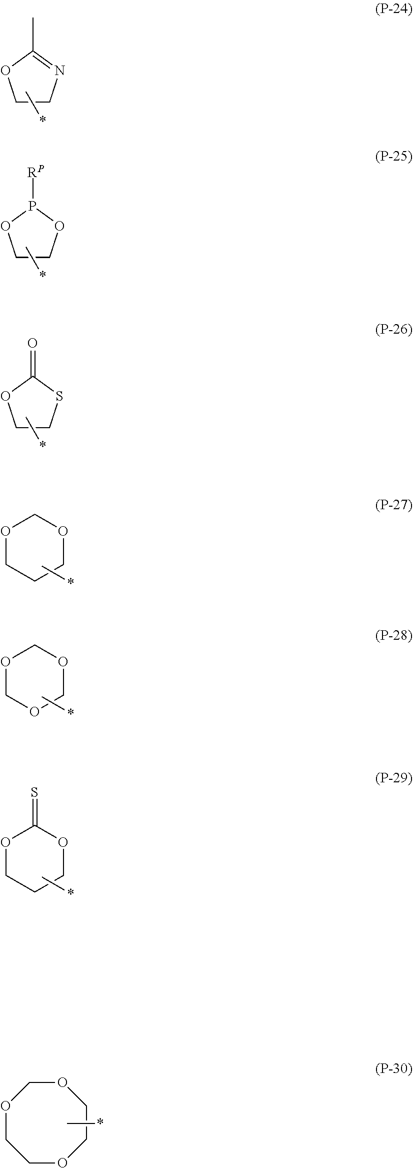

((a) Repeating Unit Containing Group Represented by Formula (1), (2), or (3))

In a case where RF1 of Formula (F-1) contains a group represented by Formula (1), (2), or (3), it is also preferable that Formula (F-1) represents a repeating unit represented by Formula (4).

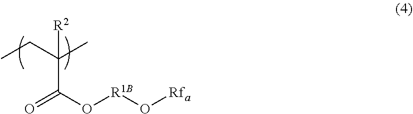

In Formula (4), Rfₐ represents a group represented by Formula (1), (2), or (3).

In Formula (4), R² has the same definition as that for R¹ in Formula (F-1), and it is preferable that R² represents a hydrogen atom or a methyl group.

In Formula (4), R^{1B} represents a divalent group having 2 to 50 carbon atoms. The divalent group having 2 to 50 carbon atoms represented by R^{1B} may have a heteroatom and may be an aromatic group, a heteroaromatic group, a heterocyclic group, an aliphatic group, or an alicyclic group.

Specific examples of R^{1B} include the following groups.

—(CH₂)ₙ₁— (n1=2 to 50);

—X—Y—(CH₂)ₙ₂— (n2=2 to 43);

—X—(CH₂)ₙ₃— (n3=1 to 44);

—CH₂CH₂(OCH₂CH₂)ₙ₄— (n4=1 to 24); and

—XCO(OCH₂CH₂)ₙ₅— (n5=1 to 21)

In the above-described formulae, X represents phenylene, biphenylene, or naphthylene which may have one to three substituents selected from the group consisting of an alkyl group having 1 to 3 carbon atoms (such as a methyl group, an ethyl group, or a propyl group), an alkoxy group having 1 to 4 carbon atoms (such as a methoxy group, an ethoxy group, a propoxy group, or a butoxy group), and a halogen atom (such as F, Cl, Br, or I). Y represents —O—CO—, —CO—O—, —CONH—, or —NHCO—.

X represents preferably 1,2-phenylene, 1,3-phenylene, or 1,4-phenylene and more preferably 1,4-phenylene.

Specific examples of a particularly preferable divalent group having 2 to 50 carbon atoms represented by R^{1B} include divalent groups having the following structures. —(CH₂)ₙ₁— (n1=2 to 10);

—C₆H₄OCO(CH₂)ₙ₁— (n2=2 to 10);

—C₆H₄(CH₂)ₙ₃— (n3=1 to 10);

—CH₂CH₂(OCH₂CH₂)ₙ₄— (n4=1 to 10); and

—C₆H₄CO(OCH₂CH₂)ₙ₅— (n5=1 to 10)

In Formula (4), R² represents a hydrogen atom or a methyl group.

((b) Repeating Unit Containing Perfluoropolyether Group)

In Formula (F-1), it is also preferable that RF1 contains a perfluoropolyether group.

The perfluoropolyether group is a divalent group in which a plurality of fluorocarbon groups are bonded to each other via an ether bond. It is preferable that the perfluoropolyether group is a divalent group in which a plurality of perfluoroalkylene groups are bonded to each other via an ether bond.

The perfluoropolyether group may be a linear structure, a branched structure, or a cyclic structure, and is preferably a linear structure or a branched structure and more preferably a linear structure.

In a case where RF1 of Formula (F-1) has a repeating unit containing a perfluoropolyether group, it is preferable that Formula (F-1) represents a constitutional unit represented by Formula (I-b).

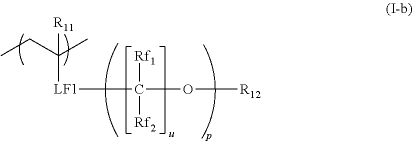

In Formula (I-b), LF1 represents the same group as in Formula (F-1). Ru represents a hydrogen atom, a fluorine atom, a chlorine atom, or an alkyl group having 1 to 20 carbon atoms. Rf₁ and Rf₂ each independently represent a fluorine atom or a perfluoroalkyl group. In a case where a plurality of Rf₁'s are present, the plurality of Rf₁'s may be the same as or different from each other. In a case where a plurality of Rf₂'s are present, the plurality of Rf₂'s may be the same as or different from each other. u represents an integer of 1 or greater. p represents an integer of 1 or greater.

R₁₂ represents a hydrogen atom or a substituent, and the substituent is not particularly limited, and examples thereof include a fluorine atom, a perfluoroalkyl group (preferably having 1 to 10 carbon atoms), an alkyl group (preferably having 1 to 10 carbon atoms), and a hydroxyalkyl group (preferably having 1 to 10 carbon atoms).

In Formula (I-b), u represents an integer of 1 or greater, preferably 1 to 10, more preferably 1 to 6, and still more preferably 1 to 3.

In Formula (I-b), p represents an integer of 1 or greater, preferably represents 1 to 100, more preferably 1 to 80, and still more preferably 1 to 60.

Further, p number of [CRf₁Rf₂]uO's may be the same as or different from each other.

(Repeating unit containing (c) alkyl group having 1 to 20 carbon atoms, which has hydrogen bond between proton-donating functional group and proton-accepting functional group and in which at least one carbon atom has fluorine atom as substituent)

In Formula (F-1), it is preferable that RF1 has an alkyl group having 1 to 20 carbon atoms, which has a hydrogen bond between a proton-donating functional group and a proton-accepting functional group and in which at least one carbon atom has a fluorine atom as a substituent (hereinafter, also referred to as “specific alkyl group c”).

In a case where RF1 in Formula (F-1) represents the specific alkyl group c, it is preferable that the repeating unit represented by Formula (F-1) is a repeating unit represented by General Formula (I-c1) or a repeating unit represented by General Formula (I-c2).

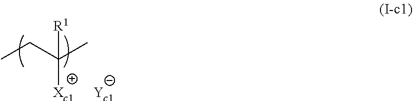

In Formula (I-c1), R¹ has the same definition as that for R¹ in Formula (F-1), and it is preferable that R¹ represents a hydrogen atom or a methyl group.

In Formula (I-c1), X_{C1}⁺ represents a group containing a proton-accepting functional group. Examples of the proton-accepting functional group include a quaternary ammonium cation and a pyridinium cation. Specific examples of X_{C1}⁺ include —C(O)—NH-L_{C1}-X_{C11}⁺, —C(O)—O-L_{C1}-X_{C11}⁺, and —X_{C12}⁺. L_{C1} represents an alkylene group having 1 to 5 carbon atoms. X_{C11}⁺ represents a quaternary ammonium cation. X_{C12}⁺ represents a pyridinium cation.

In Formula (I-c1), Y_{C1}⁻ represents a proton-donating functional group or a group containing a fluoroalkyl group. Examples of the proton-donating functional group include —C(O)O⁻ and —S(O)₂O⁻. Specific examples of Y_{C1}⁻ include R_{C1}—C(O)O⁻ and R_{C1}—S(O)₂O⁻. R_{C1} represents a fluoroalkyl group having 2 to 15 carbon atoms, a group in which one or more carbon atoms of the fluoroalkyl group having 2 to 15 carbon atoms are substituted with at least one of —O— or C(O)—, or a phenyl group having these groups as substituents.

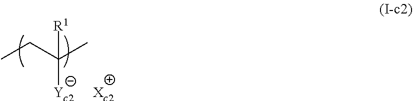

In Formula (I-c2), R¹ has the same definition as that for R¹ in Formula (F-1), and it is preferable that R¹ represents a hydrogen atom or a methyl group.

In Formula (I-c2), Y_{C2}⁻ represents a group containing a proton-donating functional group. Examples of the proton-donating functional group include —C(O)O⁻ and —S(O)₂O⁻. Specific examples of Y_{C2}⁻ include —C(O)—NH-L_{C2}-Y_{C21}⁻ and —C(O)—O-L_{C2}-Y_{C21}⁻. L_{C2} represents an alkylene group having 1 to 5 carbon atoms. Y_{C21}⁻ represents —C(O)O⁻ or —S(O)₂O⁻.

In Formula (I-c2), X_{C2}⁺ represents a proton-accepting functional group (such as a quaternary ammonium cation or a pyridinium cation) or a group containing a fluoroalkyl group. Specific examples of X_{C2}⁺ include R_{C2}—X_{C21}⁺. R_{C2} represents a fluoroalkyl group having 2 to 15 carbon atoms, a group in which one or more carbon atoms of the fluoroalkyl group having 2 to 15 carbon atoms are substituted with at least one of —O— or C(O)—, or a phenyl group having these groups as substituents. X_{C21}⁺ represents a quaternary ammonium cation.

Examples of a method of producing a repeating unit in which RF1 in Formula (F-1) represents the specific alkyl group c include a method of allowing a compound containing a proton-donating functional group described below to react with a repeating unit containing a proton-accepting functional group and a method of allowing a compound containing a proton-accepting functional group described below to react with a repeating unit containing a proton-donating functional group.

It is preferable that the compound containing a proton-donating functional group and the compound containing a proton-accepting functional group are compounds represented by any of Formulae (1-1) to (1-3).

(HB—X1)m—X3—(X2—RL)n (1-1)

(HB)—(X2—RL)n (1-2)

(HB—X1)m—(RL) (1-3)

In Formulae (1-1) and (1-3), m represents an integer of 1 to 5. Further, in Formulae (1-1) and (1-2), n represents an integer of 1 to 5. Here, the sum of m and n is an integer of 2 to 6.

Further, in Formulae (1-1) to (1-3), HB represents the above-described functional group capable of hydrogen bonding (that is, a proton-donating functional group and a proton-accepting functional group), and in a case where m represents an integer of 2 to 5, a plurality of HB's may be the same as or different from each other.

In Formulae (1-1) to (1-3), X1 and X2 each independently represent a single bond or a divalent linking group, a plurality of X1's may be the same as or different from each other in a case where m represents an integer of 2 to 5, and a plurality of X2's may be the same as or different from each other in a case where n represents an integer of 2 to 5. In Formula (1-2), a part of HB and X2 may form a ring. Further, in Formula (1-3), a part of RL and X1 may form a ring.

Examples of the divalent linking group represented by one aspect of X1 and X2 in Formulae (1-1) to (1-3) include at least one or more groups selected from the group consisting of a linear, branched, or cyclic alkylene group having 1 to 10 carbon atoms which may have a substituent, an arylene group having 6 to 12 carbon atoms which may have a substituent, an ether group (—O—), a carbonyl group (—C(═O)—), and an imino group (—NH—) which may have a substituent.

Here, examples of the substituent that the alkylene group, the arylene group, and the imino group may have include an alkyl group, an alkoxy group, a halogen atom, and a hydroxyl group. As the alkyl group, for example, a linear, branched, or cyclic alkyl group having 1 to 18 carbon atoms is preferable, an alkyl group having 1 to 8 carbon atoms (such as a methyl group, an ethyl group, a propyl group, an isopropyl group, an n-butyl group, an isobutyl group, a sec-butyl group, a t-butyl group, or a cyclohexyl group) is more preferable, an alkyl group having 1 to 4 carbon atoms is still more preferable, and a methyl group or an ethyl group is particularly preferable. As the alkoxy group, for example, an alkoxy group having 1 to 18 carbon atoms is preferable, an alkoxy group having 1 to 8 carbon atoms (such as a methoxy group, an ethoxy group, an n-butoxy group, or a methoxyethoxy group) is more preferable, an alkoxy group having 1 to 4 carbon atoms is still more preferable, and a methoxy group or an ethoxy group is particularly preferable. Examples of the halogen atom include a fluorine atom, a chlorine atom, a bromine atom, and an iodine atom. Among these, a fluorine atom and a chlorine atom are preferable.

In regard to the linear, branched, or cyclic alkylene group having 1 to 10 carbon atoms, specific examples of the linear alkylene group include a methylene group, an ethylene group, a propylene group, a butylene group, a pentylene group, a hexylene group, and a decylene group. Further, specific examples of the branched alkylene group include a dimethylmethylene group, a methylethylene group, a 2,2-dimethylpropylene group, and a 2-ethyl-2-methylpropylene group. Further, specific examples of the cyclic alkylene group include a cyclopropylene group, a cyclobutylene group, a cyclopentylene group, a cyclohexylene group, a cyclooctylene group, a cyclodecylene group, an adamantane-diyl group, a norbornane-diyl group, and an exo-tetrahydrodicyclopentadiene-diyl group.

Specific examples of the arylene group having 6 to 12 carbon atoms include a phenylene group, a xylylene group, a biphenylene group, a naphthylene group, and a 2,2′-methylenebiphenyl group. Among these, a phenylene group is preferable.

Further, in Formula (1-1), X3 represents a single bond or a divalent to hexavalent linking group. Here, examples of the divalent linking group represented by one aspect of X3 include those described as the divalent linking group represented by one aspect of X1 and X2 in Formulae (1-1) to (1-3). In addition, examples of the trivalent to hexavalent linking group represented by one aspect of X3 include structures obtained by removing three to six hydrogen atoms bonded to carbon atoms forming a ring in ring structures, for example, a cycloalkylene ring such as a cyclohexane ring or a cyclohexene ring, an aromatic hydrocarbon ring such as a benzene ring, a naphthalene ring, an anthracene ring, or a phenanthroline ring, and an aromatic heterocyclic ring such as a furan ring, a pyrrole ring, a thiophene ring, a pyridine ring, a thiazole ring, or a benzothiazole ring. Among these ring structures, a benzene ring (such as a benzene-1,2,4-yl group) is preferable.

In Formulae (1-1) to (1-3), RL represents a substituent having a fluorine atom or an alkyl group having 6 or more carbon atoms, and in a case where n represents an integer of 2 to 5, a plurality of RL's may be the same as or different from each other. Here, examples of the monovalent substituent having a fluorine atom include an alkyl group having 1 to 20 carbon atoms or an alkenyl group having 2 to 20 carbon atoms in which at least one carbon atom has a fluorine atom as a substituent.

Among the compounds represented by any of Formulae (1-1) to (1-3), specific examples of the compound containing a proton-donating functional group include a compound represented by the following formulae.

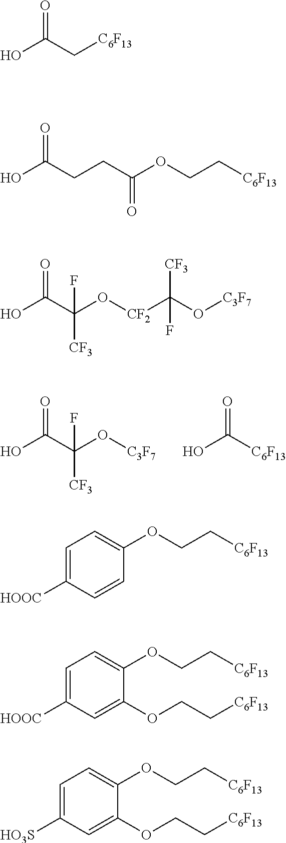

Among the compounds represented by any of Formulae (1-1) to (1-3), specific examples of the compound containing a proton-accepting functional group include compounds represented by the following formulae.

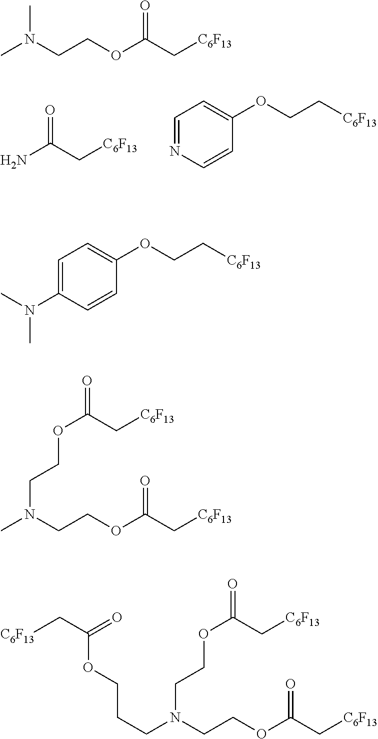

((d) Group Represented by Formula (1-d))

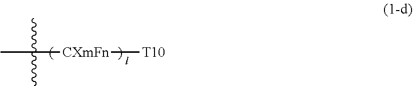

In Formula (1-d), X represents a hydrogen atom or a substituent (preferably, a group represented by “SP—H”), T10 represents a terminal group (preferably the same group as T1 described above), l represents an integer of 1 to 20, m represents an integer of 0 to 2, n represents an integer of 1 to 2, and m+n is 2.

In a case where l represents 2 or greater, a plurality of —(CXmFn)-'s may be the same as or different from each other.

X represents preferably a hydrogen atom, a halogen atom, an alkyl group having 1 to 10 carbon atoms, an alkoxy group having 1 to 10 carbon atoms, a cyano group, a nitro group, —OZ^{H}, —C(O)Z^{H}, —C(O)OZ^{H}, —OC(O)Z^{H}, —NZ^{H}Z^{H′}, —NZ^{H}C(O)Z^{H′}, —NZ^{H}C(O)OZ^{H′}, —C(O)NZ^{H}Z^{H′}, or —OC(O)NZ^{H}Z^{H′} and more preferably a hydrogen atom, a fluorine atom, —Z^{H}, or —OZ^{H}. Z^{H} and Z^{H′} each independently represent a hydrogen atom, a halogen atom, an alkyl group having 1 to 10 carbon atoms, an alkoxy group having 1 to 10 carbon atoms, a cyano group, or a nitro group, and the number of carbon atoms thereof is preferably in a range of 1 to 4.

T10 represents preferably a hydrogen atom, a halogen atom, an alkyl group having 1 to 10 carbon atoms, a cyano group, a nitro group, —OZ^{H}, —C(O)Z^{H}, —C(O)OZ^{H}, —OC(O)Z^{H}, or a crosslinkable group represented by any of Formulae (P-1) to (P-30) and more preferably a hydrogen atom, a fluorine atom, an alkyl group having 1 to 10 carbon atoms, a cyano group, a nitro group, —OZ^{H}, a vinyl group, a (meth)acryl group, a (meth)acrylamide group, a styryl group, a vinyl ether group, an epoxy group, or an oxetanyl group. Z^{H} represents a hydrogen atom, a halogen atom, an alkyl group having 1 to 10 carbon atoms, an alkoxy group having 1 to 10 carbon atoms, a cyano group, or a nitro group, and the number of carbon atoms is preferably in a range of 1 to 4.

((e) Group Represented by Formula (1-e))

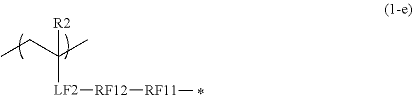

In Formula (1-e), R2 represents a hydrogen atom, a fluorine atom, a chlorine atom, or an alkyl group having 1 to 20 carbon atoms, LF2 represents a single bond or a divalent linking group, RF11 and RF12 each independently represent a perfluoropolyether group, and * represents a bonding position with respect to LF1 in Formula (F-1).

Suitable Aspects of R2 and LF2 are Respectively the Same as Those of R1 and LF1 of Formula (F-1).

Suitable aspects of RF11 and RF12 are the same as those of RF1 of Formula (F-1).

Specific examples of the monomer forming the repeating unit represented by Formula (F-1) include structures represented by Formulae (F1-1) to (F1-41), and the present invention is not limited thereto.

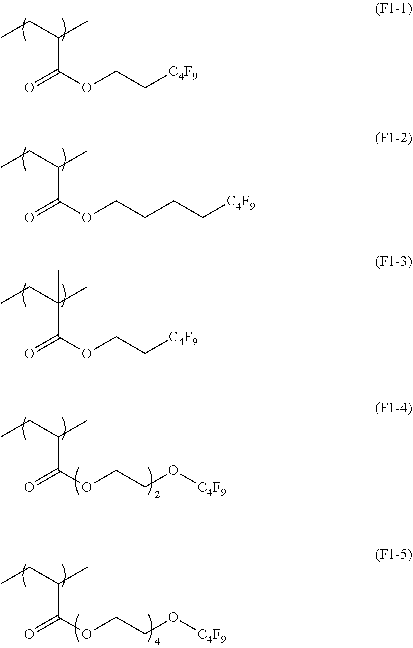

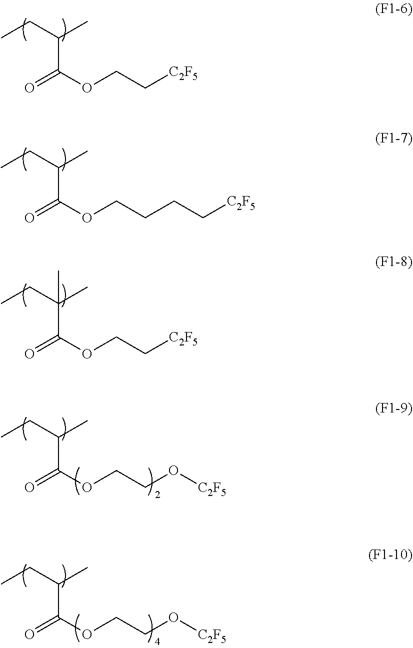

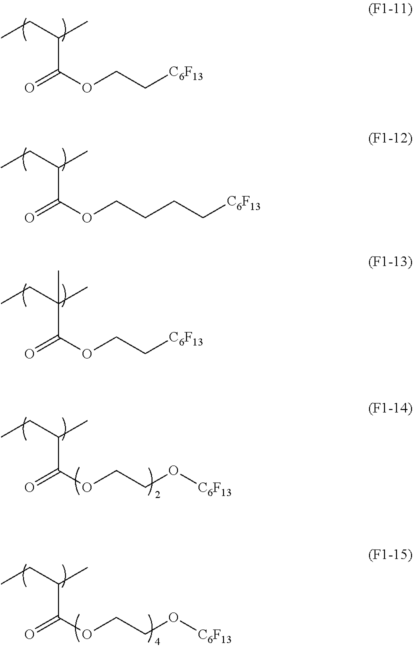

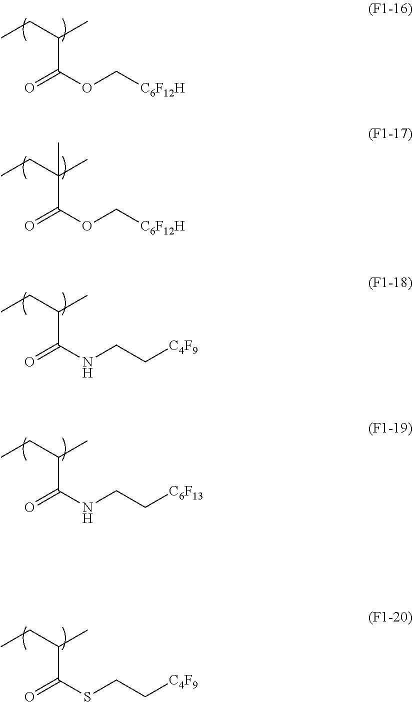

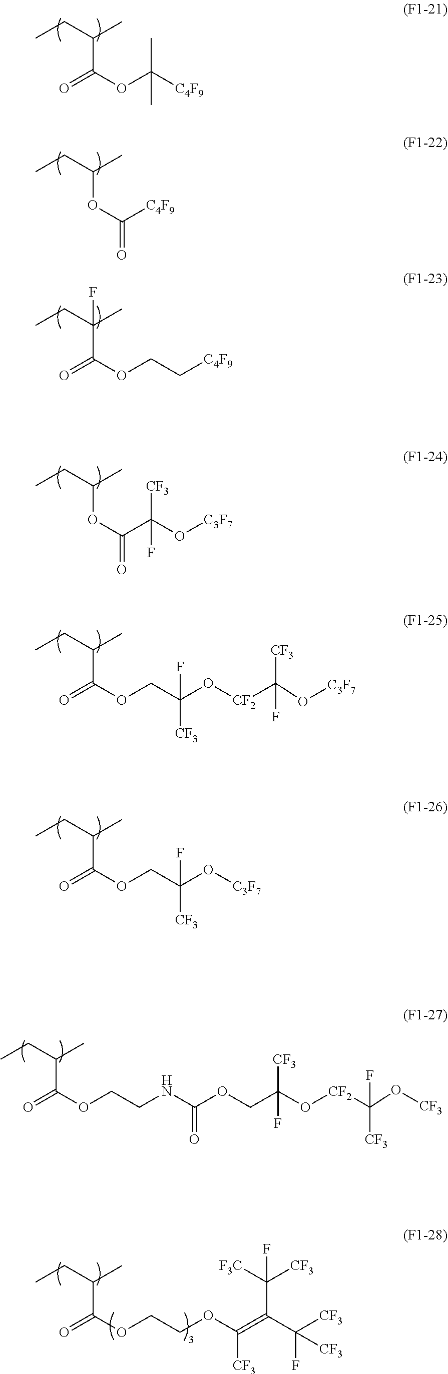

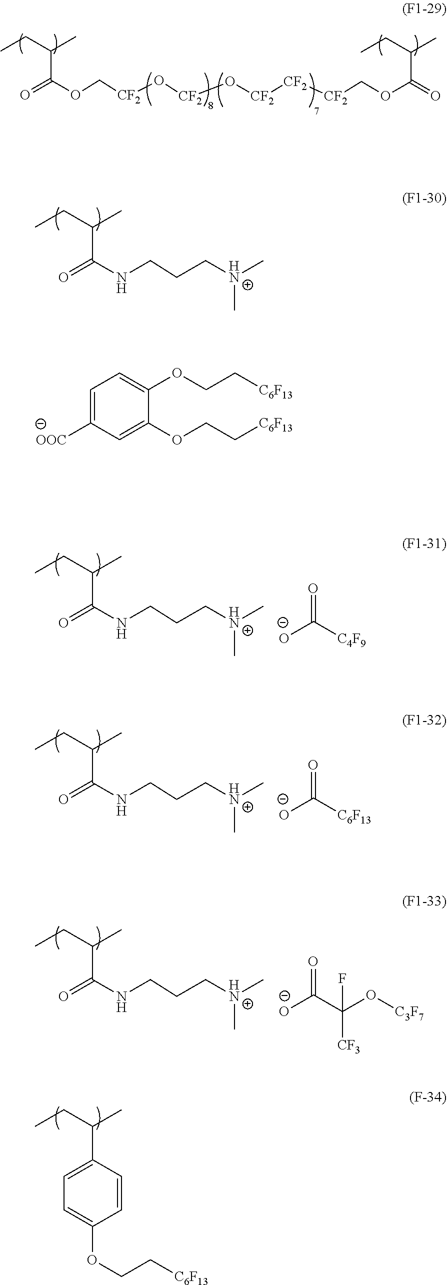

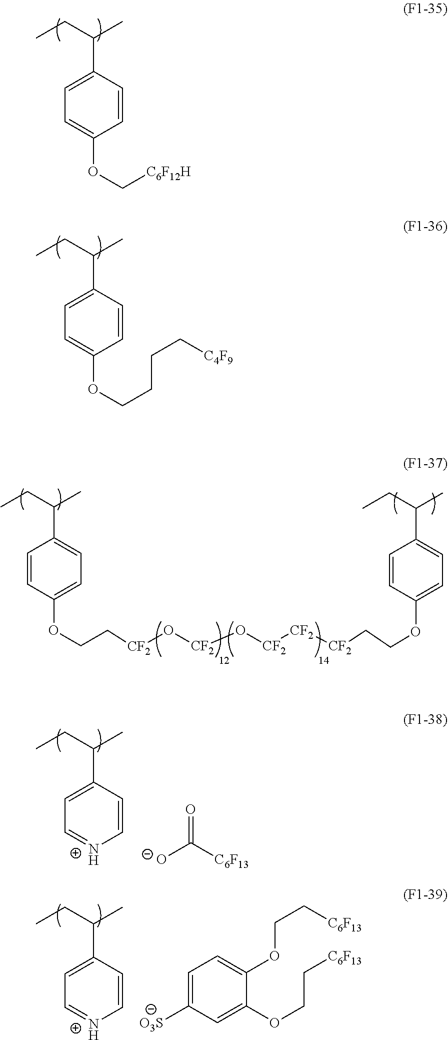

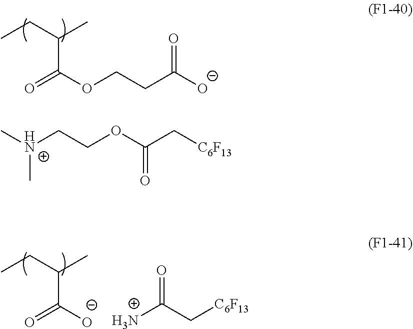

The content of the repeating unit F-1 is preferably in a range of 10% to 98% by mass, more preferably in a range of 15% to 90% by mass, and still more preferably in a range of 20% to 85% by mass with respect to all the repeating units (100% by mass) of the specific surfactant. In a case where the content of the repeating unit F-1 is in the above-described ranges, the effects of the present invention are more excellent.

The specific surfactant may have only one or two or more kinds of repeating units F-1. In a case where the specific interface improving agent has two or more kinds of repeating units F-1, the content of the repeating unit F-1 denotes the total content of the repeating units F-1.

<Repeating Unit F-2>

The repeating unit F-2 is a repeating unit represented by Formula (F-2).

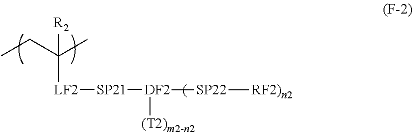

In Formula (F-2), R2 represents a hydrogen atom, a fluorine atom, a chlorine atom, or an alkyl group having 1 to 4 carbon atoms, and LF2 represents the same group as LF1 in Formula (F-1).

SP21 and SP22 each independently represent a spacer group, DF2 represents an (m2+1)-valent group, T2 represents a terminal group, RF2 represents a group having a fluorine atom, n2 represents an integer of 2 or greater, m2 represents an integer of 2 or greater, and m2 is greater than or equal to n2.

A plurality of —SP22-RF2's may be the same as or different from each other. In a case where a plurality of T2's are present, the plurality of T2's may be the same as or different from each other.

In Formula (F-2), R2 represents a hydrogen atom, a fluorine atom, a chlorine atom, or an alkyl group having 1 to 4 carbon atoms and preferably a hydrogen atom or a methyl group.

In Formula (F-2), DF2 represents an (m2+1)-valent group, and specific examples thereof include a tertiary carbon atom (—C(H)<), a quaternary carbon atom (>C<), a nitrogen atom, a phosphoric acid ester group (P(═O)(—O—)₃), a branched alkylene group having 2 to 20 carbon atoms, an aromatic ring having 4 to 15 carbon atoms, an aliphatic ring having 4 to 15 carbon atoms, and a heterocyclic ring.

The carbon atom in the branched alkylene group, the aromatic ring, and the aliphatic ring may be substituted with “SP—C” described above.

The hydrogen atom in the branched alkylene group, the aromatic ring, and the aliphatic ring may be substituted with “SP—H” described above.

It is preferable that DF2 represents a carbon atom (such as a tertiary carbon atom or a quaternary carbon atom), a nitrogen atom, a benzene ring, a cyclohexane ring, or a cyclopentane ring.

SP21 and SP22 each independently represent a spacer group, and examples thereof include SPW.

It is preferable that SP21 and SP22 represent a single bond or a linear, branched, or cyclic alkylene group having 1 to 10 carbon atoms. Here, the carbon atom of the alkylene group may be substituted with —O—, —S—, —N(Z)—, —C(Z)═C(Z′)—, —C(O)—, —C(S). —OC(O)—, —OC(S)—, —SC(O)—, —C(O)O—, —C(S)O—, —C(O)S—, —O—C(O)O—, —N(Z)C(O)—, or —C(O)N(Z)—, (Z and Z′ each independently represent a hydrogen atom, an alkyl group having 1 to 4 carbon atoms, a cycloalkyl group, an aryl group, a cyano group, or a halogen atom). Further, the hydrogen atom of the alkylene group may be substituted with a fluorine atom or a fluoroalkyl group.

T2 represents preferably a hydrogen atom, a halogen atom, —OH, —COOH, an alkyl group having 1 to 10 carbon atoms, a cyano group, a nitro group, —OZ^{H}, —C(O)Z^{H}, —C(O)OZ^{H}, —OC(O)Z^{H}, or a crosslinkable group represented by any of Formulae (P-1) to (P-30) and more preferably a hydrogen atom, a fluorine atom, —OH, —COOH, —Z^{H}, —OZ^{H}, a vinyl group, a (meth)acryl group, a (meth)acrylamide group, a styryl group, a vinyl ether group, an epoxy group, or an oxetanyl group. Z^{H} represents a hydrogen atom, a halogen atom, an alkyl group having 1 to 10 carbon atoms, an alkoxy group having 1 to 10 carbon atoms, a cyano group, or a nitro group, and the number of carbon atoms is preferably in a range of 1 to 4.

RF2 represents a group having a fluorine atom and preferably a fluorine atom, RF1 in Formula (F-1), or a group having a fluorine atom as T2.

In Formula (F-2), m2 represents preferably 2 to 8 and more preferably 2 to 6. n2 represents preferably 2 to 4 and more preferably 2 or 3.

The repeating unit represented by Formula (F-2) may be of a cleavage type in which RF2 is cleaved by an acid or a base and released from a polymer side chain. As a result, the coating properties of the upper layer are improved.

Examples of the repeating unit represented by Formula (F-2) include repeating units represented by Formulae (F2-1) to (F2-39), and the present invention is not limited thereto.

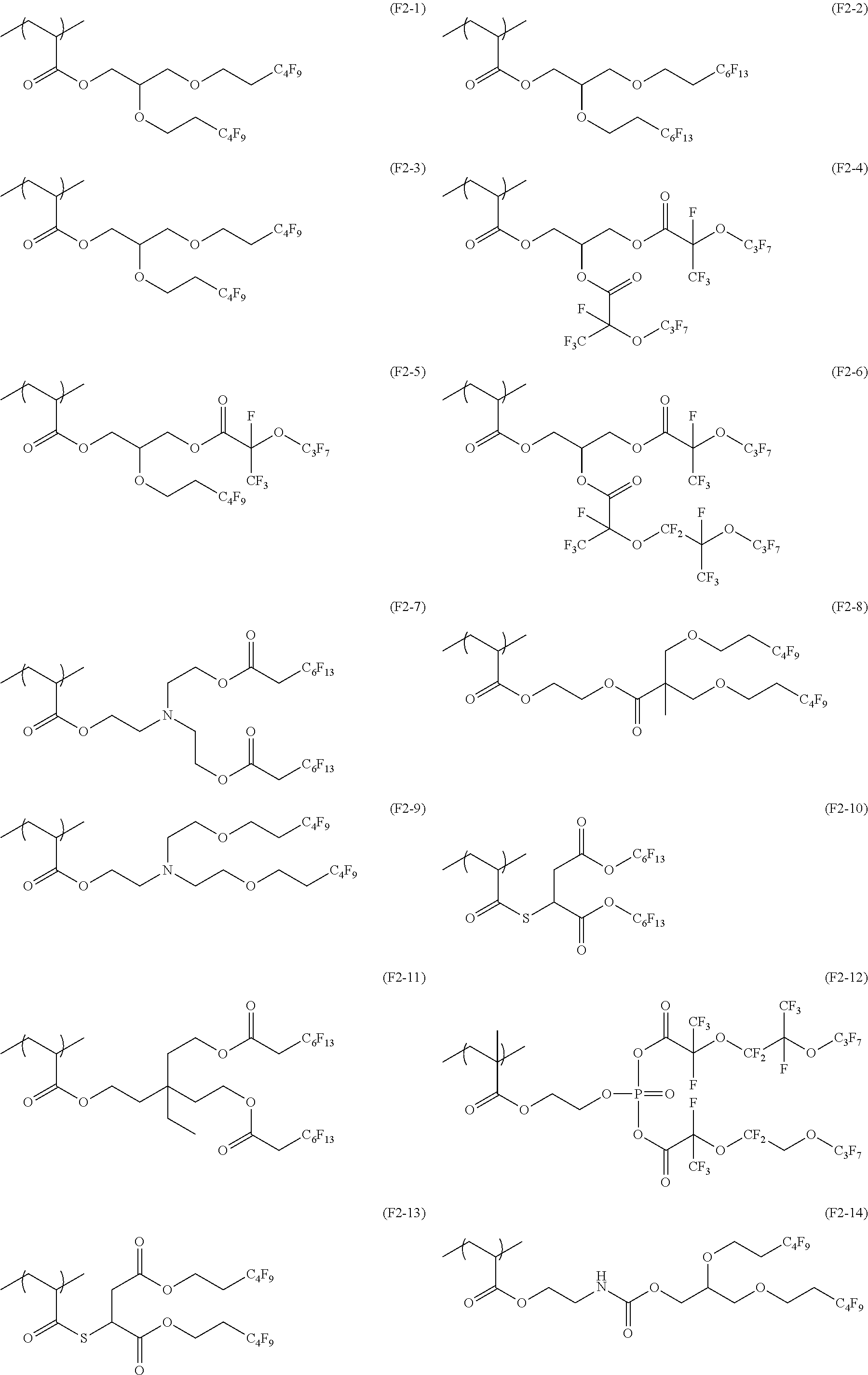

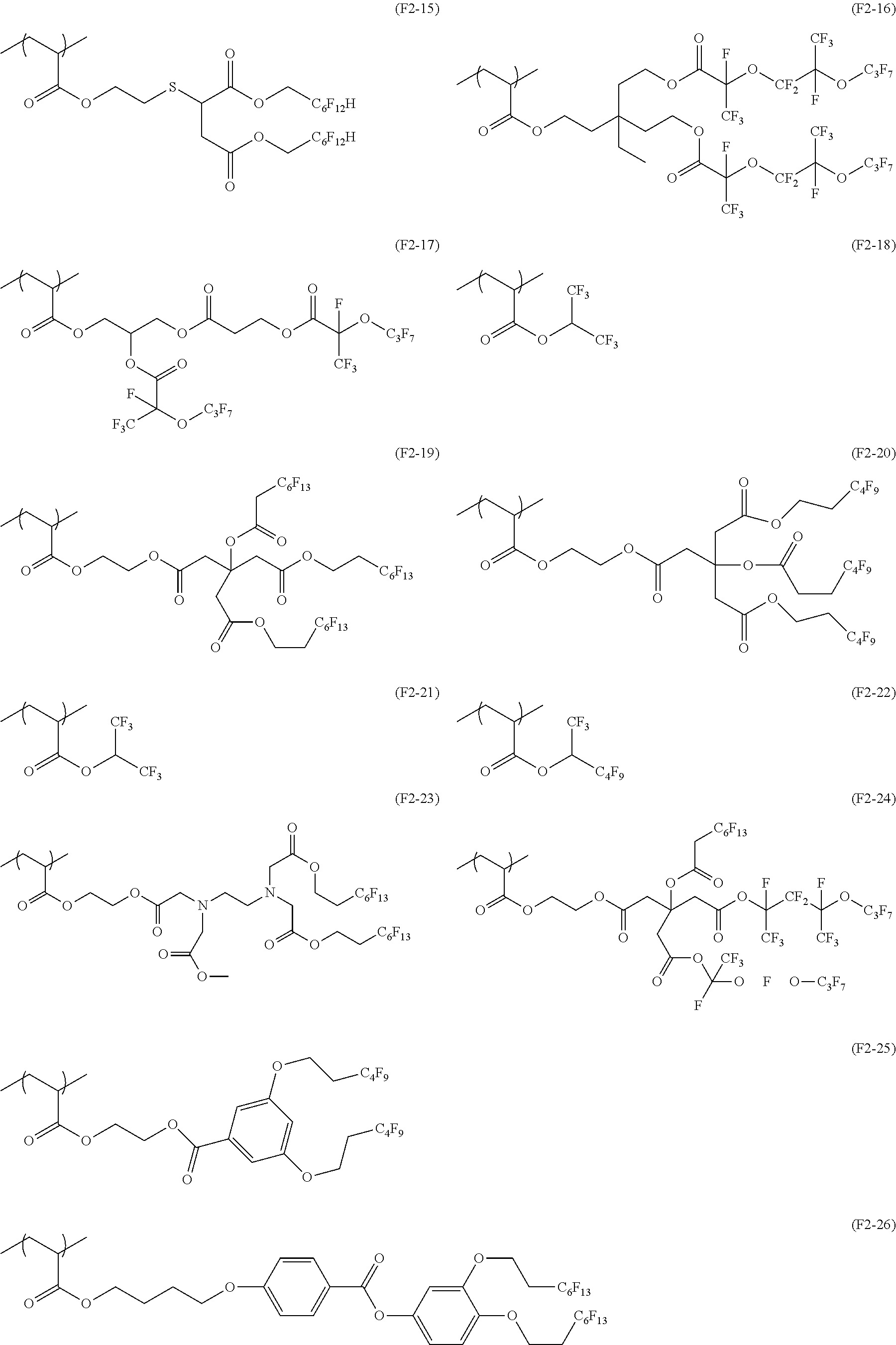

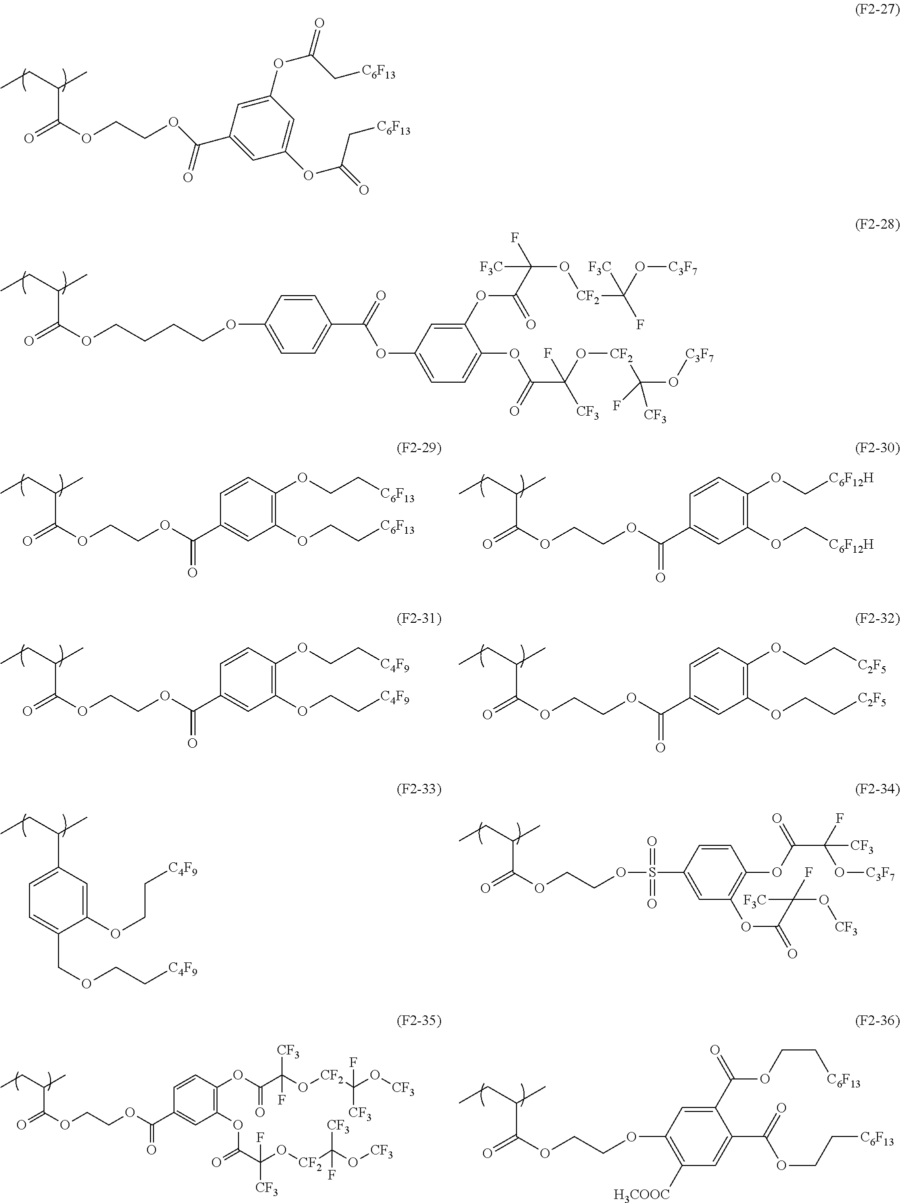

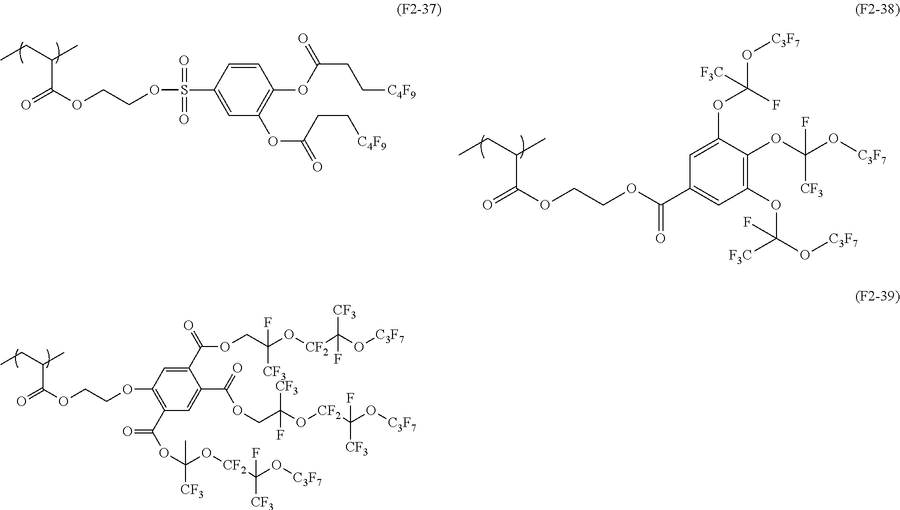

The content of the repeating unit F-2 is preferably in a range of 5% to 95% by mass, more preferably in a range of 7% to 90% by mass, and still more preferably in a range of 10% to 85% by mass with respect to all the repeating units (100% by mass) of the specific surfactant. In a case where the content of the repeating unit F-2 is in the above-described ranges, the effects of the present invention are more excellent.

The specific surfactant may have only one or two or more kinds of repeating units F-2. In a case where the specific interface improving agent has two or more kinds of repeating units F-2, the content of the repeating unit F-2 denotes the total content of the repeating units F-2.

<Other Repeating Units>

From the viewpoint that the light absorption anisotropic film having a front surface and a rear surface with different polarization degrees is more easily obtained, it is preferable that the specific surfactant has the above-described repeating unit having a fluorine atom and at least one repeating unit selected from the group consisting of a repeating unit represented by Formula (B-1) (hereinafter, also referred to as “repeating unit B-1”) and a repeating unit represented by Formula (B-2) (hereinafter, also referred to as “repeating unit B-2”).

It is preferable that both the repeating unit B-1 and the repeating unit B-2 are repeating units having no fluorine atom.

(Repeating Unit B-1)

The repeating unit B-1 is a repeating unit represented by Formula (B-1).

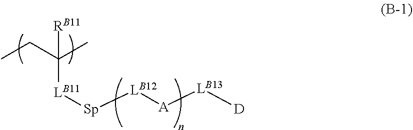

In Formula (B-1), R^{B11} represents a hydrogen atom, an alkyl group having 1 to 5 carbon atoms, or a halogen atom, preferably a hydrogen atom or an alkyl group having 1 to 5 carbon atoms, and more preferably a hydrogen atom or a methyl group.

In Formula (B-1), L^{B11} represents a single bond or —CO— and preferably —CO—.

In Formula (B-1), Sp represents a linear or branched divalent hydrocarbon group having 1 to 20 carbon atoms. Here, one or two or more —CH₂-'s that are not adjacent to each other among —CH₂-'s constituting a part of a hydrocarbon group may be each independently substituted with —O—, —S—, —NH—, or —N(Q)-, and Q represents a substituent.

Examples of the linear or branched divalent hydrocarbon group having 1 to 20 carbon atoms represented by Sp include a linear or branched divalent aliphatic hydrocarbon group having 1 to 20 carbon atoms, a divalent alicyclic hydrocarbon group having 3 to 20 carbon atoms, a divalent aromatic hydrocarbon group having 6 to 20 carbon atoms, and a divalent aromatic heterocyclic group having 6 to 20 carbon atoms. Among these, a linear or branched divalent aliphatic hydrocarbon group having 1 to 20 carbon atoms is preferable.

Here, as the divalent aliphatic hydrocarbon group having 1 to 20 carbon atoms, an alkylene group having 1 to 15 carbon atoms is preferable, and an alkylene group having 1 to 8 carbon atoms is more preferable, and specific suitable examples thereof include a methylene group, an ethylene group, a propylene group, a butylene group, a pentylene group, a hexylene group, a methylhexylene group, and a heptylene group.

As described above, one or two or more —CH₂-'s that are not adjacent to each other among —CH₂-'s constituting a part of a linear or branched divalent hydrocarbon group having 1 to 20 carbon atoms as Sp may be each independently substituted with —O—, —S—, —NH—, or —N(Q)-. As the substituent represented by Q, an alkyl group, an alkoxy group, or a halogen atom is preferable.

In Formula (B-1), L^{B12} and L^{B13} each independently represent a single bond or a divalent linking group.

Examples of the divalent linking group as L^{B12} and L^{B13} include —C(O)O—, —OC(O)—, —O—, —S—, —C(O)NR^{L1}—, —NR^{L1}C(O)—, —SO₂—, and —NR^{L1}R^{L2}—. In the formulae, R^{L1} and R^{L2} each independently represent a hydrogen atom or an alkyl group having 1 to 6 carbon atoms which may have a substituent. As the substituent that the alkyl group having 1 to 6 carbon atoms may have, an alkyl group, an alkoxy group, or a halogen atom is preferable.

In Formula (B-1), A represents a divalent linking group represented by any of Formulae (A-1) to (A-15). Here, “*” in Formulae (A-1) to (A-15) represents a bonding position with respect to L^{B12} or L^{B13}, and the carbon atoms constituting the ring structures in Formulae (A-1) to (A-15) may be substituted with heteroatoms or may have substituents. In addition, an alkyl group, an alkoxy group, or a halogen atom is preferable as the substituent that the carbon atoms constituting the ring structures may have.

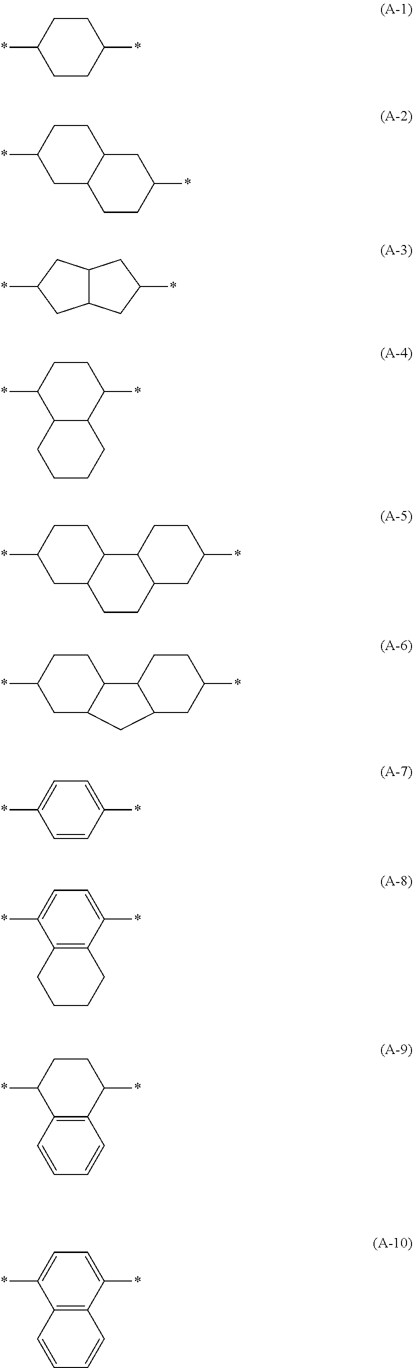

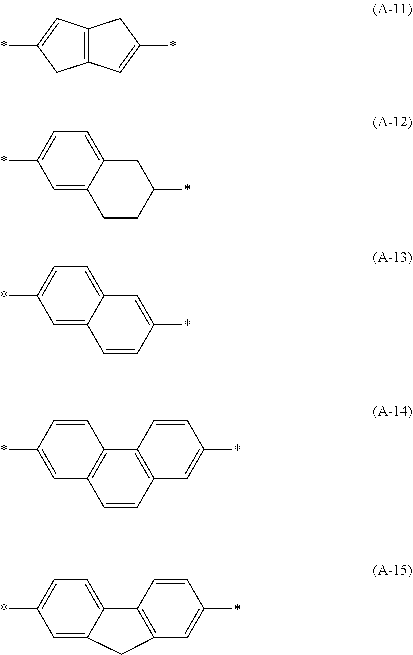 [SMILES: *C1=CC2=C(C=C(*)C2)C1 ; *c1ccc2c(c1)CCC(*)C2 ; *c1ccc2cc(*)ccc2c1 ; *c1ccc2c(ccc3cc(*)ccc32)c1 ; *c1ccc2c(c1)Cc1cc(*)ccc1-2]

Specific examples of the divalent linking group represented by any of Formulae (A-1) to (A-15) include a 1,4-phenylene group, a 1,4-cyclohexylene group, a 1,4-cyclohexenyl group, a tetrahydropyran-2,5-diyl group, a 1,4-piperazine group, a 1,4-piperidine group, a 1,3-dioxane-2,5-diyl group, a tetrahydrothiopyran-2,5-diyl group, a 1,4-bicyclo(2,2,2)octylene group, a decahydronaphthalene-2,6-diyl group, a pyridine-2,5-diyl group, a pyrimidine-2,5-diyl group, a pyrazine-2,5-diyl group, a 1,2,3,4-tetrahydronaphthalene-2,6-diyl group, a 2,6-naphthylene group, a phenanthrene-2,7-diyl group, a 9,10-dihydrophenanthrene-2,7-diyl group, a 1,2,3,4,4a,9,10,10a-octahydrophenanthrene-2,7-diyl group, a 9-fluorenone-2,7-diyl group, a fluorene-2,7-diyl group, a thienothiophene-3,6-diyl group, a carbazole-3,6-diyl group, and a carbazole-2,7-diyl group.

n represents an integer of 1 to 6, preferably 1 to 4, and more preferably 2 or 3.

In a case where n represents 2 or greater, a plurality of L^{B12′}s may be the same as or different from each other, and a plurality of A's may be the same as or different from each other.

From the viewpoint of further increasing the alignment degree of the light absorption anisotropic film to be formed, Ain Formula (B-1) represents preferably a divalent linking group represented by any of Formulae (A-1), (A-4), (A-7), (A-10), or (A-13) and more preferably a divalent linking group represented by any of Formula (A-7) or Formula (A-13).

Further, in Formula (B-1), D represents —NR^{L3}R^{L4} or a hydrogen bonding group formed of a hydrogen atom and non-metal atoms of Groups 14 to 16. Among these, from the viewpoint that the display performance in a case where the light absorption anisotropic film is applied to an image display device is more excellent, —NR^{L3}R^{L4} is preferable. Further, the non-metal atom may have a substituent.

R^{L3} and R^{L4} each independently represent an alkyl group having 1 to 5 carbon atoms or —C(O)CH₃.

Here, examples of the non-metal atoms of Groups 14 to 16 include an oxygen atom, a sulfur atom, a nitrogen atom, and a carbon atom.

Further, examples of the substituent that the non-metal atoms (particularly, a nitrogen atom and a carbon atom) may have include a halogen atom, an alkyl group, an alkoxy group, an alkyl-substituted alkoxy group, an acetyl group, a cyclic alkyl group, an aryl group (such as a phenyl group or a naphthyl group), a cyano group, an amino group, a nitro group, an alkylcarbonyl group, a sulfo group, and a hydroxyl group.

Examples of such a hydrogen bonding group include a hydrogen bond-donating group and a hydrogen bond-accepting group.

Specific examples of the hydrogen bond-donating group include an amino group, —NHR^{L5} (R^{L5} represents an alkyl group having 1 to 5 carbon atoms or an acetyl group), an amide group, a urea group, a urethane group, a sulfonylamino group, a sulfo group, a phospho group, a hydroxy group, a mercapto group, a carboxy group, a methylene group substituted with an electron withdrawing group, and a methine group substituted with an electron withdrawing group.

Specific examples of the hydrogen bond-accepting group include a heteroatom having an unshared electron pair on a heterocycle, a hydroxy group, an aldehyde, a ketone, a carboxy group, carboxylic acid ester, carboxylic acid amide, a lactone, a lactam, sulfonic acid amide, a sulfo group, a phospho group, phosphoric acid amide, urethane, urea, an ether structure (particularly, a polymer structure having an oxygen atom contained in a polyether structure), an aliphatic amine, and an aromatic amine.

In a case where the specific surfactant has a repeating unit B-1, the content of the repeating unit B-1 is preferably in a range of 15% to 80% by mass, more preferably in a range of 20% to 75% by mass, and still more preferably in a range of 30% to 70% by mass with respect to the total mass of the specific surfactant.

In a case where the content of the repeating unit B-1 is in the above-described ranges, the log P value of the specific surfactant is easily adjusted to be in the above-described ranges.

(Repeating Unit B-2)

The repeating unit B-2 is a repeating unit represented by Formula (B-2).

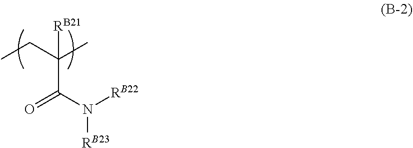

R^{B21} represents a hydrogen atom, an alkyl group having 1 to 5 carbon atoms, a halogen atom, or a cyano group, preferably a hydrogen atom or an alkyl group having 1 to 5 carbon atoms, and more preferably a hydrogen atom.

The number of carbon atoms in the alkyl group is in a range of 1 to 5, preferably in a range of 1 to 3, and more preferably 1. The alkyl group may have a linear, branched, or cyclic structure.

In Formula (B-2), R^{B22} and R^{B23} each independently represent a hydrogen atom or a substituent. However, in a case where R^{B22} and R^{B23} represent a substituent, R^{B22} and R^{B23} may be linked to each other to form a ring.

The total molecular weight of R^{B22} and R^{B23} is preferably 200 or less, more preferably 100 or less, and still more preferably 70 or less. In a case where the total molecular weight thereof is 100 or less, the interaction between the repeating units B-2 is further improved, and thus the compatibility between the specific surfactant and the liquid crystal compound can be further decreased. In this manner, a light absorption anisotropic film having less alignment defects and an excellent alignment degree can be obtained.

The lower limit of the total molecular weight of R^{B22} and R^{B23} is preferably 2 or greater.

From the viewpoint that the effects of the present invention are more excellent, as the substituent represented by R^{B22} and R^{B23}, an organic group is preferable, an organic group having 1 to 15 carbon atoms is more preferable, an organic group having 1 to 12 carbon atoms is still more preferable, and an organic group having 1 to 8 carbon atoms is particularly preferable.

Examples of the organic group include a linear, branched or cyclic alkyl group, an aromatic hydrocarbon group, and a heterocyclic group.

The number of carbon atoms of the alkyl group is preferably in a range of 1 to 15, more preferably in a range of 1 to 12, and still more preferably in a range of 1 to 8.

The carbon atoms of the alkyl group may be substituted with —O—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ each independently represent a hydrogen atom, an alkyl group having 1 to 4 carbon atoms, a cycloalkyl group, an aryl group, a cyano group, or a halogen atom), —C≡C—, —N═N—, —S—, —C(S)—, —S(O)—, —SO₂—, —(O)S(O)O—, —O(O)S(O)O—, —SC(O)—, —C(O)S—, or a group obtained by combining two or more of these groups. Among the groups which may be substituted with the carbon atoms of the alkyl group, from the viewpoint that the effects of the present invention are more excellent, —O—, —C(O)—, —N(Z)—, —OC(O)—, or —C(O)O— is preferable.

Further, the hydrogen atoms of the alkyl group may be substituted with a halogen atom, a cyano group, an aryl group, a nitro group, —OZ^{H}, —C(O)Z^{H}, —C(O)OZ^{H}, —OC(O)Z^{H}, —OC(O)OZ^{H}, —NZ^{H}Z^{H′}, —NZ^{H}C(O)Z^{H′}, —NZ^{H}C(O)OZ^{H′}, —C(O)NZ^{H}Z^{H′}, —OC(O)NZ^{H}Z^{H′}, —NZ^{H}C(O)NZ^{H′}OZ^{H″}, —SZ^{H}, —C(S)Z^{H}, —C(O)SZ^{H}, or —SC(O)Z^{H}. Z^{H}, Z^{H′}, and Z^{H″} each independently represent a hydrogen atom, a halogen atom, an alkyl group having 1 to 10 carbon atoms, a cyano group, or a nitro group. Among the groups which may be substituted with the hydrogen atoms of the alkyl group, from the viewpoint that the effects of the present invention are more excellent, —OH, —COOH, or an aryl group (preferably a phenyl group) is preferable.

Further, the hydrogen atoms of the aromatic hydrocarbon group and the hydrogen atoms of the heterocyclic group may be substituted with a halogen atom, a cyano group, an alkyl group having 1 to 10 carbon atoms, a cyano group, a nitro group, —OZ^{H}, —C(O)Z^{H}, —C(O)OZ^{H}, —OC(O)Z^{H}, —OC(O)OZ^{H}, —NZ^{H}Z^{H′}, —NZ^{H}C(O)Z^{H′}, —NZ^{H}C(O)OZ^{H′}, —C(O)NZ^{H}Z^{H′}, —OC(O)NZ^{H}Z^{H′}, —NZ^{H}C(O)NZ^{H′}OZ^{H″}, —SZ^{H}, —C(S)Z^{H}, —C(O)SZ^{H}, —SC(O)Z^{H}, or —B(OH)₂. Z^{H}, Z^{H′}, and Z^{H″} each independently represent a hydrogen atom, a halogen atom, an alkyl group having 1 to 10 carbon atoms, a cyano group, or a nitro group. Among the groups which may be substituted with the hydrogen atoms of the aromatic hydrocarbon group and the hydrogen atoms of the heterocyclic group, from the viewpoint that the effects of the present invention are more excellent, —OH or —B(OH)₂ is preferable.

R^{B22} and R^{B23} each independently represent preferably a hydrogen atom or an organic group having 1 to 15 carbon atoms, more preferably an organic group having 1 to 15 carbon atoms, and from the viewpoint that the display performance in a case where the light absorption anisotropic layer is applied to an image display device is more excellent, still more preferably an alkyl group having 1 to 15 carbon atoms.

The ring formed by R^{B21} and R^{B22} being linked to each other is a heterocyclic ring having a nitrogen atom, and may further have heteroatoms such as an oxygen atom, a sulfur atom, and a nitrogen atom in the ring.

From the viewpoint that the effects of the present invention are more excellent, the ring formed by R^{B21} and R^{B22} being linked to each other is preferably a 4- to 8-membered ring, more preferably a 5- to 7-membered ring, and still more preferably a 5- or 6-membered ring.

From the viewpoint that the effects of the present invention are more excellent, the number of carbon atoms constituting the ring formed by R^{B21} and R^{B22} being linked to each other is preferably in a range of 3 to 7 and more preferably in a range of 3 to 6.

The ring formed by R^{B21} and R^{B22} being linked to each other may or may not have aromaticity, but it is preferable that the ring does not have aromaticity from the viewpoint that the effects of the present invention are more excellent.

Specific examples of the ring formed by R^{B21} and R^{B22} being linked to each other include the following groups.

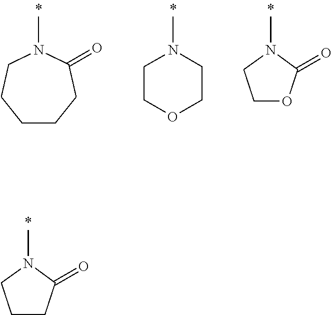

Specific examples of the repeating unit B-2 are shown below, but the repeating unit B-2 is not limited to the following structures.

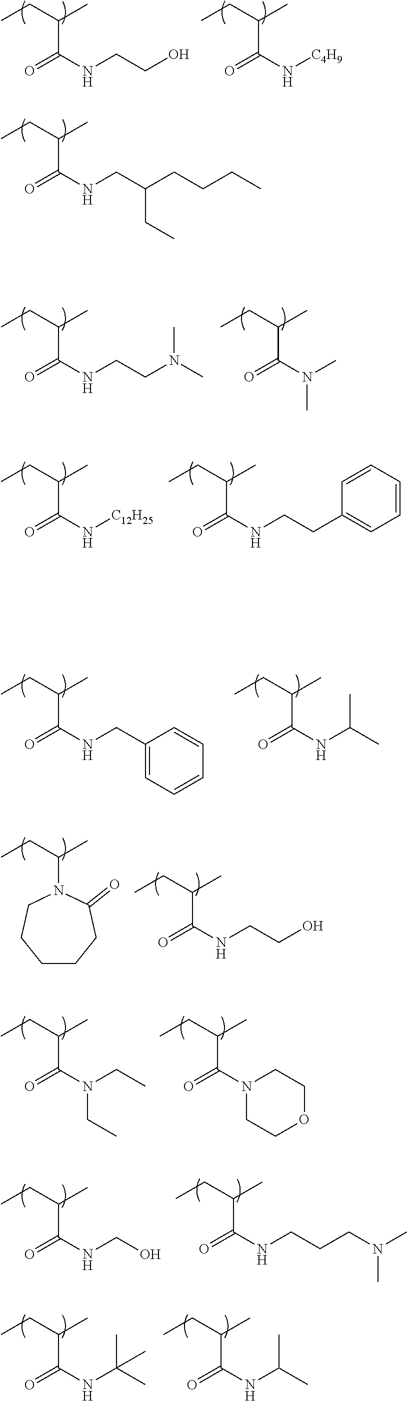

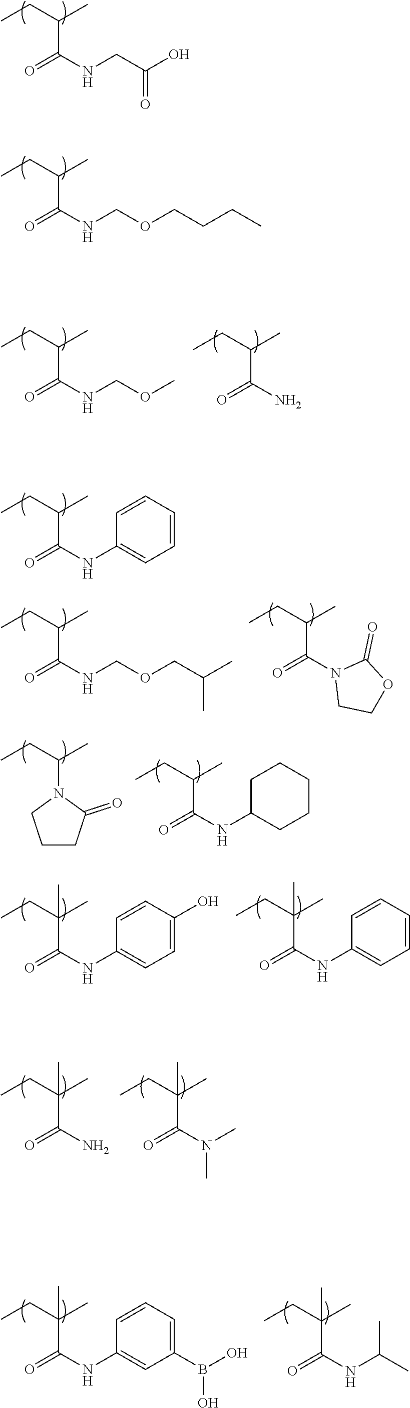

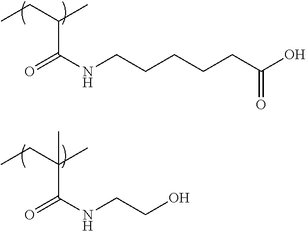

In a case where the specific surfactant has a repeating unit B-2, the content of the repeating unit B-2 is preferably in a range of 15% to 80% by mass, more preferably in a range of 20% to 75% by mass, and still more preferably in a range of 30% to 70% by mass with respect to all the repeating units (100% by mass) of the specific surfactant.

In a case where the content of the repeating unit B-2 is in the above-described ranges, the log P value of the specific surfactant is easily adjusted to be in the above-described ranges.

The log P value of the specific surfactant is 5.2 or less and more preferably 4.5 or less from the viewpoint that the effects of the present invention are more excellent.

The lower limit of the log P value of the specific surfactant is not particularly limited, but is preferably 0 or greater.

The log P value is an indicator expressing the properties of hydrophilicity and hydrophobicity of a chemical structure, and is also referred to as a hydrophilic-hydrophobic parameter. The log P value of each compound can be calculated using software such as ChemBioDraw Ultra or HSPiP (Ver. 4.1.07). Further, the log P value can be acquired experimentally by the method of the OECD Guidelines for the Testing of Chemicals, Sections 1, Test No. 117 or the like. In the present invention, a value calculated by inputting the structural formula of a compound to HSPiP (Ver. 4.1.07) is employed as the log P value unless otherwise specified.

From the viewpoint that the display performance in a case where the light absorption anisotropic layer is applied to an image display device is more excellent, it is preferable that the specific surfactant does not contain a hydrogen bonding group. The specific examples of the hydrogen bonding group are as described above.

The content of the fluorine atom in the specific surfactant is preferably 10% by mass or greater, more preferably 13% by mass or greater, and still more preferably 15% by mass or greater. In a case where the content of the fluorine atom is greater than or equal to the above-described values, the specific surfactant is likely to be unevenly distributed on one surface side of the light absorption anisotropic film, and thus a light absorption anisotropic film having a front surface and a rear surface with different polarization degrees can be more easily obtained.

The content of the fluorine atom in the specific surfactant is preferably 40% by mass or less, more preferably 35% by mass or less, and still more preferably 30% by mass or less. In a case where the content of the fluorine atom is less than or equal to the above-described values, the log P value of the specific surfactant is easily adjusted to be in the above-described ranges.

The content of the fluorine atom in the specific surfactant denotes the proportion (%) of the mass of the fluorine atom in the total mass of the specific surfactant, and can be measured by nuclear magnetic resonance (NMR) analysis.

In a case where the light absorption anisotropic film contains the specific surfactant, from the viewpoint that the light absorption anisotropic film having a front surface and a rear surface with different polarization degrees is more easily obtained, the content of the specific surfactant is preferably in a range of 0.05% to 5% by mass, more preferably in a range of 0.10% to 3% by mass, and still more preferably in a range of 0.50% to 2% by mass with respect to the total mass of the light absorption anisotropic film.

The specific surfactant may be used alone or in combination of two or more kinds thereof.

In a case where the light absorption anisotropic film according to the embodiment of the present invention contains the specific surfactant and the polymer liquid crystal compound, the distance between the HSP value of the specific surfactant and the HSP value of the polymer liquid crystal compound (hereinafter, also simply referred to as “HSP distance”) is preferably 3.5 MPa^{1/2} or greater, more preferably 5.0 MPa^{1/2} or greater, and particularly preferably 10 MPa^{1/2} or greater. In a case where the HSP distance is greater than or equal to the above-described values, the dichroic substance is unlikely to be mixed into the light absorption anisotropic film, and as a result, the aligning properties of the dichroic substance on one surface side of the light absorption anisotropic film are disturbed. Therefore, the display performance in a case where the light absorption anisotropic film is applied to an image display device is more excellent.

The HSP distance between the specific surfactant and the polymer liquid crystal compound is not particularly limited, but is preferably 30 MPa^{1/2} or less.

Here, the details of the Hansen solubility parameter (HSP value) are described in Hansen, Charles (2007), Hansen Solubility Parameters: A user's handbook, Second Edition. Boca Raton, Fla: CRC Press. ISBN 9780849372483.

The HSP value of each compound (each group) in the present invention is calculated by inputting the structural formula of the compound into the following software and is, more specifically, a value corresponding to Stotal. As the software, Hansen Solubility Parameters in Practice (HSPiP) ver 4.1.07 is used.

[Other Components]

The light absorption anisotropic film according to the embodiment of the present invention may contain components other than the components described above (hereinafter, also referred to as “other components”). Examples of the other components include an adhesion improving agent and surfactants other than the specific surfactant (hereinafter, also referred to as “other surfactants”).

<Adhesion Improving Agent>

The light absorption anisotropic film according to the embodiment of the present invention may contain an adhesion improving agent from the viewpoint of the adhesiveness between the light absorption anisotropic film and other layers described below. Examples of the adhesion improving agent include compounds containing a hydroxyl group, a carboxyl group, and a boronic acid group. Among these, a compound containing a boronic acid group is preferable.

Suitable examples of the compound containing a boronic acid group include a compound represented by the following formula.

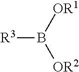

In the formula, R¹ and R² each independently represent a hydrogen atom, a substituted or unsubstituted aliphatic hydrocarbon group, a substituted or unsubstituted aryl group, or a substituted or unsubstituted heterocyclic group. R³ represents a substituent containing a (meth)acryloyl group.

Specific examples of the compound containing a boronic acid group include a boronic acid compound represented by General Formula (I) described in paragraphs to of JP2008-225281A.

As the compound containing a boronic acid group, compounds shown below are also preferable.

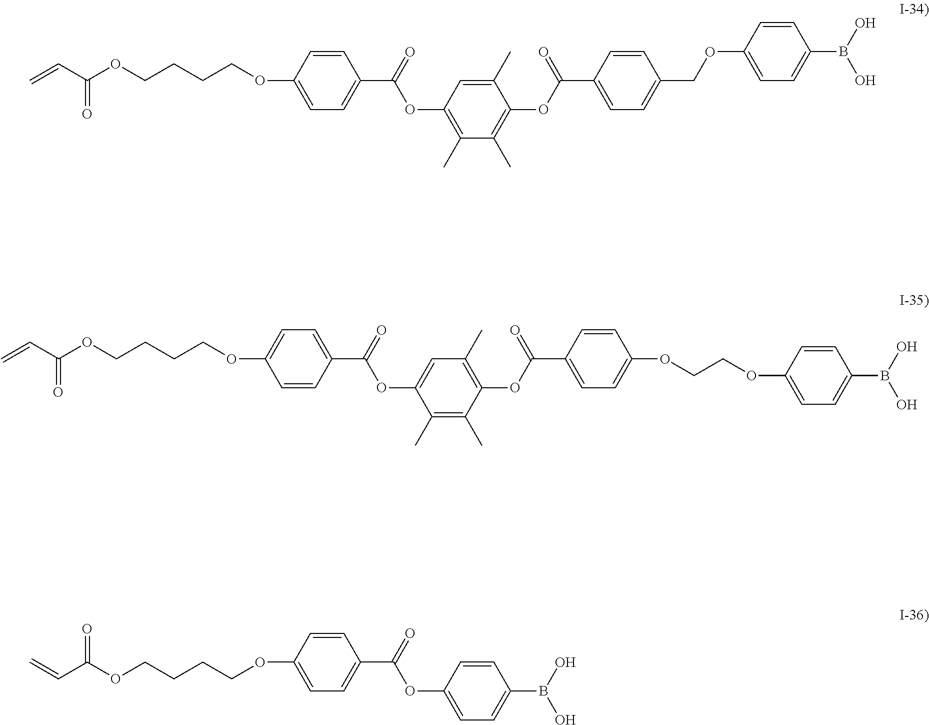 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

In a case where the light absorption anisotropic film contains an adhesion improving agent, the content of the adhesion improving agent is preferably in a range of 0.1% to 10% by mass and more preferably in a range of 0.5% to 5% by mass with respect to the total mass of the light absorption anisotropic film.

<Other Surfactants>

The light absorption anisotropic film according to the embodiment of the present invention may contain other surfactants. The other surfactants denote surfactants other than the specific surfactant, and specific examples thereof include surfactants having no fluorine atom or having a log P value of greater than 5.2.

As the other surfactants, fluorine (meth)acrylate-based polymers with a log P value of greater than 5.2 among those described in paragraphs to of JP2007-272185A can be used.

In a case where the light absorption anisotropic film according to the embodiment of the present invention contains other surfactants, the content of the other surfactants is preferably in a range of 0.01% to 0.1% by mass and more preferably in a range of 0.01% to 0.05% by mass with respect to the total mass of the light absorption anisotropic film.

<Light Resistance Improving Agent>

The light absorption anisotropic film may contain a light resistance improving agent from the viewpoint of further improving the light resistance.

As the light resistance improving agent, an oxidizing agent and a singlet oxygen quencher described in WO2017/170036A, and an antioxidant and the like described in JP2019-133148A and JP2019-191507A can be used. Among these, as the light resistance improving agent, a compound having an N-oxyl structure is more preferable.

In a case where the light absorption anisotropic film according to the embodiment of the present invention contains a light resistance improving agent, the content of the light resistance improving agent is preferably in a range of 0.1% to 5.0% by mass and more preferably in a range of 0.3% to 3.0% by mass with respect to the total mass of the light absorption anisotropic film.

[Composition for Forming Light Absorption Anisotropic Film]

It is preferable that the light absorption anisotropic film according to the embodiment of the present invention is formed of a composition for forming a light absorption anisotropic film containing a dichroic substance.

It is preferable that the composition for forming a light absorption anisotropic film contains a liquid crystal compound, a specific surfactant, a polymerization initiator, a solvent, and the like in addition to the dichroic substance and may further contain the other components described above.

The dichroic substance contained in the composition for forming a light absorption anisotropic film is the same as the dichroic substance contained in the light absorption anisotropic film according to the embodiment of the present invention.

It is preferable that the content of the dichroic substance with respect to the total solid content mass of the composition for forming a light absorption anisotropic film is the same as the content of the dichroic substance with respect to the total mass of the light absorption anisotropic layer according to the embodiment of the present invention.

Here, “total solid content in the composition for forming a light absorption anisotropic film” denotes components excluding the solvent, and specific examples of the solid content include the dichroic substance, the liquid crystal compound, the specific surfactant, and the other components described above.

The liquid crystal compound, the specific surfactant, and the other components that can be contained in the composition for forming a light absorption anisotropic film are respectively the same as the liquid crystal compound, the specific surfactant, and the other components that can be contained in the light absorption anisotropic film according to the embodiment of the present invention.

It is preferable that the contents of the liquid crystal compound, the specific surfactant, and the other components with respect to the total solid content mass of the composition for forming the light absorption anisotropic film are respectively the same as the contents of the liquid crystal compound, the specific surfactant, and the other components with respect to the total mass of the light absorption anisotropic film according to the embodiment of the present invention.

<Polymerization Initiator>

It is preferable that the composition for forming a light absorption anisotropic film contains a polymerization initiator. The polymerization initiator is not particularly limited, but a compound having photosensitivity, that is, a photopolymerization initiator is preferable.

As the photopolymerization initiator, various compounds can be used without any particular limitation. Examples of the photopolymerization initiator include α-carbonyl compounds (U.S. Pat. Nos. 2,367,661A and 2,367,670A), acyloin ether (U.S. Pat. No. 2,448,828A), α-hydrocarbon-substituted aromatic acyloin compounds (U.S. Pat. No. 2,722,512A), polynuclear quinone compounds (U.S. Pat. Nos. 3,046,127A and 2,951,758A), a combination of a triarylimidazole dimer and a p-aminophenyl ketone (U.S. Pat. No. 3,549,367A), acridine and phenazine compounds (JP1985-105667A (JP-S60-105667A) and U.S. Pat. No. 4,239,850A), oxadiazole compounds (U.S. Pat. No. 4,212,970A), o-acyloxime compounds (paragraph of JP2016-27384A), and acylphosphine oxide compounds (JP1988-40799B (JP-S63-40799B), JP1993-29234B (JP-H5-29234B), JP1998-95788A (JP-H10-95788A), and JP1998-29997A (JP-H10-29997A)).

A commercially available product can also be used as such a photopolymerization initiator, and examples thereof include IRGACURE 184, IRGACURE 907, IRGACURE 369, IRGACURE 651, IRGACURE 819, IRGACURE OXE-01, and IRGACURE OXE-02 (all manufactured by BASF SE).

The polymerization initiator may be used alone or in combination of two or more kinds thereof.

In a case where the composition for forming a light absorption anisotropic film contains a polymerization initiator, the content of the polymerization initiator is preferably in a range of 0.01 to 30 parts by mass and more preferably in a range of 0.1 to 15 parts by mass with respect to 100 parts by mass of the total amount of the dichroic substance and the liquid crystal compound in the composition for forming a light absorption anisotropic film. The durability of the light absorption anisotropic film is enhanced in a case where the content of the polymerization initiator is 0.01 parts by mass or greater, and the alignment degree of the light absorption anisotropic film is enhanced in a case where the content thereof is 30 parts by mass or less.

<Solvent>

From the viewpoints of the workability and the like, it is preferable that the composition for forming a light absorption anisotropic film contains a solvent.

Examples of the solvent include organic solvents such as ketones (such as acetone, 2-butanone, methyl isobutyl ketone, cyclopentanone, and cyclohexanone), ethers (such as dioxane, tetrahydrofuran, tetrahydropyran, dioxolane, tetrahydrofurfuryl alcohol, and cyclopentyl methyl ether), aliphatic hydrocarbons (such as hexane), alicyclic hydrocarbons (such as cyclohexane), aromatic hydrocarbons (such as benzene, toluene, xylene, and trimethylbenzene), halogenated carbons (such as dichloromethane, trichloromethane (chloroform), dichloroethane, dichlorobenzene, and chlorotoluene), esters (such as methyl acetate, ethyl acetate, butyl acetate, and diethyl carbonate), alcohols (such as ethanol, isopropanol, butanol, and cyclohexanol), cellosolves (such as methyl cellosolve, ethyl cellosolve, and 1,2-dimethoxyethane), cellosolve acetates, sulfoxides (such as dimethyl sulfoxide), amides (such as dimethylformamide, dimethylacetamide, N-methylpyrrolidone, N-ethylpyrrolidone, and 1,3-dimethyl-2-imidazolidinone), and heterocyclic compounds (such as pyridine), and water. These solvents may be used alone or in combination of two or more kinds thereof.

Among these solvents, it is preferable to use an organic solvent and more preferable to use halogenated carbons or ketones from the viewpoint that the effects of the present invention are more excellent.

In a case where the composition for forming a light absorption anisotropic film contains a solvent, the content of the solvent is preferably in a range of 80% to 99% by mass, more preferably in a range of 83% to 97% by mass, and still more preferably in a range of 85% to 95% by mass with respect to the total mass of the composition for forming a light absorption anisotropic film.

[Method of Producing Light Absorption Anisotropic Film]

A method of producing the light absorption anisotropic film according to the embodiment of the present invention is not particularly limited, but a method of sequentially performing a step of coating an alignment film with the above-described composition for forming a light absorption anisotropic film to form a coating film (hereinafter, also referred to as “coating film forming step”) and a step of aligning liquid crystal components contained in the coating film (hereinafter, also referred to as “aligning step”) (hereinafter, also referred to as “present production method”) is preferable from the viewpoint of further increasing the alignment degree of the light absorption anisotropic film to be obtained.

Further, the liquid crystal component is a component that contains not only the liquid crystal compound described above but also a dichroic substance having liquid crystallinity.

Hereinafter, each step will be described.

<Coating Film Forming Step>

The coating film forming step is a step of coating an alignment film with the composition for forming a light absorption anisotropic film to form a coating film.

The alignment film can be easily coated with the composition for forming a light absorption anisotropic film by using the composition for forming a light absorption anisotropic film which contains the above-described solvent or using a liquid-like material such as a melt obtained by heating the composition for forming a light absorption anisotropic film.

Examples of a method of coating the film with the composition for forming a light absorption anisotropic film include known methods such as a roll coating method, a gravure printing method, a spin coating method, a wire bar coating method, an extrusion coating method, a direct gravure coating method, a reverse gravure coating method, a die coating method, a spraying method, and an ink jet method.

(Alignment Film)

The alignment film may be any film as long as the film allows the liquid crystal compound that can be contained in the composition for forming a light absorption anisotropic film to be horizontally aligned.

An alignment film can be provided by means such as a rubbing treatment performed on a film surface of an organic compound (preferably a polymer), oblique vapor deposition of an inorganic compound, formation of a layer having microgrooves, or accumulation of an organic compound (such as ω-tricosanoic acid, dioctadecylmethylammonium chloride, or methyl stearylate) using a Langmuir-Blodgett method (LB film). Further, an alignment film in which an alignment function is generated by application of an electric field, application of a magnetic field, or irradiation with light is also known. Among these, in the present invention, an alignment film formed by performing a rubbing treatment is preferable from the viewpoint of easily controlling the pretilt angle of the alignment film, and a photo-alignment film formed by irradiation with light is also preferable from the viewpoint of the uniformity of alignment.

(1) Rubbing Treatment Alignment Film

A polymer material used for the alignment film formed by performing a rubbing treatment is described in a plurality of documents, and a plurality of commercially available products can be used. In the present invention, polyvinyl alcohol or polyimide and derivatives thereof are preferably used. The alignment film can refer to the description on page 43, line 24 to page 49, line 8 of WO2001/88574A1.

The thickness of the alignment film is preferably in a range of 0.01 to 10 μm and more preferably in a range of 0.01 to 1 μm.

(2) Photo-Alignment Film

A photo-alignment material used for an alignment film formed by irradiation with light is described in a plurality of documents. In the present invention, preferred examples thereof include azo compounds described in JP2006-285197A, JP2007-76839A, JP2007-138138A, JP2007-094071A, JP2007-121721A, JP2007-140465A, JP2007-156439A, JP2007-133184A, JP2009-109831A, JP3883848B, and JP4151746B, aromatic ester compounds described in JP2002-229039A, maleimide and/or alkenyl-substituted nadiimide compounds having a photo-alignment unit described in JP2002-265541A and JP2002-317013A, photocrosslinkable silane derivatives described in JP4205195B and JP4205198B, and photocrosslinkable polyimides, polyamides, or esters described in JP2003-520878A, JP2004-529220A, and JP4162850B. Among these, azo compounds, photocrosslinkable polyimides, polyamides, or esters are more preferable.

Among these, a photosensitive compound containing a photoreactive group that is generated by at least one of dimerization or isomerization due to the action of light is preferably used as the photo-alignment compound.

Further, examples of the photoreactive group include a group having a cinnamic acid (cinnamoyl) structure (skeleton), a group having a coumarin structure (skeleton), a group having a chalcone structure (skeleton), a group having a benzophenone structure (skeleton), and a group having an anthracene structure (skeleton). Among these groups, a group having a cinnamoyl structure or a group having a coumarin structure is preferable, and a group having a cinnamoyl structure is more preferable.

In addition, the photosensitive compound containing a photo-aligned group may further contain a crosslinkable group.

As the crosslinkable group, a thermally crosslinkable group that causes a curing reaction due to the action of heat and a photocrosslinkable group that causes a curing reaction due to the action of light are preferable, and the crosslinkable group may be a crosslinkable group that contains both a thermally crosslinkable group and a photocrosslinkable group.

Examples of the crosslinkable group include at least one selected from the group consisting of an epoxy group, an oxetanyl group, a group represented by —NH—CH₂—O—R (R represents a hydrogen atom or an alkyl group having 1 to 20 carbon atoms), a group having an ethylenically unsaturated double bond, and a block isocyanate group. Among these, an epoxy group, an oxetanyl group, or a group having an ethylenically unsaturated double bond is preferable.

Further, a 3-membered cyclic ether group is also referred to as an epoxy group, and a 4-membered cyclic ether group is also referred to as an oxetanyl group.

Further, specific examples of the group having an ethylenically unsaturated double bond include a vinyl group, an allyl group, a styryl group, an acryloyl group, and a methacryloyl group. Among these, an acryloyl group or a methacryloyl group is preferable.

The photo-alignment film formed of the above-described material is irradiated with linearly polarized light or non-polarized light to produce a photo-alignment film.

In the present specification, the “irradiation with linearly polarized light” and the “irradiation with non-polarized light” are operations for causing a photoreaction in the photo-alignment material. The wavelength of the light to be used varies depending on the photo-alignment material to be used and is not particularly limited as long as the wavelength is required for the photoreaction. The peak wavelength of light to be used for irradiation with light is preferably in a range of 200 nm to 700 nm, and ultraviolet light having a peak wavelength of 400 nm or less is more preferable.

Examples of the light source used for irradiation with light include commonly used light sources, for example, lamps such as a tungsten lamp, a halogen lamp, a xenon lamp, a xenon flash lamp, a mercury lamp, a mercury xenon lamp, and a carbon arc lamp, various lasers [such as a semiconductor laser, a helium neon laser, an argon ion laser, a helium cadmium laser, and a yttrium aluminum garnet (YAG) laser], a light emitting diode, and a cathode ray tube.

As means for obtaining linearly polarized light, a method of using a polarizing plate (for example, an iodine polarizing plate, a dichroic substance polarizing plate, or a wire grid polarizing plate), a method of using a prism-based element (for example, a Glan-Thompson prism) or a reflective type polarizer for which a Brewster's angle is used, or a method of using light emitted from a laser light source having polarized light can be employed. In addition, only light having a required wavelength may be selectively applied using a filter, a wavelength conversion element, or the like.

In a case where light to be applied is linearly polarized light, a method of applying light vertically or obliquely to the upper surface with respect to the alignment film or the surface of the alignment film from the rear surface is employed. The incidence angle of light varies depending on the photo-alignment material, but is preferably in a range of 0 to 90° (vertical) and more preferably in a range of 40 to 90°.

In a case where light to be applied is non-polarized light, the alignment film is irradiated with non-polarized light obliquely. The incidence angle is preferably in a range of 10° to 80°, more preferably in a range of 20° to 60°, and still more preferably in a range of 30° to 50°.

The irradiation time is preferably in a range of 1 minute to 60 minutes and more preferably in a range of 1 minute to 10 minutes.

In a case where patterning is required, a method of performing irradiation with light using a photomask as many times as necessary for pattern preparation or a method of writing a pattern by laser light scanning can be employed.

<Aligning Step>

The aligning step is a step of aligning the dichroic substance contained in the coating film. In this manner, the light absorption anisotropic film according to the embodiment of the present invention can be obtained. In the aligning step, the dichroic substance is considered to be aligned along the liquid crystal compound aligned by the alignment film.

The aligning step may include a drying treatment. Components such as a solvent can be removed from the coating film by performing the drying treatment. The drying treatment may be performed by a method of allowing the coating film to stand at room temperature for a predetermined time (for example, natural drying) or a method of heating the coating film and/or blowing air to the coating film.

Here, the dichroic substance contained in the composition for forming a light absorption anisotropic film may be aligned by the coating film forming step or the drying treatment described above. For example, in an aspect in which the composition for forming a light absorption anisotropic film is prepared as a coating solution containing a solvent, the light absorption anisotropic film according to the embodiment of the present invention may be obtained by drying the coating film and removing the solvent from the coating film so that the dichroic substance contained in the coating film is aligned.

It is preferable that the aligning step includes a heat treatment. In this manner, the dichroic substance contained in the coating film is more aligned, and the alignment degree of the light absorption anisotropic film to be obtained is further increased.

From the viewpoint of the manufacturing suitability, the heating temperature is preferably in a range of 10° C. to 250° C. and more preferably 25° C. to 190° C. Further, the heating time is preferably in a range of 1 to 300 seconds and more preferably in a range of 1 to 60 seconds.

It is preferable that the heat treatment is performed in multiple stages at different heating temperatures and more preferable that the heat treatment in the first stage is performed and the heat treatment in the second and subsequent stages are performed at lower temperatures than the heating temperature of the heat treatment in the first stage.

In this manner, the light absorption anisotropic film according to the embodiment of the present invention which has a front surface and a rear surface with different polarization degrees is easily obtained. That is, in the vicinity of one surface of the light absorption anisotropic film in which the entire dichroic substance is horizontally aligned, the light absorption anisotropic film in which the dichroic substance is in an alignment state close to vertical alignment is considered to be easily obtained.

The aligning step may include a cooling treatment performed after the heat treatment. The cooling treatment is a treatment of cooling the coating film after being heated to room temperature (20° C. to 25° C.). In this manner, the alignment of the dichroic substance contained in the coating film is further fixed, and the alignment degree of the light absorption anisotropic film to be obtained is further increased. The cooling means is not particularly limited and can be performed according to a known method.

The light absorption anisotropic film according to the embodiment of the present invention can be obtained by performing the above-described steps.

[Other Steps]

The present production method may include a step of curing the light absorption anisotropic film after the aligning step (hereinafter, also referred to as “curing step”).

The curing step is performed by, for example, heating the layer and/or irradiating (exposing) the layer with light. Between these, it is preferable that the curing step is performed by irradiating the layer with light.

Various light sources such as infrared rays, visible light, and ultraviolet rays can be used as the light source for curing, but ultraviolet rays are preferable. In addition, ultraviolet rays may be applied while the film is heated during curing, or ultraviolet rays may be applied through a filter that transmits only a specific wavelength.

Further, the exposure may be performed under a nitrogen atmosphere. In a case where the curing of the light absorption anisotropic film proceeds by radical polymerization, since the inhibition of polymerization by oxygen is reduced, it is preferable that exposure is performed in a nitrogen atmosphere.

[Physical Properties and the Like of Light Absorption Anisotropic Film]

<Polarization Degree>

In the light absorption anisotropic film according to the embodiment of the present invention, a polarization degree A measured by allowing polarized light to be incident from one surface of the light absorption anisotropic film is different from a polarization degree B measured by allowing polarized light to be incident from the other surface of the light absorption anisotropic film.

The higher polarization degree between the polarization degree A and the polarization degree B is preferably in a range of 70% to 99.99%, more preferably in a range of 80% to 99.99%, and still more preferably in a range of 90% to 99.99%.

The lower polarization degree between the polarization degree A and the polarization degree B is preferably in a range of 70% to 99.89%, more preferably in a range of 80% to 99.89%, and still more preferably in a range of 90% to 99.89%.

From the viewpoint that the effects of the present invention are more excellent, the absolute value of a difference between the polarization degree A and the polarization degree B (hereinafter, also simply referred to as “difference in polarization degree”) is preferably 0.10% or greater, more preferably 0.20% or greater, and still more preferably 0.30% or greater.

Further, the upper limit of the difference in polarization degree is preferably 5.0% or less, more preferably 3.0% or less, and still more preferably 1.0% or less.

The polarization degree A and the polarization degree B are measured by the method described in the section of the examples below.

In a laminate including the light absorption anisotropic film, in a case where the measurement of the polarization degree of the single light absorption anisotropic film is affected by a layer other than the light absorption anisotropic film (for example, a case where a layer other than the light absorption anisotropic film has a value of an in-plane retardation), it is preferable that the polarization degree is measured by peeling or forming only the single light absorption anisotropic film or the polarization degree of the light absorption anisotropic film is acquired by considering the optical characteristics of the layer other than the light absorption anisotropic film.

<Absorption Axis>

It is preferable that the light absorption anisotropic film has an absorption axis in the plane.

In the present invention, the expression “light absorption anisotropic film has an absorption axis in the plane” denotes that in a case where a direction parallel to the plane of the light absorption anisotropic film and with maximized absorption is defined as an x-axis, a direction orthogonal to the x-axis in the plane of the light absorption anisotropic film is defined as a y-axis, and the thickness direction of the light absorption anisotropic film orthogonal to the x-axis and the y-axis is defined as a z-axis, the x-axis and the absorption axis coincide with each other in a case where the absorbance is continuously measured from the x-axis to the z-axis and a direction in which the absorption is maximized is defined as an absorption axis.

In the present invention, in a case where the light absorption anisotropic film has an absorption axis in the plane, most of the molecules of the dichroic substance in the light absorption anisotropic film are horizontally aligned (aligned in the in-plane direction of the light absorption anisotropic film).

<Out-of-Plane Alignment Degree F_{zx}>

The alignment state of the dichroic substance in the vicinity of the surface of the light absorption anisotropic film can be determined, for example, based on the value of the out-of-plane alignment degree f_{zx}. The out-of-plane alignment degree f_{zx} is theoretically 0 in a case of no alignment, −0.5 in a case of alignment completely in an observation direction, and 1.0 in a case of alignment orthogonal to the observation direction.

In the light absorption anisotropic film according to the embodiment of the present invention, in the surface of the light absorption anisotropic film on a side where a lower polarization degree is measured, the out-of-plane alignment degree f_{zx} of the dichroic substance in the surface with the lower polarization degree is preferably −0.2 or greater, more preferably 0 or greater, and still more preferably 0.2 or greater. As described above, in a case where the out-of-plane alignment degree f_{zx} of the dichroic substance in the surface with the lower polarization degree is −0.2 or greater, it can be said that the dichroic substance is in an alignment state close to vertical alignment in the surface with the lower polarization degree.

The upper limit of the out-of-plane alignment degree f_{zx} of the dichroic substance in the surface with the lower polarization degree is 1.0.

Here, the surface of the light absorption anisotropic film on a side where the lower polarization degree is measured denotes the incident surface of polarized light on a side where the lower polarization degree is measured in a case of the measurement of the polarization degree A and the polarization degree B of the light absorption anisotropic film. For example, in a case where the polarization degree A is less than the polarization degree B, the surface denotes the incident surface of polarized light in the light absorption anisotropic film in a case of the measurement of the polarization degree A.

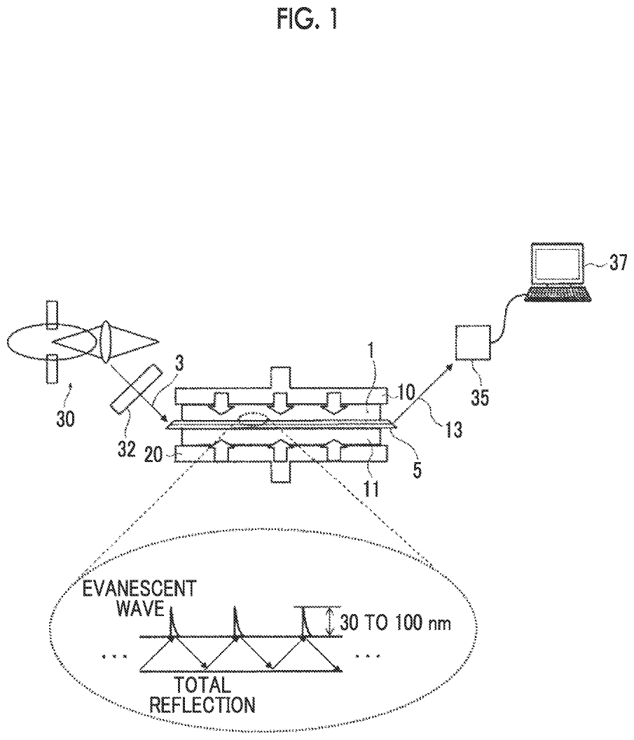

The out-of-plane alignment degree f_{zx} of the dichroic substance in the light absorption anisotropic film according to the embodiment of the present invention is calculated based on an absorbance spectrum of an object to be measured, which is measured with a waveguide spectroscopic analyzer illustrated in FIG. 1.

FIG. 1 is a schematic view illustrating a waveguide spectroscopic analyzer used for measuring the absorption peak intensity of the dichroic substance in the vicinity of the surface of the light absorption anisotropic film.

The waveguide spectroscopic analyzer illustrated in FIG. 1 includes a light source 30, a polarizer 32, a waveguide substrate 5, an upper holding tool 10 disposed on one surface side of the waveguide substrate 5, a lower holding tool 20 disposed on the other surface side of the waveguide substrate 5, a detector 35, and an analyzer 37.

An object 1 to be measured is disposed on the upper holding tool 10 side of the waveguide substrate 5. The object 1 to be measured is a laminate including the light absorption anisotropic film according to the embodiment of the present invention, and specifically, the laminate is formed such that the substrate (described below), the alignment film (described below), and the light absorption anisotropic film according to the embodiment of the present invention are laminated in this order. The object 1 to be measured is disposed such that the light absorption anisotropic film is on the waveguide substrate 5 side.

An object 11 to be measured is disposed on the lower holding tool 20 side of the waveguide substrate 5. The object 11 to be measured is the same laminate as the object 1 to be measured, and is disposed such that the light absorption anisotropic film is on the waveguide substrate 5.

The light generated by light emission of the light source 30 is polarized by the polarizer 32 and is incident on one end surface of the waveguide substrate 5 as an incidence ray 3. The incidence ray 3 incident on the waveguide substrate 5 is totally reflected at the interface between the object 1 to be measured and the waveguide substrate 5 and at the interface between the object 11 to be measured and the waveguide substrate 5 a plurality of times, and an evanescent wave is absorbed by the object 1 to be measured and the object 11 to be measured during the total reflection. Emitted light 13 emitted from the other end face of the waveguide substrate 5 is detected by the detector 35 which is a spectroscope. The absorbance spectra of the object 1 to be measured and the object 11 to be measured are obtained by the analyzer 37 performing calculation and analysis based on the emitted light 13 detected by detector 35 and the intensity of the incidence ray 3.

In a case where the evanescent wave infiltrates into a side of the object to be measured by several tens of nanometers during the total reflection, a region of the object to be measured at a depth of several tens of nanometers from the surface of the light absorption anisotropic film can be selectively measured.

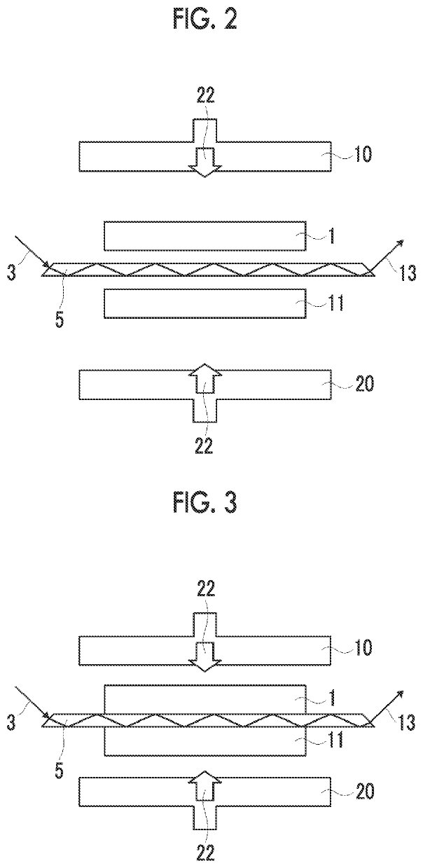

A method of measuring the absorbance spectrum using the waveguide spectroscopic analyzer of FIG. 1 will be described in more detail with reference to FIGS. 2 to 4.

First, the reference intensity (Ref intensity) is measured using the waveguide spectroscopic analyzer of FIG. 1. Specifically, as illustrated in FIG. 2, the light absorption spectrum is measured in a state where the object 1 to be measured and the object 11 to be measured are not in close contact with the waveguide substrate 5, and the measured value is corrected in a state where the object 1 to be measured and the object 11 to be measured are in close contact with the waveguide substrate 5. Further, the Ref intensity is acquired by allowing the incidence ray 3 to be incident from one end portion of the waveguide substrate 5, guiding the incidence ray 3 in the waveguide substrate 5 while being totally reflected at a total reflection angle of 64 degrees, emitting the emitted light 13 from the other end portion of the waveguide substrate 5 after the total reflection carried out approximately 20 times, and detecting the light intensity spectrum with the detector 35.

Next, a pressure is applied in a direction of an arrow 22 by the upper holding tool 10 and the lower holding tool 20 such that the object 1 to be measured and the object 11 to be measured are in close contact with the waveguide substrate 5 as illustrated in FIG. 3. Further, the light intensity spectrum is detected and defined as a Sig intensity in the same manner as in the measurement of the Ref intensity. The Sig intensity is corrected by the Ref intensity to acquire the absorbance spectrum of the object to be measured.

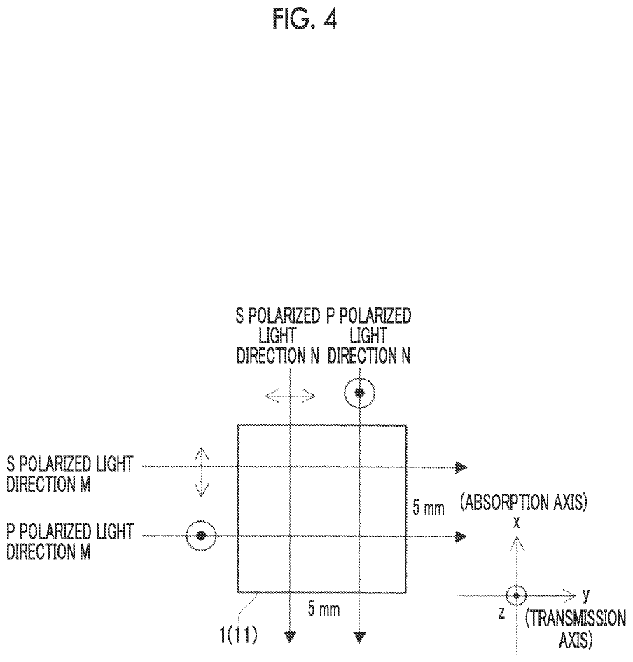

The above-described operation is performed in four patterns of a case where the polarization state of the incidence ray is in an S polarized light direction M and in a P polarized light direction M and a case where the polarization state of the incidence ray is in an S polarized light direction N and in a P polarized light direction N after rotation of the objects to be measured on both surfaces by 90 degrees. FIG. 4 illustrates the relationship between the traveling directions M and N of light and the orientation of the object to be measured.

In the obtained absorbance spectrum, the absorption peak near a wavelength of 270 nm is assumed to be absorption derived from the liquid crystal compound and the absorption peak near a wavelength of 650 nm is assumed to be absorption derived from the dichroic substance, and the respective absorption peak intensities are analyzed based on this assumption.

A method of calculating the out-of-plane alignment degree f_{zx} based on the absorption peak intensity measured in the above-described manner will be described below.

The spatial absorption coefficients in an in-plane absorption axis direction (x), an in-plane transmission axis direction (y), and a thickness direction (z) of the object to be measured are defined as kx, ky, and kz, and the absorption coefficients kx, ky, and kz are represented by the following equations.

$${k}_{x} = \frac{{A}_{SM}}{α}$$

$${k}_{y} = \frac{{A}_{SN}}{α}$$

$${k}_{z} = \frac{\{ ( \frac{{A}_{PM} - β {k}_{y}}{γ} ) + ( \frac{{A}_{PN} - β {k}_{x}}{γ} ) \}}{2}$$

Here, A_{SM} represents the peak absorbance in a case of S polarized light in the direction M, A_{SN} represents the absorbance at the peak wavelength in a case of S polarized light in the direction N, A_{PM} represents the peak absorbance in a case of P polarized light in the direction M, and A_{PN} represents the absorbance at the peak wavelength in a case of P polarized light in the direction N.

α, β, and γ are represented by the following equations.

$$α = \frac{4 {n}_{2}^{2}}{{n}_{1}^{2} tan {θ ( 1 - \frac{{n}_{2}^{2}}{{n}_{1}^{2} {sin}^{2} θ} )}^{\frac{1}{2}} ( 1 - \frac{{n}_{2}^{2}}{{n}_{1}^{2}} )}$$

$$β = \frac{4 {n}_{2}^{2} ( 1 - \frac{{n}_{2}^{2}}{{n}_{1}^{2} {sin}^{2} θ} )}{{n}_{1}^{2} tan {θ ( 1 - \frac{{n}_{2}^{2}}{{n}_{1}^{2} {sin}^{2} θ} )}^{\frac{1}{2}} ( 1 - \frac{{n}_{2}^{2}}{{n}_{1}^{2} {sin}^{2} θ} + \frac{{n}_{2}^{4}}{{n}_{1}^{4}} {cot}^{3} θ )}$$

$$γ = \frac{4 {n}_{2}^{2}}{{n}_{1}^{2} tan {θ ( 1 - \frac{{n}_{2}^{2}}{{n}_{1}^{2} {sin}^{2} θ} )}^{\frac{1}{2}} ( 1 - \frac{{n}_{2}^{2}}{{n}_{1}^{2} {sin}^{2} θ} + \frac{{n}_{2}^{4}}{{n}_{1}^{4}} {cot}^{2} θ )}$$

Here, n₁ represents the refractive index of the waveguide substrate, n₂ represents the refractive index of the object to be measured, and θ represents the total reflection angle.

The in-plane alignment degree f_{xy} and the out-of-plane alignment degree f_{zx} in the surface of the light absorption anisotropic film are represented as follows.

$${f}_{xy} = ( \frac{{D}_{xy} - 1}{{D}_{xy} + 2} ) \cdot ( \frac{{D}_{0} + 2}{{D}_{0} - 1} )$$

Here, D₀, D_{xy}, and D_{zx} are as follows.

$${D}_{0} = {cot}^{2} δ$$

$${D}_{xy} = \frac{{k}_{x}}{{k}_{y}}$$

$${D}_{zx} = \frac{{k}_{z}}{{k}_{x}}$$

Here, δ denotes an angle between the orientation of the absorption transition moment used for assignment and the molecular axis.

<Visible Light Average Transmittance>

The visible light average transmittance of the light absorption anisotropic film is preferably in a range of 35% to 70%, more preferably in a range of 38% to 60%, and still more preferably in a range of 40% to 50%. In a case where the visible light average transmittance of the light absorption anisotropic film is in the above-described ranges, the aligning properties of the liquid crystal compound and the effects of the present invention are excellent.

In the present invention, the average visible light transmittance denotes an arithmetic average value of the transmittances at every 5 nm in a visible light region (wavelength range of 400 nm to 700 nm). The transmittance is measured using a spectrophotometer (for example, a multi-channel spectroscope (trade name, “QE65000”, manufactured by OCEAN OPTICS Inc.).

<Thickness>

The thickness of the light absorption anisotropic film is not particularly limited, but is preferably in a range of 100 to 8,000 nm and more preferably in a range of 300 to 5,000 nm from the viewpoint of the flexibility in a case where a laminate according to the embodiment of the present invention is used in a polarizer.

[Laminate]

The laminate according to the embodiment of the present invention is a laminate including a protective layer, the above-described light absorption anisotropic film according to the embodiment of the present invention, and an alignment film in this order in the thickness direction. Further, the alignment film is disposed on the surface side of the light absorption anisotropic film on a side where the higher polarization degree is measured between the polarization degree A and the polarization degree B measured using the light absorption anisotropic film.

Here, the surface of the light absorption anisotropic film on a side where the higher polarization degree is measured denotes the incident surface of polarized light on a side where the higher polarization degree is measured in a case of the measurement of the polarization degree A and the polarization degree B of the light absorption anisotropic film. For example, in a case where the polarization degree B is greater than the polarization degree A, the surface denotes the incident surface of polarized light in the light absorption anisotropic film in a case of the measurement of the polarization degree B.

In a case where the laminate according to the embodiment of the present invention is applied to an image display device, the protective layer side is typically disposed on a viewing side (the incident side of light). It is assumed that in a case where the surface with a lower polarization degree (the surface with a lower refractive index) is disposed on the protective layer side, the difference in refractive index between the light absorption anisotropic film and the protective layer is decreased, and thus the internal reflection can be suppressed.

[Light Absorption Anisotropic Film]

The light absorption anisotropic film of the laminate according to the embodiment of the present invention is as described above, and thus the description thereof will not be repeated.

The refractive index of the light absorption anisotropic film at a wavelength of 550 nm is preferably in a range of 1.55 to 2.00 and more preferably in a range of 1.60 to 1.90.

Here, the refractive index of the light absorption anisotropic film at a wavelength of 550 nm denotes an average refractive index (nₐᵥₑ) and is represented by Equation (R1).

nₐᵥₑ=(nₓ+n_{y}+n_{z})/3 Equation (R1)

In Equation (R1), the direction in which the refractive index is maximized in the plane is defined as an x-axis, the direction orthogonal to the x-axis is defined as a y-axis, and the normal direction with respect to the plane is defined as a z-axis, and the respective refractive indices are defined as nₓ, n_{y}, and n_{z}. Each refractive index is measured using a spectroscopic ellipsometer M-2000U (manufactured by J. A. Woollam. Co., Inc.).

It is preferable that the refractive index of the light absorption anisotropic film at a wavelength of 550 nm is greater than the refractive index of the protective layer at a wavelength of 550 nm. As a result, the effects of the present invention are more excellent.

[Protective Layer]

The protective layer is not particularly limited, and examples thereof include an oxygen-shielding layer and an ultraviolet (UV) absorbing layer. Among these, an oxygen-shielding layer is preferable.

The oxygen-shielding layer is an oxygen-shielding film having an oxygen shielding function. In the present specification, the oxygen shielding function is not limited to a function for making a state where oxygen is not allowed to pass through the layer, and also includes a function for making a state where a small amount of oxygen is allowed to pass through the layer depending on the desired performance.

Specific examples of the oxygen-shielding layer include layers containing organic compounds such as polyvinyl alcohol, modified polyvinyl alcohol, polyethylene vinyl alcohol, polyvinyl ether, polyvinylpyrrolidone, polyacrylamide, polyacrylic acid, cellulose ether, polyamide, polyimide, a styrene/maleic acid copolymer, gelatin, vinylidene chloride, and cellulose nanofibers. Among these, polyacrylic acid, polyvinyl alcohol, or modified polyvinyl alcohol is preferable.

From the viewpoint of further improving the light resistance, the oxygen-shielding layer may further contain a light resistance improving agent together with the organic compound. Specific examples of the light resistance improving agent are as described in the section of the light absorption anisotropic film above. In a case where the oxygen-shielding layer contains the light resistance improving agent, the content of the light resistance improving agent is preferably in a range of 0.1% to 5.0% by mass and more preferably in a range of 0.3% to 3.0% by mass with respect to the total mass of the oxygen-shielding layer.

The thickness of the oxygen-shielding layer is preferably in a range of 0.1 to 10 μm and more preferably in a range of 0.5 to 5.5 μm.

The refractive index of the protective layer at a wavelength of 550 nm is preferably in a range of 1.40 to 1.60 and more preferably in a range of 1.45 to 1.55.

Here, the refractive index of the protective layer at a wavelength of 550 nm can be measured by the same method as the method for the average refractive index of the light absorption anisotropic film described above.

[Alignment Film]

The alignment film of the laminate according to the embodiment of the present invention is the same as the alignment film used in the above-described method of producing the light absorption anisotropic film, and thus the description thereof will not be repeated.

[Base Material]

The laminate according to the embodiment of the present invention may include a base material on the surface side of the alignment film opposite to the light absorption anisotropic film.

The base material can be selected depending on the applications of the light absorption anisotropic layer, and examples thereof include glass and a polymer film.

In a case where a polymer film is used as the base material, it is preferable to use an optically isotropic polymer film. As specific examples and preferred aspects of the polymer, the description in paragraph of JP2002-22942A can be applied. Further, even in a case of a polymer easily exhibiting the birefringence such as polycarbonate and polysulfone which has been known in the related art, a polymer with the exhibiting property which has been decreased by modifying the molecules described in WO2000/26705A can be used.

The visible light average transmittance of the base material is preferably 80% or greater.

[Optically Anisotropic Film]

it is preferable that the laminate according to the embodiment of the present invention includes an optically anisotropic film (optically anisotropic layer).

Here, the optically anisotropic film denotes all films showing a phase difference, and examples thereof include a stretched polymer film and a phase difference film provided with an optically anisotropic layer containing a liquid crystal compound aligned on a support.

Here, the alignment direction of the liquid crystal compound contained in the optically anisotropic layer is not particularly limited, and examples thereof include horizontal, vertical, and twisted alignment with respect to the film surface.

Further, a λ/4 plate, a λ/2 plate, and the like have specific functions of the optically anisotropic film.

In addition, the optically anisotropic layer may be formed of a plurality of layers. In regard to the optically anisotropic layer formed of a plurality of optically anisotropic layers, for example, the description in paragraphs to of JP2014-209219A can be referred to.

Further, such an optically anisotropic film and the above-described light absorption anisotropic film may be provided by coming into contact with each other, or another layer may be provided between the optically anisotropic film and the light absorption anisotropic film. Examples of such a layer include the above-described alignment film and a pressure sensitive adhesive layer or an adhesive layer for ensuring the adhesiveness.

It is preferable that the laminate according to the embodiment of the present invention uses a λ/4 plate as the above-described optically anisotropic film and has the λ/4 plate on the surface side of the alignment film opposite to the above-described light absorption anisotropic film.

Here, “λ/4 plate” is a plate having a λ/4 function, specifically, a plate having a function of converting linearly polarized light having a specific wavelength into circularly polarized light (or converting circularly polarized light into linearly polarized light).

For example, specific examples of an aspect in which a λ/4 plate has a single-layer structure include a stretched polymer film and a phase difference film in which an optically anisotropic layer having a λ/4 function is provided on a support. Further, specific examples of an aspect in which a λ/4 plate has a multilayer structure include a broadband λ/4 plate obtained by laminating a λ/4 plate and a λ/2 plate.

[Image Display Device]

An image display device according to the embodiment of the present invention includes the above-described light absorption anisotropic film or the above-described laminate according to the embodiment of the present invention.

The display element used in the image display device according to the embodiment of the present invention is not particularly limited, and examples thereof include a liquid crystal cell, an organic electroluminescence (organic EL) display panel, and a plasma display panel.

Among these, a liquid crystal cell or an organic EL display panel is preferable, and an organic EL display panel is more preferable. That is, in the display device according to the embodiment of the present invention, a liquid crystal display device obtained by using a liquid crystal cell as a display element or an organic EL display device obtained by using an organic EL display panel as a display element is preferable, and an organic EL display device is more preferable.

[Liquid Crystal Display Device]

A liquid crystal display device which is an example of the display device according to the embodiment of the present invention is a liquid crystal display device that includes the above-described optical laminate according to the embodiment of the present invention (but does not include a λ/4 plate) and a liquid crystal cell.

In the present invention, between the optical laminates provided on both sides of the liquid crystal cell, it is preferable that the laminate according to the embodiment of the present invention is used as a front-side (viewing side) polarizer and more preferable that the laminate according to the embodiment of the present invention is used as a front-side polarizer and a rear-side polarizer.

Hereinafter, the liquid crystal cell constituting the liquid crystal display device will be described in detail.

<Liquid Crystal Cell>

A liquid crystal cell for use in the liquid crystal display device is preferably in a vertical alignment (VA) mode, an optically compensated bend (OCB) mode, an in-plane-switching (IPS) mode, or a twisted nematic (TN) mode, but the liquid crystal cell is not limited thereto.

In the liquid crystal cell in a TN mode, rod-like liquid crystal molecules (rod-like liquid crystal compound) are substantially horizontally aligned in a case of no voltage application and further twistedly aligned at 60° to 120°. The liquid crystal cell in a TN mode is most frequently used as a color TFT liquid crystal display device and is described in a plurality of documents.

In the liquid crystal cell in a VA mode, rod-like liquid crystal molecules are substantially vertically aligned at the time of no voltage application. The concept of the liquid crystal cell in a VA mode includes (1) liquid crystal cell in a VA mode in a narrow sense where rod-like liquid crystal molecules are aligned substantially vertically in a case of no voltage application and substantially horizontally in a case of voltage application (described in JP1990-176625A (JP-H₂-176625A)), (2) liquid crystal cell (in a multi-domain vertical alignment (MVA) mode) (SID97, described in Digest of tech. Papers (proceedings) 28 (1997) 845) in which the VA mode is formed to have multi-domain in order to expand the viewing angle, (3) liquid crystal cell in an axially symmetric aligned microcell (n-ASM) mode in which rod-like liquid crystal molecules are substantially vertically aligned in a case of no voltage application and twistedly multi-domain aligned in a case of voltage application (described in proceedings of Japanese Liquid Crystal Conference, pp. 58 to 59 (1998)), and (4) liquid crystal cell in a SURVIVAL mode (presented at LCD International 98). Further, the liquid crystal cell may be of any of a patterned vertical alignment (PVA) type, a photo-alignment (optical alignment) type, or a polymer-sustained alignment (PSA) type. Details of these modes are described in JP2006-215326A and JP2008-538819A.

In the liquid crystal cell in an IPS mode, rod-like liquid crystal molecules are aligned substantially parallel to the substrate, and the liquid crystal molecules respond planarly through application of an electric field parallel to the substrate surface. In the IPS mode, black display is carried out in a state where no electric field is applied, and absorption axes of a pair of upper and lower polarizing plates are orthogonal to each other. A method of reducing leakage light during black display in an oblique direction and improve the viewing angle using an optical compensation sheet is disclosed in JP1998-54982A (JP-H10-54982A), JP1999-202323A (JP-H11-202323A), JP1997-292522A (JP-H9-292522A), JP1999-133408A (JP-H11-133408A), JP1999-305217A (JP-H11-305217A), and JP1998-307291A (JP-H10-307291A).

[Organic EL Display Device]

As an organic EL display device which is an example of the display device according to the embodiment of the present invention, an embodiment of a display device including the above-described laminate (preferably including a λ/4 plate) according to the embodiment of the present invention and an organic EL display panel in this order from the viewing side is suitably exemplified. In this case, it is preferable that the laminate is formed such that the protective layer, the light absorption anisotropic film, the alignment film, and the λ/4 plate are disposed in this order from the viewing side.

Further, the organic EL display panel is a display panel formed of an organic EL element obtained by sandwiching an organic light-emitting layer (organic electroluminescence layer) between electrodes (between a cathode and an anode). The configuration of the organic EL display panel is not particularly limited, and a known configuration is employed.

### EXAMPLES

Hereinafter, the present invention will be described in more detail with reference to examples. Materials, used amounts, ratios, treatment contents, treatment procedures, and the like described in the following examples can be appropriately changed without departing from the spirit of the present invention. Therefore, the scope of the present invention should not be limitatively interpreted by the following examples.

### Example 1

### Preparation of Transparent Support

The following composition was put into a mixing tank and stirred, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88: | |
| Polyester compound B described in | 12 parts by mass |
| example of JP2015-227955A: | |
| Compound F shown below: | 2 parts by mass |
| Methylene chloride (first solvent): | 430 parts by mass |
| Methanol (second solvent): | 64 parts by mass |

Compound F

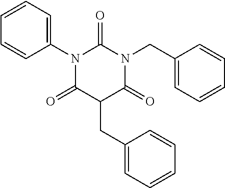 [SMILES: O=C1C(Cc2ccccc2)C(=O)N(c2ccccc2)C(=O)N1Cc1ccccc1]

10 parts by mass of the following matting agent solution was added to 90 parts by mass of the above-described core layer cellulose acylate dope, thereby preparing a cellulose acetate solution used as an outer layer cellulose acylate dope.

Matting agent solution

Silica particles with average particle size of 20 nm (AEROSIL R972,
manufactured by Nippon Aerosil Co., Ltd.): 2 parts by mass
Methylene chloride (first solvent): 76 parts by mass
Methanol (second solvent): 11 parts by mass
Core layer cellulose acylate dope described above: 1 parts by mass

The core layer cellulose acylate dope and the outer layer cellulose acylate dope were filtered through filter paper having an average pore size of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off from the drum in a state where the solvent content in the film was approximately 20% by mass, both ends of the film in the width direction were fixed with tenter clips, and the film was dried while being stretched in the lateral direction at a stretching ratio of 1.1 times.

Thereafter, the obtained film was further dried by being transported between the rolls of the heat treatment device to prepare a transparent support having a thickness of 40 μm, and the transparent support was used as a cellulose acylate film A1.

[Formation of Photo-Alignment Film B1]

The cellulose acylate film A1 was continuously coated with the following composition for forming a photo-alignment film using a wire bar. The support on which a coating film was formed was dried with hot air at 140° C. for 120 seconds, and the coating film was irradiated with polarized ultraviolet rays (10 mJ/cm², using an ultra-high pressure mercury lamp) to form a photo-alignment film B1, thereby obtaining a triacetyl cellulose (TAC) film with a photo-alignment film. The film thickness of the photo-alignment film B1 was 0.25

(Composition for forming photo-alignment film)

| | |
|---|---|
| Polymer PA-1 shown below: | 100.00 parts by mass |
| Acid generator PAG-1 shown below: | 8.25 parts by mass |
| Stabilizer DIPEA shown below: | 0.6 parts by mass |
| Xylene: | 1126.60 parts by mass |
| Methyl isobutyl ketone: | 125.18 parts by mass |

Polymer PA-1 (In the formulae, the numerical value described in each repeating unit denotes the content (% by mass) of each repeating unit with respect to all repeating units) 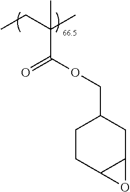 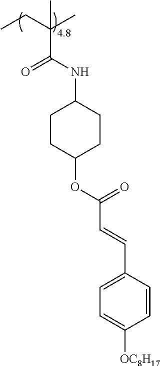 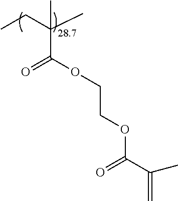
Acid generator PAG-1 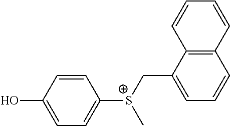 [SMILES: C[S+](Cc1cccc2ccccc12)c1ccc(O)cc1] 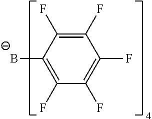
Stabilizer DIPEA

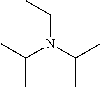

### Preparation of Light Absorption Anisotropic Film C1

The obtained photo-alignment film B1 was continuously coated with a composition for forming a light absorption anisotropic film with the following composition using a wire bar, to form a coating film.

Next, the coating film was heated at 140° C. for 15 seconds, subjected to a heat treatment at 80° C. for 5 seconds, and cooled to room temperature (23° C.). Next, the coating film was heated at 75° C. for 60 seconds and cooled to room temperature again.

Thereafter, a light absorption anisotropic layer C1 (polarizer) (thickness: 1.8 μm) was prepared on the photo-alignment film B1 by irradiating the coating film with a light emitting diode (LED) lamp (central wavelength of 365 nm) for 2 seconds under an irradiation condition of an illuminance of 200 mW/cm².

The transmittance of the light absorption anisotropic layer C1 in a wavelength range of 280 to 780 nm was measured with a spectrophotometer, and the visible light average transmittance was 42%.

The absorption axis of the light absorption anisotropic layer C1 was in the plane of the light absorption anisotropic layer C1 and was orthogonal to the width direction of the cellulose acylate film A1.

Composition of composition for forming light absorption anisotropic film

| | |
|---|---|
| First dichroic substance Dye-C1 shown below: | 0.65 parts by mass |
| Second dichroic substance Dye-M1 shown below: | 0.15 parts by mass |
| Third dichroic substance Dye-Y1 shown below: | 0.52 parts by mass |
| Liquid crystal compound L-1 shown below: | 2.69 parts by mass |
| Liquid crystal compound L-2 shown below: | 1.15 parts by mass |
| Adhesion improving agent A-1 shown below: | 0.17 parts by mass |
| Polymerization initiator IRGACURE OXE-02 (manufactured by BASF SE): | 0.17 parts by mass |
| Surfactant F-1 shown below: | 0.013 parts by mass |
| Cyclopentanone: | 92.14 parts by mass |
| Benzyl alcohol: | 2.36 parts by mass |

Dichroic substance Dye-C1 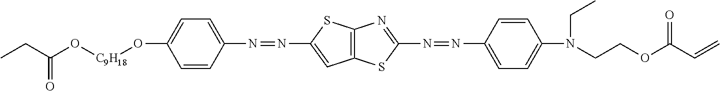
Dichroic substance Dye-M1 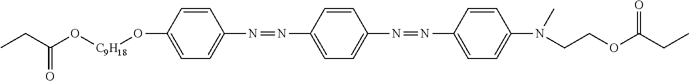
Dichroic substance Dye-Y1 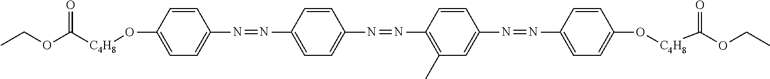
Liquid crystal compound L-1 (in the formulae, the numerical value (“59”, “15”, or “26”) described in each repeating unit denotes the content (% by mass) of each repeating unit with respect to all repeating units) 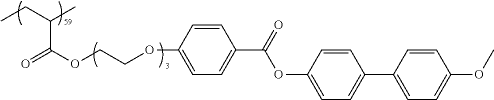 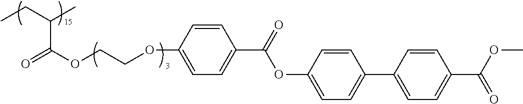 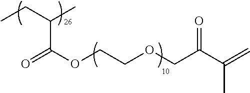
Liquid crystal compound L-2 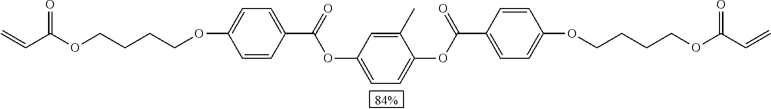 [SMILES: C=CC(=O)OCCCCOc1ccc(C(=O)Oc2ccc(OC(=O)c3ccc(OCCCCOC(=O)C=C)cc3)c(C)c2)cc1] 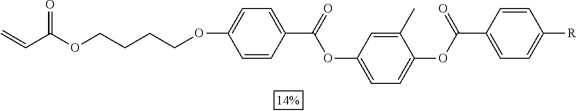 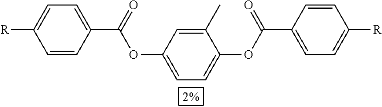 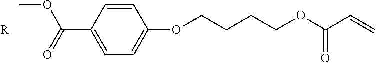
Adhesion improving agent A-1 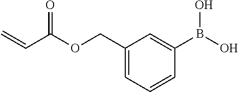
Surfactant F-1 (in the formulae, the numerical value described in each repeating unit denotes the content (% by mass) of each repeating unit with respect to all repeating units, and Ac denotes —C(O)CH₃)

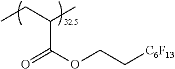

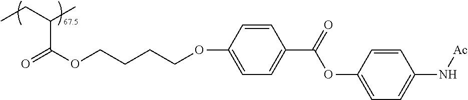

[Formation of Oxygen-Shielding Layer D1]

The light absorption anisotropic film C1 was continuously coated with a coating solution D1 having the following composition with a wire bar. Thereafter, the film was dried with hot air at 80° C. for 5 minutes, thereby obtaining a laminate on which the oxygen-shielding layer D1 consisting of polyvinyl alcohol (PVA) having a thickness of 1.0 μm was formed, that is, a laminate CP1 in which the cellulose acylate film A1 (transparent support), the photo-alignment film B1, the light absorption anisotropic film C1, and the oxygen-shielding layer D1 were provided adjacent to each other in this order.

Composition of coating solution D1 for forming oxygen-shielding layer

| | |
|---|---|
| Modified polyvinyl alcohol shown below: | 3.80 parts by mass |
| Initiator Irg2959: | 0.20 parts by mass |
| Water: | 70 parts by mass |
| Methanol: | 30 parts by mass |

Modified polyvinyl alcohol

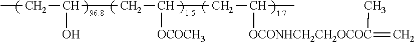

### Preparation of TAC Film Including Positive A-Plate

The cellulose acylate film A1 was continuously coated with a coating solution E1 for forming a photo-alignment film having the following composition using a wire bar. The support on which the coating film was formed was dried with hot air at 140° C. for 120 seconds, and the coating film was irradiated with polarized ultraviolet rays (10 mJ/cm², using an ultra-high pressure mercury lamp) to form a photo-alignment film E1 having a thickness of 0.2 μm, thereby obtaining a TAC film with a photo-alignment film.

Coating solution E1 for forming photo-alignment film

| | |
|---|---|
| Polymer PA-2 shown below: | 100.00 parts by mass |
| Acid generator PAG-1 shown above: | 5.00 parts by mass |
| Acid generator CPI-110TF shown below: | 0.005 parts by mass |
| Isopropyl alcohol: | 16.50 parts by mass |
| Butyl acetate: | 1072.00 parts by mass |
| Methyl ethyl ketone: | 268.00 parts by mass |

Acid generator CPI-110TF 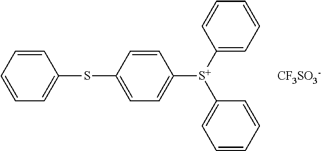
Polymer PA-2

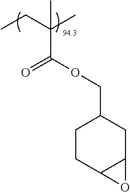

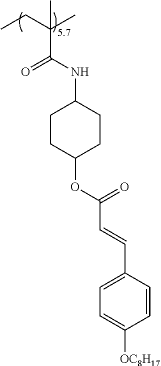

The photo-alignment film E1 was coated with a composition F1 having the following composition using a bar coater. The coating film formed on the photo-alignment film E1 was heated to 120° C. with hot air, cooled to 60° C., irradiated with ultraviolet rays having a wavelength of 365 nm with an illuminance of 100 mJ/cm² using a high-pressure mercury lamp in a nitrogen atmosphere, and continuously irradiated with ultraviolet rays with an illuminance of 500 mJ/cm² while being heated at 120° C. so that the alignment of the liquid crystal compound was immobilized, thereby preparing a TAC film having a positive A-plate F1.

The thickness of the positive A-plate F1 was 2.5 and the Re (550) was 144 nm. Further, the positive A-plate satisfied the relationship of “Re(450)≤Re(550)≤Re(650)”. Re(450)/Re(550) was 0.82.

Composition F1

| | |
|---|---|
| Polymerizable liquid crystal compound LA-1 shown below: | 43.50 parts by mass |
| Polymerizable liquid crystal compound LA-2 shown below: | 43.50 parts by mass |
| Polymerizable liquid crystal compound LA-3 shown below: | 8.00 parts by mass |
| Polymerizable liquid crystal compound LA-4 shown below: | 5.00 parts by mass |
| Polymerization initiator PI-1 shown below: | 0.55 parts by mass |
| Leveling agent T-1: | 0.20 parts by mass |
| Cyclopentanone: | 235.00 parts by mass |

Polymerizable liquid crystal compound LA-1 (tBu represents tertiary butyl group) 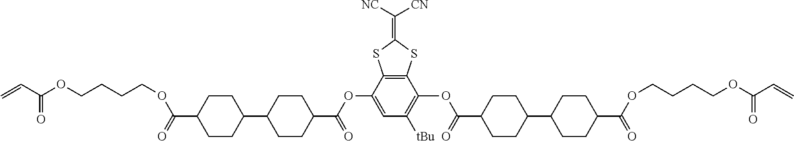 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-2 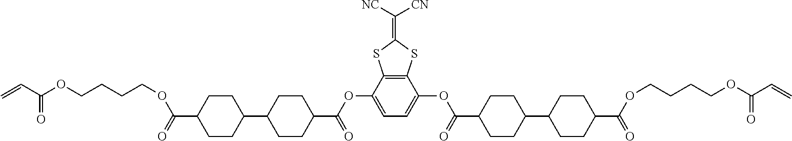 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-3 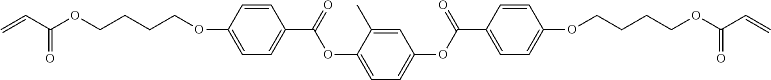 [SMILES: C=CC(=O)OCCCCOc1ccc(C(=O)Oc2ccc(OC(=O)c3ccc(OCCCCOC(=O)C=C)cc3)c(C)c2)cc1]
Polymerizable liquid crystal compound LA-4 (Me represents methyl group) 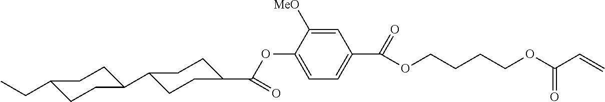 [SMILES: C=CC(=O)OCCCCOC(=O)c1ccc(OC(=O)C2CCC(C3CCC(CC)CC3)CC2)c(OC)c1]
Polymerization initiator PI-1 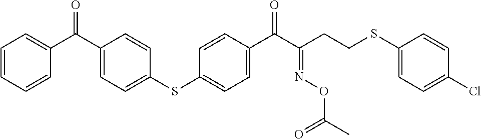 [SMILES: CC(=O)O/N=C(\CCSc1ccc(Cl)cc1)C(=O)c1ccc(Sc2ccc(C(=O)c3ccccc3)cc2)cc1]
Leveling agent T-1

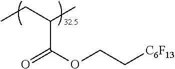

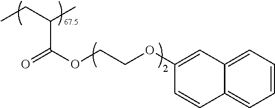

### Preparation of TAC Film Having Positive C-Plate H1

The above-described cellulose acylate film A1 was used as a temporary support.

The cellulose acylate film A1 was allowed to pass through a dielectric heating roll at a temperature of 60° C., the film surface temperature was increased to 40° C., one surface of the film was coated with an alkaline solution having the following composition such that the coating amount reached 14 ml/m² using a bar coater and heated to 110° C., and the film was transported for 10 seconds under a steam-type far-infrared heater (manufactured by Noritake Co., Ltd.).

Next, the film was coated with pure water such that the coating amount reached 3 ml/m² using the same bar coater. Next, the process of washing the film with water using a fountain coater and draining the film using an air knife was repeated three times, and the film was transported to a drying zone at 70° C. for 10 seconds and dried, thereby preparing a cellulose acylate film A1 which had been subjected to an alkali saponification treatment.

(Alkaline solution)

Potassium hydroxide: 4.7 parts by mass
Water: 15.8 parts by mass
Isopropanol: 63.7 parts by mass
Fluorine-containing surfactant SF-1 (C₁₄H₂₉O(CH₂CH₂O)₂₀H): 1.0 parts
by mass
Propylene glycol: 14.8 parts by mass

The cellulose acylate film A1 that had been subjected to the alkali saponification treatment was continuously coated with a coating solution G1 for forming a photo-alignment film having the following composition using a #8 wire bar. The obtained film was dried with hot air at 60° C. for 60 seconds and further dried with hot air at 100° C. for 120 seconds to form a photo-alignment film G1.

Coating solution G1 for forming photo-alignment film

Polyvinyl alcohol (PVA103, manufactured by Kuraray Co., Ltd.): 2.4
parts by mass
Isopropyl alcohol: 1.6 parts by mass
Methanol: 36 parts by mass
Water: 60 parts by mass

The photo-alignment film G1 was coated with a coating solution H1 for forming a positive C-plate having the following composition, the obtained coating film was aged at 60° C. for 60 seconds and irradiated with ultraviolet rays at an illuminance of 1,000 mJ/cm² in the air using an air-cooled metal halide lamp at an illuminance of 70 mW/cm² (manufactured by Eye Graphics Co., Ltd.), and the alignment state thereof was immobilized to vertically align the liquid crystal compound, thereby preparing a TAC film having a positive C-plate H1 with a thickness of 0.5 μm.

The Rth (550) of the obtained positive C-plate was −60 nm.

Coating solution H1 for forming positive C-plate

| | |
|---|---|
| Liquid crystal compound LC-1 shown below: | 80 parts by mass |
| Liquid crystal compound LC-2 shown below: | 20 parts by mass |
| Vertically aligned liquid crystal compound alignment agent S01: | 1 part by mass |
| Ethylene oxide-modified trimethylolpropane triacrylate (V#360, manufactured by | 8 parts by mass |
| Osaka Organic Chemical Industry Ltd.): | |
| IRGACURE 907 (manufactured by BASF SE): | 3 parts by mass |
| KAYACURE DETX (manufactured by Nippon Kayaku Co., Ltd.): | 1 part by mass |
| Compound B03 shown below: | 0.4 parts by mass |
| Methyl ethyl ketone: | 170 parts by mass |
| Cyclohexanone: | 30 parts by mass |

Liquid crystal compound LC-1 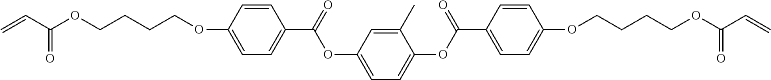 [SMILES: C=CC(=O)OCCCCOc1ccc(C(=O)Oc2ccc(OC(=O)c3ccc(OCCCCOC(=O)C=C)cc3)c(C)c2)cc1]
Liquid crystal compound LC-2 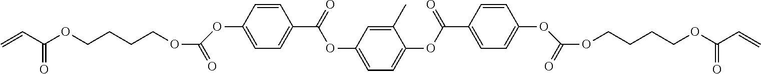 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]
Vertically aligned liquid crystal compound alignment agent S01 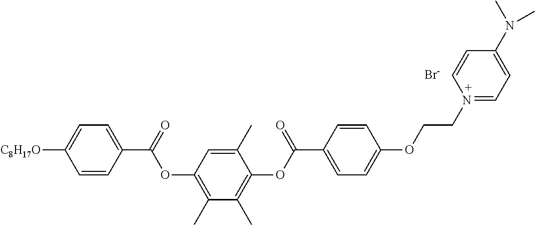
Compound B03

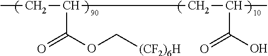

### Preparation of Pressure Sensitive Adhesives N1 and N2

Next, an acrylate-based polymer was prepared according to the following procedures.

95 parts by mass of butyl acrylate and 5 parts by mass of acrylic acid were polymerized by a solution polymerization method in a reaction container equipped with a cooling pipe, a nitrogen introduction pipe, a thermometer, and a stirrer, thereby obtaining an acrylate-based polymer (NA1) with an average molecular weight of 2,000,000 and a molecular weight distribution (Mw/Mn) of 3.0.

Next, an acrylate-based pressure sensitive adhesive was prepared with the following compositions using the obtained acrylate-based polymer (NA1). Each separate film that had been subjected to a surface treatment with a silicone-based release agent was coated with the composition using a die coater, dried in an environment of 90° C. for 1 minute, and irradiated with ultraviolet rays (UV) under the following conditions, thereby obtaining the following acrylate-based pressure sensitive adhesives N1 N2 (pressure sensitive adhesive layers). The composition and the film thickness of the acrylate-based pressure sensitive adhesive are shown below.

<UV Irradiation Conditions>
Electrodeless lamp H bulb (Fusion Co., Ltd.)
Illuminance of 600 mW/cm², light dose of 150 mJ/cm²
The UV illuminance and the light dose were measured using “UVPF-36” (manufactured by Eye Graphics Co., Ltd.).

(Acrylate-based pressure sensitive adhesive
N1 (film thickness of 15 μm)

Acrylate-based polymer (NA1): 100 parts by mass
(A) Polyfunctional acrylate-based monomer shown below: 11.1 parts by
mass
(B) Photopolymerization initiator shown below: 1.1 parts by mass
(C) Isocyanate-based crosslinking agent shown below: 1.0 parts by mass
(D) Silane coupling agent shown below: 0.2 parts by mass

(Acrylate-based pressure sensitive adhesive
N2 (film thickness of 25 μm))

Acrylate-based polymer (NA1): 100 parts by mass
(C) Isocyanate-based crosslinking agent shown below: 1.0 parts by mass
(D) Silane coupling agent shown below: 0.2 parts by mass

(A) Polyfunctional acrylate-based monomer: tris(acryloyloxyethyl) isocyanurate, molecular weight=423, trifunctional type (trade name, “ARONIX M-315”, manufactured by Toagosei Co., Ltd.)
(B) Photopolymerization initiator: mixture of benzophenone and 1-hydroxycyclohexyl phenyl ketone at mass ratio of 1:1, “IRGACURE 500” (manufactured by Ciba Specialty Chemicals Corp.)
(C) Isocyanate-based crosslinking agent: trimethylolpropane-modified tolylene diisocyanate (“CORONATE L”, manufactured by Nippon Polyurethane Industry Co., Ltd.)
(D) Silane coupling agent: 3-glycidoxypropyltrimethoxysilane (“KBM-403”, manufactured by Shin-Etsu Chemical Co., Ltd.)

### Preparation of UV Adhesive

A UV adhesive composition having the following composition was prepared.

UV adhesive composition

| | |
|---|---|
| CEL2021P (manufactured by Daicel | 70 parts by mass |
| Corporation) shown below: | |
| 1,4-Butanediol diglycidyl ether: | 20 parts by mass |
| 2-Ethylhexyl glycidyl ether: | 10 parts by mass |
| CPI-100P: | 2.25 parts by mass |

CPI-100P

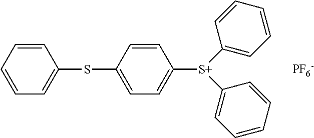

### Preparation of Laminate CPAC1

The TAC film having the positive A-plate F1 on the phase difference side and the TAC film having the positive C-plate H1 on the phase difference side were bonded to each other by irradiation with UV rays having a light dose of 600 mJ/cm² using the UV adhesive composition. The thickness of the UV adhesive layer was 3 Further, the surfaces bonded to each other with the UV adhesive were respectively subjected to a corona treatment. Next, the photo-alignment film E1 on the positive A-plate F1 side and the cellulose acylate film A1 were removed to obtain a retardation plate AC1. Further, the retardation plate AC1 has a layer configuration of the positive A-plate F1, the UV adhesive layer, the positive C-plate H1, the photo-alignment film G1, and the cellulose acylate film A1.

The laminate CP1 on the side of the oxygen-shielding layer was bonded to the low-reflection surface film CV-LC5 (manufactured by FUJIFILM Corporation) on the side of the support using the pressure sensitive adhesive N1. Next, only the cellulose acylate film A1 of the laminate CP1 was removed, and the surface from which the film had been removed and the retardation plate AC1 on the side of the positive A-plate F1 were bonded to each other using the pressure sensitive adhesive N1. Next, the photo-alignment film G1 on the side of the positive C-plate H1 and the cellulose acylate film A1 included in the retardation plate AC1 were removed, thereby preparing a laminate CPAC1. At this time, the films were bonded to each other such that an angle between the absorption axis of the light absorption anisotropic film C1 included in the laminate CPAC1 and the slow axis of the positive A-plate F1 was set to 45°. Further, the laminate CPAC1 has a layer configuration of the low-reflection surface film CV-LC5, the pressure sensitive adhesive layer N1, the oxygen-shielding layer D1, the light absorption anisotropic film C1, the photo-alignment film B1, the pressure sensitive adhesive layer N1, the positive A-plate F1, the UV adhesive layer, and the positive C-plate H1.

GALAXY S5 (manufactured by Samsung Electronics Co., Ltd.) equipped with an organic EL panel (organic EL display element) was disassembled, the touch panel provided with a circularly polarizing plate was peeled off from the organic EL display device, the circularly polarizing plate was further peeled off from the touch panel, and the organic EL display element, the touch panel, and the circularly polarizing plate were isolated from each other. Subsequently, the isolated touch panel was bonded to the organic EL display element again, and the laminate CPAC1 on the side of the positive C-plate 1 which had been prepared above was bonded onto the touch panel such that air did not enter, thereby preparing an organic EL display device.

### Examples 2 to 5 and Comparative Examples 1 to 4

Each laminate and each organic EL display device were prepared by the same method as in Example 1 except that the kind of the surfactant in the composition for forming a light absorption anisotropic film and the content of the surfactant with respect to the total solid content of the composition for forming a light absorption anisotropic film were changed as listed in Table 1.

All absorption axes of the light absorption anisotropic films in Examples 2 to 5 and Comparative Examples 1 to 3 were in the plane of the light absorption anisotropic film as in Example 1 and were orthogonal to the width direction of the cellulose acylate film A1.

Further, alignment failure occurred in the light absorption anisotropic film of Comparative Example 4, and thus it was not possible to evaluate the polarization degree, the display performance, and the like described below.

In the formulae, the numerical value described in each repeating unit in the surfactants (F-2) to (F-6) represents the content (% by mass) of each repeating unit with respect to all the repeating units. In addition, Ac represents —C(O)CH₃, and Me represents a methyl group.

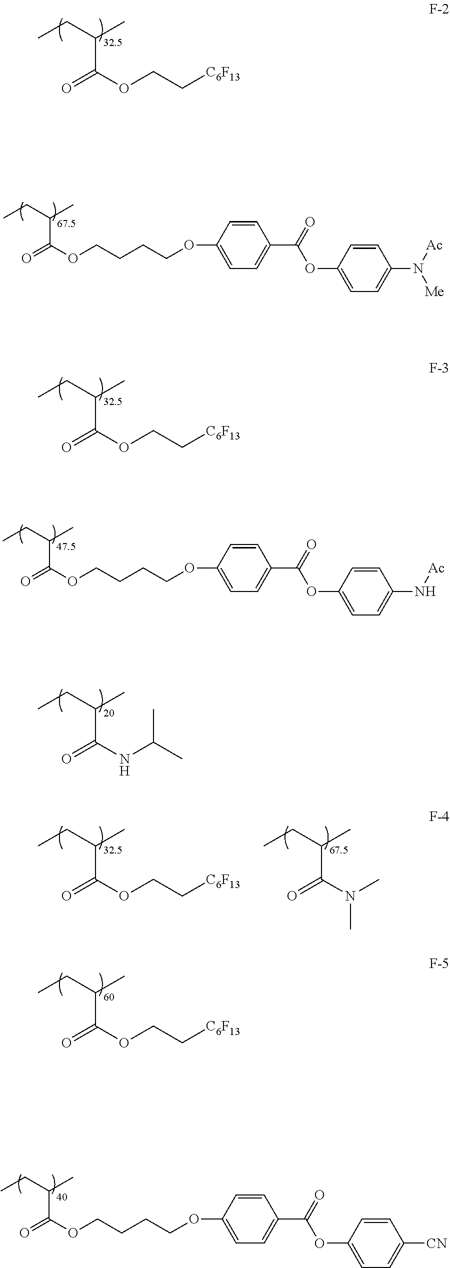

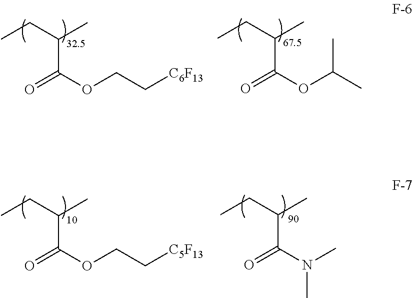

### Example 6

A laminate CPAC2 was prepared in the same manner as that for the laminate CPAC1 except that the laminate CP1 was changed to the laminate CP2 obtained as follows, and an organic EL display device was further prepared.

### Preparation of Cellulose Acylate Film A2

The following composition was put into a mixing tank, stirred, and further heated at for 10 minutes. Thereafter, the obtained composition was filtered through filter paper having an average pore size of 34 μm and a sintered metal filter having an average pore size of thereby preparing a dope. The concentration of solid contents of the dope was 23.5% by mass, the addition amount of the plasticizer was the ratio to the cellulose acylate, and the solvent of the dope was methylene chloride/methanol/butanol=81/18/1 (mass ratio).

Cellulose acylate dope

| | |
|---|---|
| Cellulose acylate (acetyl substitution degree: 2.86, viscosity average | 100 parts by mass |
| polymerization degree: 310): | |
| Sugar ester compound 1 (Formula (S4)): | 6.0 parts by mass |
| Sugar ester compound 2 (Formula (S5)): | 2.0 parts by mass |
| Silica particle dispersion liquid (AEROSIL R972, manufactured by | 0.1 parts by mass |
| Nippon Aerosil Co., Ltd.): | |
| Solvent (methylene chloride/methanol/butanol): | 351.9 parts by mass |

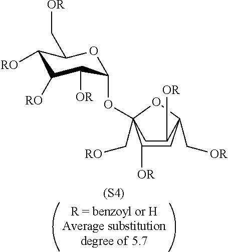

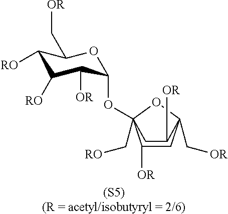

The dope prepared above was cast using a drum film forming machine. The dope was cast from a die such that the dope was in contact with the metal support cooled to 0° C., and the obtained web (film) was peeled off a drum. Further, the drum was made of stainless steel (SUS).

The web (film) obtained by casting was peeled off from the drum and dried in a tenter device for 20 minutes using a tenter device such that both ends of the web were clipped with clips and transported at 30° C. to 40° C. during film transport. Subsequently, the web was post-dried by zone heating while being transported using a roll. The obtained web was subjected to knurling and wound up to obtain a cellulose acylate film A2.

The film thickness of the obtained cellulose acylate film A2 was 60 μm, the in-plane retardation Re (550) at a wavelength of 550 nm was 1 nm, and the retardation Rth (550) at a wavelength of 550 nm in the thickness direction was 35 nm.

[Formation of Photo-Alignment Film B2]

The cellulose acylate film A2 was continuously coated with the following composition for forming a photo-alignment film using a wire bar. The support on which a coating film was formed was dried with hot air at 140° C. for 120 seconds, and the coating film was irradiated with polarized ultraviolet rays (10 mJ/cm², using an ultra-high pressure mercury lamp) to form a photo-alignment film B2, thereby obtaining a triacetyl cellulose (TAC) film with a photo-alignment film. The film thickness of the photo-alignment film B2 was 1 μm.

(Composition for forming photo-alignment film)

Polymer PA-1: 100.00 parts by mass
EPICLON N-695 (manufactured by DIC Corporation): 53.85 parts
by mass
Acid generator PAG-1: 12.69 parts by mass
Stabilizer DIPEA: 0.92 parts by mass
Methyl ethyl ketone: 307.01 parts by mass
Butyl acetate: 921.03 parts by mass

### Preparation of Light Absorption Anisotropic Film C2

The obtained photo-alignment film B2 was continuously coated with a composition for forming a light absorption anisotropic film with the following composition using a wire bar, to form a coating film.

Next, the coating film was heated at 140° C. for 15 seconds, subjected to a heat treatment at 80° C. for 5 seconds, and cooled to room temperature (23° C.). Next, the coating film was heated at 75° C. for 60 seconds and cooled to room temperature again.

Thereafter, a light absorption anisotropic layer C2 (polarizer) (thickness: 0.45 μm) was prepared on the photo-alignment film B2 by irradiating the coating film with a light emitting diode (LED) lamp (central wavelength of 365 nm) for 2 seconds under an irradiation condition of an illuminance of 200 mW/cm².

The transmittance of the light absorption anisotropic layer C1 in a wavelength range of 280 to 780 nm was measured with a spectrophotometer, and the visible light average transmittance was 49%.

Composition of composition for forming light absorption anisotropic film

| | |
|---|---|
| First dichroic substance Dye-C1 shown below: | 0.45 parts by mass |
| Second dichroic substance Dye-M1 shown below: | 0.20 parts by mass |
| Third dichroic substance Dye-Y1 shown below: | 0.18 parts by mass |
| Liquid crystal compound L-1: | 2.39 parts by mass |
| Liquid crystal compound L-2: | 1.34 parts by mass |
| Adhesion improving agent A-1: | 0.15 parts by mass |
| Polymerization initiator IRGACURE OXE-02 | 0.15 parts by mass |
| (manufactured by BASF SE): | |
| Surfactant F-8: | 0.026 parts by mass |
| Cyclopentanone: | 92.75 parts by mass |
| Benzyl alcohol: | 2.38 parts by mass |

Surfactant F-8

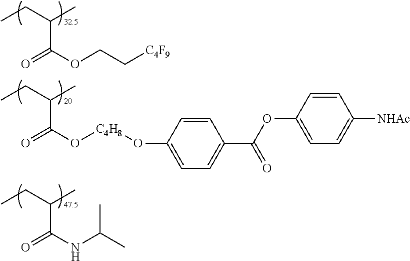

In the formula shown above, “Ac” represents an acetyl group.

The log P value of the surfactant F-8 is 3.3.

[Formation of Oxygen-Shielding Layer D2]

The light absorption anisotropic film C2 was continuously coated with a coating solution D2 having the following composition with a wire bar.

Thereafter, the film was dried with hot air at 80° C. for 5 minutes, thereby obtaining a laminate on which the oxygen-shielding layer D2 consisting of polyvinyl alcohol (PVA) having a thickness of 0.35 μm was formed, that is, a laminate CP2 in which the cellulose acylate film A2 (transparent support), the photo-alignment film B2, the light absorption anisotropic film C2, and the oxygen-shielding layer D2 were provided adjacent to each other in this order.

Composition of coating solution D2 for forming oxygen-shielding layer

| | |
|---|---|
| Modified polyvinyl alcohol shown above: | 3.31 parts by mass |
| Initiator Irg2959: | 0.17 parts by mass |
| Glutaraldehyde: | 0.07 parts by mass |
| Pyridinium paratoluene sulfonate: | 0.05 parts by mass |
| Surfactant F-9 shown below: | 0.0018 parts by mass |
| Water: | 74.0 parts by mass |
| Ethanol: | 22.4 parts by mass |

Surfactant F-9

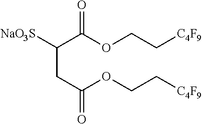

### Example 7

A laminate CPAC3 was prepared in the same manner as that for the laminate CPAC2 except that the composition of the composition for forming a light absorption anisotropic film was changed as follows, and an organic EL display device was further prepared.

Composition of composition for forming light absorption anisotropic film

| | |
|---|---|
| First dichroic substance Dye-C1 shown below: | 0.45 parts by mass |
| Second dichroic substance Dye-M1 shown below: | 0.20 parts by mass |
| Third dichroic substance Dye-Y1 shown below: | 0.18 parts by mass |
| Liquid crystal compound L-1: | 2.36 parts by mass |
| Liquid crystal compound L-2: | 1.34 parts by mass |
| Adhesion improving agent A-1: | 0.15 parts by mass |
| Polymerization initiator IRGACURE OXE-02(manufactured by BASF SE): | 0.15 parts by mass |
| Surfactant F-8: | 0.026 parts by mass |
| Light resistance improving agent B-1 shown below: | 0.029 parts by weight |
| Cyclopentanone: | 92.75 parts by mass |
| Benzyl alcohol: | 2.38 parts by mass |

Light resistance improving agent B-1

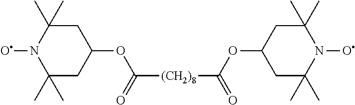

### Example 8

A laminate CPAC4 was prepared in the same manner as that for the laminate CPAC2 except that the coating solution D2 for forming an oxygen-shielding layer was changed to a coating solution D3 for forming an oxygen-shielding layer obtained as follows, and an organic EL display device was further prepared.

Composition of coating solution D3
for forming oxygen-shielding layer

Modified polyvinyl alcohol shown above: 3.28 parts by mass
Initiator Irg2959: 0.17 parts by mass
Glutaraldehyde: 0.07 parts by mass
Pyridinium paratoluene sulfonate: 0.05 parts by mass
Surfactant F-9: 0.0018 parts by mass
Light resistance improving agent B-1: 0.036 parts by weight
Water: 74.0 parts by mass
Ethanol: 22.4 parts by mass

### Example 9

The cellulose acylate film A2 was continuously coated with the following composition for forming a photo-alignment film using a wire bar. The support on which a coating film was formed was dried with hot air at 140° C. for 120 seconds, and the coating film was irradiated with polarized ultraviolet rays (10 mJ/cm², using an ultra-high pressure mercury lamp) to form a photo-alignment film B3, thereby obtaining a triacetyl cellulose (TAC) film with a photo-alignment film. The film thickness of the photo-alignment film B3 was 1.5 μm.

(Composition for forming photo-alignment film)

| | |
|---|---|
| Polymer PA-1: | 100.00 parts by mass |
| EPICLON N-695 (manufactured by DIC Corporation): | 57.5 parts by mass |
| jER YX7400 (manufactured by Mitsubishi Chemical Corporation): | 18.75 parts by mass |
| Polymer PA-3 shown below: | 6.25 parts by mass |
| Acid generator PAG-1: | 16.8 parts by mass |
| Stabilizer DIPEA: | 1.06 parts by mass |
| Butyl acetate: | 1195.1 parts by mass |

Polymer PA-3 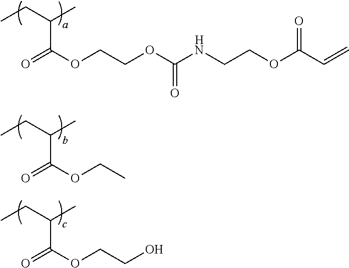
a/b/c = 89/10/1 (% by mass)

A laminate CP3 was prepared in the same manner as that for the laminate CP1 except that the triacetyl cellulose (TAC) film with a photo-alignment film provided with the photo-alignment film B3 on the cellulose acylate film A2 was used in place of the triacetyl cellulose (TAC) film with a photo-alignment film provided with the photo-alignment film B1 on the cellulose acylate film A1.

Further, a laminate CPAC5 was prepared in the same manner as that for the laminate CPAC1 except that the laminate CP3 was used in place of the laminate CP1, and an organic EL display device was further prepared.

### Example 10

The cellulose acylate film A2 was continuously coated with the following composition for forming a photo-alignment film using a wire bar. The support on which a coating film was formed was dried with hot air at 140° C. for 120 seconds, and the coating film was irradiated with polarized ultraviolet rays (10 mJ/cm², using an ultra-high pressure mercury lamp) to form a photo-alignment film B4, thereby obtaining a triacetyl cellulose (TAC) film with a photo-alignment film. The film thickness of the photo-alignment film B4 was 1.0 μm.

(Composition for forming photo-alignment film)

Polymer PA-1: 100.00 parts by mass
EPICLON N-695 (manufactured by DIC Corporation): 62.34 parts by
mass
jER YX7400 (manufactured by Mitsubishi Chemical Corporation): 20.33
parts by mass
Polymer PA-3: 8.69 parts by mass
Polymerization initiator IRGACURE OXE-02 (manufactured by BASF
SE): 6.52 parts by mass
Acid generator PAG-1: 18.16 parts by mass
Stabilizer DIPEA: 1.15 parts by mass
Butyl acetate: 1295.8 parts by mass

A laminate CP4 was prepared in the same manner as that for the laminate CP1 except that the triacetyl cellulose (TAC) film with a photo-alignment film provided with the photo-alignment film B4 on the cellulose acylate film A2 was used in place of the triacetyl cellulose (TAC) film with a photo-alignment film provided with the photo-alignment film B1 on the cellulose acylate film A1.

Further, a laminate CPAC6 was prepared in the same manner as that for the laminate CPAC1 except that the laminate CP4 was used in place of the laminate CP1, and an organic EL display device was further prepared.

### Example 11

The cellulose acylate film A2 was continuously coated with the following composition for forming a photo-alignment film using a wire bar. The support on which a coating film was formed was dried with hot air at 140° C. for 120 seconds, and the coating film was irradiated with polarized ultraviolet rays (10 mJ/cm², using an ultra-high pressure mercury lamp) to form a photo-alignment film B5, thereby obtaining a triacetyl cellulose (TAC) film with a photo-alignment film. The film thickness of the photo-alignment film B5 was 1.5 μm.

(Composition for forming photo-alignment film)

Polymer PA-1: 100.00 parts by mass
EPICLON N-695 (manufactured by DIC Corporation): 62.34 parts by
mass
jER YX7400 (manufactured by Mitsubishi Chemical Corporation): 20.33
mass
Polymer PA-3: 8.69 parts by mass
Polymerization initiator PI-1: 6.52 parts by mass
Acid generator PAG-1: 18.16 parts by mass
Stabilizer DIPEA: 1.15 parts by mass
Butyl acetate: 1295.8 parts by mass

A laminate CP5 was prepared in the same manner as that for the laminate CP1 except that the triacetyl cellulose (TAC) film with a photo-alignment film provided with the photo-alignment film B5 on the cellulose acylate film A2 was used in place of the triacetyl cellulose (TAC) film with a photo-alignment film provided with the photo-alignment film B1 on the cellulose acylate film A1.

Further, a laminate CPAC7 was prepared in the same manner as that for the laminate CPAC1 except that the laminate CP5 was used in place of the laminate CP1, and an organic EL display device was further prepared.

[Evaluation]

[Polarization Degree]

The polarization degree was measured using a laminate obtained after the formation of the oxygen-shielding layer (for example, the laminate CP1 in which the cellulose acylate film A1 (transparent support), the photo-alignment film B1, the light absorption anisotropic film C1, and the oxygen-shielding layer D1 were provided adjacent to each other in this order in Example 1).

Specifically, the transmittance of the light absorption anisotropic film was measured using an automatic polarizing film measuring device (trade name, VAP-7070, manufactured by Jasco Corporation), and the polarization degree was calculated according to the following equation.

Polarization degree [%]=[(MD−TD)/(MD+TD)]×100
MD: transmittance of light absorption anisotropic film with respect to polarized light in y-axis direction
TD: transmittance of light absorption anisotropic film with respect to polarized light in x-axis direction

Here, the polarization degree was measured for each incident surface of polarized light in the laminate. That is, a polarization degree PA in a case where polarized light was incident from the oxygen-shielding layer side (for example, the oxygen-shielding layer D1 side in Example 1) of the laminate and a polarization degree P_{B} in a case where polarized light was incident from the photo-alignment film side (for example, the photo-alignment film B1 side in Example 1) of the laminate were acquired.

The absolute value (difference in polarization degree) of the difference between the polarization degree PA and the polarization degree P_{B} was acquired based on the polarization degree PA and the polarization degree P_{B} obtained above.

[Out-of-Plane Alignment Degree F_{zx}]

The out-of-plane alignment degree f_{zx} of the dichroic substance was calculated by the above-described method using the waveguide spectroscopic analyzer of FIG. 1.

Further, two laminates before the formation of the oxygen-shielding layer (for example, the laminate in which the cellulose acylate film A1 (transparent support), the photo-alignment film B1, and the light absorption anisotropic film C1 were provided adjacent to each other in this order in Example 1) were prepared as the object to be measured and provided on both surfaces of the waveguide substrate 5. In addition, the size of the object to be measured was set to 5 mm×5 mm.

The outline and the measurement conditions of the constituent members of the waveguide spectroscopic analyzer are shown below.

Waveguide substrate: single crystal diamond substrate,length of 9 mm×width of 5 mm×thickness of 0.4 mm
Light source: heavy hydrogen lamp and halogen lamp
Measurement wavelength range: 240 to 880 nm
Total reflection angle of incidence ray in waveguide substrate: 64 degrees
Number of times of total reflection: approximately 20 times

[Display Performance]

The display screen of the prepared organic EL display device was brought into a black display state, and the reflected light in a case where a fluorescent lamp was projected from the front was observed. The display performance was evaluated based on the following standards.
A: It is black, no color-tinting is visible at all, and the reflectivity is low
B: Coloring is slightly visible, but the reflectivity is low
C: Coloring is slightly visible, and the reflectivity is high

The results of each evaluation are listed in Table 1.

In Table 1, the HSP distance denotes the distance between the HSP values of the surfactant and the HSP value of the liquid crystal compound L-1 in the light absorption anisotropic film.

TABLE 1

| | | | | | Surfactant | | | | | | |
|---|---|---|---|---|---|---|---|---|---|---|---|
| | | | | | | | | | | Content of | |
| | | | Differ- | | | | | Presence or | | surfactant | |
| | Polar- | Polar- | ence in | | | | | absence of | Content of | with respect | |
| | ization | ization | polar- | Out-of-plane | | | HSP | hydrogen | fluorine | to total | |
| | degree | degree | ization | alignment | | Log | distance | bonding | atom (% | solid content | Display |
| | P_{A} | P_{B} | degree | degree f_{EX} | Type | P | (MPa^{1/2}) | group | by mass) | (% by mass) | performance |
| Example 1 | 99.68% | 99.82% | 0.14% | −0.2 | F-1 | 4 | 3.9 | Present | 19% | 0.23% | B |
| Example 2 | 99.52% | 99.88% | 0.36% | 0.0 | F-2 | 5.1 | 4.0 | Absent | 19% | 0.21% | A |
| Example 3 | 99.71% | 99.82% | 0.11% | −0.1 | F-3 | 4 | 3.9 | Present | 19% | 0.24% | B |
| Example 4 | 99.51% | 99.83% | 0.32% | 0.0 | F-4 | 2.4 | 27.3 | Absent | 19% | 0.18% | A |
| Example 5 | 99.69% | 99.80% | 0.11% | −0.2 | F-3 | 4 | 3.9 | Present | 19% | 0.25% | B |
| Comparative | 99.81% | 99.81% | 0.00% | −0.5 | F-5 | 6 | 5.0 | Absent | 38% | 0.15% | C |
| Example 1 | | | | | | | | | | | |
| Comparative | 99.85% | 99.85% | 0.00% | −0.5 | F-6 | 3 | 3.2 | Present | 19% | 0.20% | C |
| Example 2 | | | | | | | | | | | |
| Comparative | 99.79% | 99.79% | 0.00% | −0.5 | F-4 | 2.4 | 27.3 | Absent | 19% | 0.03% | C |
| Example 3 | | | | | | | | | | | |
| Comparative | — | — | — | — | F-7 | 0.93 | 33.4 | Absent | 6% | 0.15% | Alignment |
| Example 4 | | | | | | | | | | | failure |

As listed in Table 1, it was found that in a case where the light absorption anisotropic film having a front surface and a rear surface with different polarization degrees was used, internal reflection occurring between the light absorption anisotropic film and the layer disposed adjacent to the light absorption anisotropic film was suppressed, and an image display device with excellent display performance was obtained (Examples 1 to 5). In addition, since each of the light absorption anisotropic films of Examples 6 to 11 also had a front surface and a rear surface with different polarization degrees, the effects of the present invention were confirmed.

Based on the comparison between Examples 1 to 5, it was found that in a case where the surfactant contained in the light absorption anisotropic film contained no hydrogen bonding group (Examples 2 and 4), the display performance was more excellent.

As a result of the measurement of the refractive indices of the light absorption anisotropic film and the oxygen-shielding layer constituting each laminate of Examples 1 to 5 at a wavelength of 550 nm using the above-described method, the refractive index of the light absorption anisotropic film was greater than the refractive index of the oxygen-shielding layer (protective layer) in all the examples.

On the contrary, it was found that in a case where the light absorption anisotropic film having a front surface and a rear surface with the same polarization degree was used, internal reflection occurring between the light absorption anisotropic film and the layer disposed adjacent to the light absorption anisotropic film was not suppressed, and the display performance of the image display device was degraded (Comparative Examples 1 to 3).

### EXPLANATION OF REFERENCES

1, 11: object to be measured
3: incidence ray
5: waveguide substrate
10: upper holding tool
13: emitted light
20: lower holding tool
22: arrow
30: light source
32: polarizer
35: detector
37: analyzer

What is claimed is:

1. A light absorption anisotropic film comprising:
a dichroic substance,
wherein a polarization degree A measured by allowing polarized light to be incident from one surface of the light absorption anisotropic film is different from a polarization degree B measured by allowing polarized light to be incident from the other surface of the light absorption anisotropic film.

2. The light absorption anisotropic film according to claim 1,
wherein an absolute value of a difference between the polarization degree A and the polarization degree B is 0.10% or greater.

3. The light absorption anisotropic film according to claim 1,
wherein in a surface of the light absorption anisotropic film on a side where the measured polarization degree is smaller between the polarization degree A and the polarization degree B, the dichroic substance has an out-of-plane alignment degree f_{zx} of −0.2 or greater.

4. The light absorption anisotropic film according to claim 1,
wherein the light absorption anisotropic film has an in-plane absorption axis.

5. The light absorption anisotropic film according to claim 1,
wherein the light absorption anisotropic film has a visible light average transmittance of 35% to 70%.

6. The light absorption anisotropic film according to claim 1,
wherein a content of the dichroic substance is 40% by mass or less with respect to a total mass of the light absorption anisotropic film.

7. The light absorption anisotropic film according to claim 1, further comprising:
a polymer liquid crystal compound.

8. The light absorption anisotropic film according to claim 1, further comprising:
a surfactant having a fluorine atom and a log P value of 5.2 or less.

9. The light absorption anisotropic film according to claim 8,
wherein a content of the fluorine atom in the surfactant is 10% by mass or greater.

10. The light absorption anisotropic film according to claim 8,
wherein the surfactant does not contain a hydrogen bonding group.

11. The light absorption anisotropic film according to claim 8,
wherein a content of the surfactant is in a range of 0.05% to 5% by mass with respect to a total mass of the light absorption anisotropic film.

12. The light absorption anisotropic film according to claim 8,
wherein in a case where the light absorption anisotropic film contains a polymer liquid crystal compound,
a distance between a Hansen solubility parameter of the surfactant and a Hansen solubility parameter of the polymer liquid crystal compound is 3.5 MPa^{1/2} or greater.

13. A laminate comprising:
a protective layer;
the light absorption anisotropic film according to claim 1; and
an alignment film in this order in a thickness direction,
wherein the alignment film is disposed on a surface side of the light absorption anisotropic film where a measured polarization degree is greater between a polarization degree A and a polarization degree B measured using the light absorption anisotropic film.

14. The laminate according to claim 13,
wherein a refractive index of the light absorption anisotropic film at a wavelength of 550 nm is greater than a refractive index of the protective layer at a wavelength of 550 nm.

15. The laminate according to claim 13, further comprising:
a λ/4 plate on a surface side of the alignment film opposite to the light absorption anisotropic film.

16. An image display device comprising:
the light absorption anisotropic film according to claim 1.

17. An image display device comprising:
the laminate according to claim 13.

18. The light absorption anisotropic film according to claim 2,
wherein in a surface of the light absorption anisotropic film on a side where the measured polarization degree is smaller between the polarization degree A and the polarization degree B, the dichroic substance has an out-of-plane alignment degree f_{zx} of −0.2 or greater.

19. The light absorption anisotropic film according to claim 2,
wherein the light absorption anisotropic film has an in-plane absorption axis.

20. The light absorption anisotropic film according to claim 2,
wherein the light absorption anisotropic film has a visible light average transmittance of 35% to 70%.
